(19) United States
(12) Patent Application Publication
(10) Pub. No.: US 2025/0311242 A1
(43) Pub. Date: Oct. 2, 2025

(54) MEMORY DEVICE AND OPERATION METHOD THEREOF

(71) Applicant: YANGTZE MEMORY TECHNOLOGIES CO., LTD., Wuhan (CN)

(72) Inventors: Yaqin Liu, Wuhan (CN); Wei Liu, Wuhan (CN); Liang Chen, Wuhan (CN); Zhiliang Xia, Wuhan (CN); Zongliang Huo, Wuhan (CN); Yuancheng Yang, Wuhan (CN); Dongxue Zhao, Wuhan (CN)

(21) Appl. No.: 18/624,605

(22) Filed: Apr. 2, 2024

(30) Foreign Application Priority Data
Mar. 26, 2024 (CN) 202410354166.7

(51) Int. Cl. H10B 80/00; H01L 23/00; H01L 25/00; H01L 25/065; H01L 25/18; H10B 12/00

(52) U.S. Cl. CPC H10B 80/00; H01L 24/08; H01L 24/80; H01L 25/0657; H01L 25/18; H01L 25/50; H10B 12/036; H10B 12/05; H10B 12/33; H01L 2224/08145; H01L 2224/80895; H01L 2224/80896; H01L 2924/1431; H01L 2924/1436

(57) ABSTRACT

A semiconductor device and method for forming thereof is provided. The semiconductor device includes a first semiconductor structure and a second semiconductor structure. The first semiconductor structure includes a peripheral circuit. The second semiconductor structure includes memory cells each having a vertical transistor and a storage unit coupled to the vertical transistor. The vertical transistor includes a semiconductor layer extending along a vertical direction and a gate structure coupled to the semiconductor layer. A leakage value of the semiconductor layer is lower than a pico-ampere. The first semiconductor structure is bonded with the second semiconductor structure, and the vertical transistor is between the peripheral circuit and the storage unit.

### CROSS-REFERENCE TO RELATED APPLICATIONS

This application claims the benefit of priority to Chinese Application No. 202410354166.7, filed on Mar. 26, 2024, which is incorporated herein by reference in its entirety.

### BACKGROUND

The present disclosure relates to semiconductor devices and methods for forming thereof.

Planar memory cells are scaled to smaller sizes by improving process technology, circuit design, programming algorithm, and fabrication process. However, as feature sizes of the memory cells approach a lower limit, planar process and fabrication techniques become challenging and costly. As a result, memory density for planar memory cells approaches an upper limit.

### SUMMARY

In one aspect, a semiconductor device including a first semiconductor structure and a second semiconductor structure is provided. The first semiconductor structure includes a peripheral circuit. The second semiconductor structure includes memory cells each having a vertical transistor and a storage unit coupled to the vertical transistor. The vertical transistor includes a semiconductor layer extending along a vertical direction and a gate structure coupled to the semiconductor layer. A leakage value of the semiconductor layer is lower than a pico-ampere. The first semiconductor structure is coupled with the second semiconductor structure, and the vertical transistor is between the peripheral circuit and the storage unit.

In some implementations, the second semiconductor structure further includes bit lines each extending along a first lateral direction and coupled with the semiconductor layer and gate lines each extending along a second lateral direction and coupled with the gate structure. The vertical direction, the first lateral direction, and the second lateral direction are perpendicular to each other.

In some implementations, the bit lines are between the vertical transistors and the peripheral circuit.

In some implementations, each bit line is coupled with at least two opposite sides of an end of the semiconductor layer of each vertical transistor away from the storage unit.

In some implementations, the gate structure includes a gate electrode and a gate dielectric between the gate electrode and the semiconductor layer in the first and second lateral directions.

In some implementations, the vertical transistor is a single-gate transistor in which a gate structure of the vertical transistor is located at one side of the semiconductor layer in a plan view.

In some implementations, the semiconductor layer includes a vertical portion extending along the vertical direction and an extending portion extending from an end of the vertical portion towards an adjacent vertical transistor along a second lateral direction. The extending portion is coupled with the storage unit, and the vertical direction and the second lateral direction are perpendicular to each other.

In some implementations, the vertical transistor includes a double-gate transistor in which a gate structure of the vertical transistor is located at two opposite sides of the semiconductor layer.

In some implementations, the semiconductor layer includes a vertical portion extending along the vertical direction and an extending portion extending from an end of the vertical portion towards two adjacent vertical transistors along a second lateral direction. The extending portion is coupled with the storage unit, and the vertical direction and the second lateral direction are perpendicular to each other.

In some implementations, the vertical transistor is a gate-all-around (GAA) transistor in which the gate structure fully surrounds the semiconductor layer in a plan view.

In some implementations, the semiconductor layer includes a vertical portion extending along the vertical direction and an extending portion extending from an end of the vertical portion towards two adjacent vertical transistors along a second lateral direction. The extending portion is coupled with the storage unit, and the vertical direction and the second lateral direction are perpendicular to each other.

In some implementations, the vertical transistor includes a tri-gate transistor in which the gate structure partially surrounds the semiconductor layer in a plan view.

In some implementations, each vertical transistor is coupled with the corresponding storage unit through a direct ohmic contact or a storage node contact.

In some implementations, the second semiconductor structure further includes a pad-out interconnect layer, and the storage units are disposed between the vertical transistors and the pad-out interconnect layer.

In some implementations, the first semiconductor structure further includes a pad-out interconnect layer, and the peripheral circuit is disposed between the second semiconductor structure and the pad-out interconnect layer.

In some implementations, the semiconductor layer includes one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In another aspect, a method for forming a semiconductor device is provided. The method includes forming a first set of memory cells on a substrate, forming a dielectric layer covering the first set of memory cells, and forming a second set of memory cells on the dielectric layer. Each of the memory cells of the first set and the second set includes a vertical transistor and a storage unit coupled to the vertical transistor. The vertical transistor comprises a semiconductor layer extending along a vertical direction and a gate structure coupled to the semiconductor layer. A leakage value of the semiconductor layer is lower than a pico-ampere.

In some implementations, the method further includes coupling a peripheral circuit with the second set of memory cells. The vertical transistors of the second set of memory cells are between the peripheral circuit and the storage units of the second set of memory cells.

In some implementations, coupling the peripheral circuit with the second set of memory cells comprises hybrid bonding.

In some implementations, the method further includes forming a pad-out interconnect layer on the first set of memory cells. The storage units of the first set of memory cells are disposed between the vertical transistors of the first set of memory cells and the pad-out interconnect layer.

In some implementations, the method further includes forming a pad-out interconnect layer on the peripheral circuit. The peripheral circuit is disposed between the vertical transistors of the second set of memory cells and the pad-out interconnect layer.

In some implementations, forming the first set of memory cells includes forming the storage units on the substrate. The storage units are surrounded by a first isolation layer. Forming the first set of memory cells further includes forming a second isolation layer covering the storage unit, forming through holes on the second insolation layer to expose the storage units, and forming the vertical transistors in the through holes.

In some implementations, forming the vertical transistors in the through holes includes forming two semiconductor layers of two adjacent vertical transistors on two opposite sidewalls of each of the through hole, forming two gate structures coupled to the two semiconductor layers respectively, and filling the through hole with dielectric materials to isolate the two gate structures with each other.

In some implementations, forming two semiconductor layers on two opposite sidewalls of each of the through hole including: epitaxially growing an initial semiconductor layer covering a bottom and the two opposite sidewalls of each of the through hole; and forming a trench on the initial semiconductor layer on the bottom of the through hole to punch through the initial semiconductor layer into two separate semiconductor layers of two adjacent vertical transistors.

In some implementations, a width of the trench is less than a width of the bottom of the through hole.

In some implementations, the semiconductor layer comprises one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

In still another aspect, a semiconductor device including a first semiconductor structure and a second semiconductor structure is provided. The first semiconductor structure includes a peripheral circuit. The second semiconductor structure includes a first set of memory cells and a second set of memory cells stacked on the first set of memory cells. Each of the memory cells of the first set and the second set includes a vertical transistor and a storage unit coupled to the vertical transistor. The vertical transistor includes a semiconductor layer extending along a vertical direction and a gate structure coupled to the semiconductor layer. A leakage value of the semiconductor layer is lower than a pico-ampere. The first semiconductor structure is bonded with the second semiconductor structure, and the first set of memory cells is between the peripheral circuit and the second set of memory cells.

In some implementations, the vertical transistors of the first set of memory cells are disposed between the peripheral circuit and the storage units of the first set of memory cells.

In some implementations, the vertical transistors of the second set of memory cells are disposed between the storage units of the first set of memory cells and the storage units of the second set of memory cells.

In some implementations, the first semiconductor structure further includes a pad-out interconnect layer, and the peripheral circuit is disposed between the vertical transistors of the first set of memory cells and the pad-out interconnect layer.

In some implementations, the second semiconductor structure further includes a pad-out interconnect layer, and the storage units of the second set of memory cells are disposed between the vertical transistors of the second set of memory cells and the pad-out interconnect layer.

In some implementations, the first semiconductor structure further includes a first bonding layer including a first bonding contact. The second semiconductor structure further includes a second bonding layer including a second bonding contact. The first bonding contact is coupled with the second bonding contact at the first bonding interface.

In some implementations, the first set of memory cells further includes bit lines each extending along a first lateral direction and coupled with the semiconductor layers of the vertical transistors of the first set of memory cells and gate lines extending along a second lateral direction and coupled with the gate structure of the vertical transistors of the first set of memory cells. The vertical direction, the first lateral direction, and the second lateral direction are perpendicular to each other.

In some implementations, the second set of memory cells further includes bit lines each extending along the first lateral direction and coupled with the semiconductor layers of the vertical transistors of the second set of memory cells and gate lines each extending along the second lateral direction and coupled with the gate structure of the vertical transistors of the second set of memory cells. The vertical direction, the first lateral direction, and the second lateral direction are perpendicular to each other.

In some implementations, the semiconductor layer comprises one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

### BRIEF DESCRIPTION OF THE DRAWINGS

The accompanying drawings, which are incorporated herein and form a part of the specification, illustrate aspects of the present disclosure and, together with the description, further serve to explain the principles of the present disclosure and to enable a person skilled in the pertinent art to make and use the present disclosure.

FIG. 1A illustrates a schematic view of a cross-section of a semiconductor device, according to some aspects of the present disclosure.

FIG. 1B illustrates a schematic view of a cross-section of another semiconductor device, according to some aspects of the present disclosure.

FIG. 2 illustrates a schematic diagram of a semiconductor device including peripheral circuits and an array of memory cells each having a vertical transistor, according to some aspects of the present disclosure.

FIG. 3 illustrates a schematic circuit diagram of a semiconductor device including peripheral circuits and an array of dynamic random-access memory (DRAM) cells, according to some aspects of the present disclosure.

FIG. 4 illustrates a schematic circuit diagram of a semiconductor device including peripheral circuits and an array of phase-change memory (PCM) cells, according to some aspects of the present disclosure.

FIG. 5 illustrates a plan view of an array of memory cells each including a vertical transistor in a memory device, according to some aspects of the present disclosure.

FIG. 6A illustrates a side view of a cross-section of a semiconductor device including vertical transistors, according to some aspects of the present disclosure.

FIG. 6B illustrates a side view of a cross-section of another semiconductor device including vertical transistors, according to some aspects of the present disclosure.

FIG. 7 illustrates a flowchart of a method for forming a semiconductor device including vertical transistors, according to some aspects of the present disclosure.

FIGS. 8A-8P illustrate a fabrication process for forming a semiconductor device including vertical transistors, according to some aspects of the present disclosure.

FIG. 9A illustrates a side view of a cross-section of a semiconductor device including vertical transistors, according to some aspects of the present disclosure.

FIG. 9B illustrates a side view of a cross-section of another semiconductor device including vertical transistors, according to some aspects of the present disclosure.

FIG. 10 illustrates a flowchart of a method for forming a semiconductor device including vertical transistors, according to some aspects of the present disclosure.

FIGS. 11A-11H illustrate a fabrication process for forming a semiconductor device including vertical transistors, according to some aspects of the present disclosure.

FIG. 12 illustrates a plan view of an array of memory cells each including a vertical transistor in a memory device, according to some aspects of the present disclosure.

FIG. 13 illustrates a side view of a cross-section of a semiconductor device including vertical transistors, according to some aspects of the present disclosure.

FIG. 14 illustrates a flowchart of a method for forming a semiconductor device including vertical transistors, according to some aspects of the present disclosure.

FIG. 15 illustrates a flowchart of a method for forming an array of vertical transistors, according to some aspects of the present disclosure.

FIGS. 16A-16K illustrate a fabrication process for forming a semiconductor device including vertical transistors, according to some aspects of the present disclosure.

FIG. 17 illustrates a plan view of an array of memory cells each including a vertical transistor in a memory device, according to some aspects of the present disclosure.

FIG. 18 illustrates a side view of a cross-section of a semiconductor device including vertical transistors, according to some aspects of the present disclosure.

FIG. 19 illustrates a flowchart of a method for forming a semiconductor device including vertical transistors, according to some aspects of the present disclosure.

FIG. 20 illustrates a flowchart of a method for forming an array of vertical transistors, according to some aspects of the present disclosure.

FIGS. 21A-21L illustrate a fabrication process for forming a semiconductor device including vertical transistors, according to some aspects of the present disclosure.

The present disclosure will be described with reference to the accompanying drawings.

### DETAILED DESCRIPTION

Although specific configurations and arrangements are discussed, it should be understood that this is done for illustrative purposes only. As such, other configurations and arrangements can be used without departing from the scope of the present disclosure. Also, the present disclosure can also be employed in a variety of other applications. Functional and structural features as described in the present disclosures can be combined, adjusted, and modified with one another and in ways not specifically depicted in the drawings, such that these combinations, adjustments, and modifications are within the scope of the present disclosure.

In general, terminology may be understood at least in part from usage in context. For example, the term “one or more” as used herein, depending at least in part upon context, may be used to describe any feature, structure, or characteristic in a singular sense or may be used to describe combinations of features, structures or characteristics in a plural sense. Similarly, terms, such as “a,” “an,” or “the,” again, may be understood to convey a singular usage or to convey a plural usage, depending at least in part upon context. In addition, the term “based on” may be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something but also includes the meaning of “on” something with an intermediate feature or a layer therebetween, and that “above” or “over” not only means the meaning of “above” or “over” something but can also include the meaning it is “above” or “over” something with no intermediate feature or layer therebetween (i.e., directly on something).

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations), and the spatially relative descriptors used herein may likewise be interpreted accordingly.

As used herein, the term “substrate” refers to a material onto which subsequent material layers are added. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically non-conductive material, such as a glass, a plastic, or a sapphire wafer.

As used herein, the term “layer” refers to a material portion including a region with a thickness. A layer can extend over the entirety of an underlying or overlying structure or may have an extent less than the extent of an underlying or overlying structure. Further, a layer can be a region of a homogeneous or inhomogeneous continuous structure that has a thickness less than the thickness of the continuous structure. For example, a layer can be located between any pair of horizontal planes between, or at, a top surface and a bottom surface of the continuous structure. A layer can extend horizontally, vertically, and/or along a tapered surface. A substrate can be a layer, can include one or more layers therein, and/or can have one or more layers thereupon, thereabove, and/or therebelow. A layer can include multiple layers. For example, an interconnect layer can include one or more conductors and contact layers (in which interconnect lines and/or vertical interconnect access (via) contacts are formed) and one or more dielectric layers.

Transistors are used as the switch or selecting devices in the memory cells of some semiconductor devices, such as DRAM, PCM, and ferroelectric DRAM (FRAM). However, the planar transistors commonly used in existing memory cells usually have a horizontal structure with buried word lines in the substrate and bit lines above the substrate. Since the source and drain of a planar transistor are disposed laterally at different locations, which increases the area occupied by the transistor. The design of planar transistors also complicates the arrangement of interconnected structures, such as word lines and bit lines, coupled to the memory cells, for example, limiting the pitches of the word lines and/or bit lines, thereby increasing the fabrication complexity and reducing the production yield. Moreover, because the bit lines and the storage units (e.g., capacitors or PCM elements) are arranged on the same side of the planar transistors (above the transistors and substrate), the bit line process margin is limited by the storage units, and the coupling capacitance between the bit lines and storage units, such as capacitors, are increased. Planar transistors may also suffer from a high leakage current as the saturated drain current keeps increasing, which is undesirable for the performance of semiconductor devices.

On the other hand, the memory cell array and the peripheral circuits for controlling the memory cell array are usually arranged side-by-side in the same plane. As the number of memory cells keeps increases, to maintain the same chip size, the dimensions of the components in the memory cell array, such as transistors, word lines, and/or bit lines, need to keep decreasing in order not to significantly reduce the memory cell array efficiency.

To address one or more of the aforementioned issues, the present disclosure introduces a solution in which vertical transistors replace the conventional planar transistors as the switch and selecting devices in a memory cell array of semiconductor devices (e.g., DRAM, PCM, and FRAM). Compared with planar transistors, the vertically arranged transistors (i.e., the drain and source are overlapped in the plan view) can reduce the area of the transistor as well as simplify the layout of the interconnect structures, e.g., metal wiring the word lines and bit lines, which can reduce the fabrication complexity and improve the yield. For example, the pitches of word lines and/or bit lines can be reduced for ease of fabrication. The vertical structures of the transistors also allow the bit lines and storage units, such as capacitors, to be arranged on opposite sides of the transistors in the vertical direction (e.g., one above and one below the transistors), such that the process margin of the bit lines can be increased and the coupling capacitance between the bit lines and the storage units can be decreased.

Consistent with the scope of the present disclosure, according to some aspects of the present disclosure, the memory cell array having vertical transistors and the peripheral circuits of the memory cell array can be formed on different wafers and bonded together in a face-to-face manner. Thus, the thermal budget of fabricating the memory cell array does not affect the fabrication of the peripheral circuits. The stacked memory cell array and peripheral circuits can also reduce the chip size compared with the side-by-side arrangement, thereby improving the array efficiency. In some implementations, more than one memory cell array is stacked over one another using bonding techniques to further increase the array efficiency. In some implementations, the word lines and bit lines are disposed close to the bonding interface due to the vertically arranged transistors, which can be coupled to the peripheral circuits through a large number (e.g., millions) of parallel bonding contacts across the bonding interface can make direct, short-distance (e.g., micron-level) electrical connections between the memory cell array and peripheral circuits to increase the throughput and input/output (I/O) speed of the semiconductor devices.

In some implementations, the vertical transistors disclosed herein include multi-gate transistors (e.g., gate-all-around (GAA) transistors, tri-gate transistors, or double-gate transistors), which can have a larger gate control area to achieve better channel control with a smaller subthreshold swing. During the off state, since the channel is fully depleted, the leakage current of multi-gate transistors can be significantly reduced as well. Thus, using multi-gate transistors instead of planar transistors can achieve a much better speed (saturated drain current)/leakage current performance.

In some implementations, the vertical transistors disclosed herein include single-gate transistors (a.k.a. single-side gate transistors) in a mirror-symmetric arrangement with respect to adjacent transistors in the bit line direction as a result of splitting multi-gate transistors (e.g., double-gate transistors) using trench isolations extending along the word line direction. Thus, the memory cell density in the bit line direction can be significantly increased (e.g., doubled) without unduly complicating the fabrication process compared with using processes, such as self-aligned double patterning (SADP). Also, the mirror-symmetric single-gate transistors have a larger process window for word line, bit line, and transistor pitch reduction, compared to either conventional planar transistors or multi-gate vertical transistors, for example, with dual-side or all-around gates.

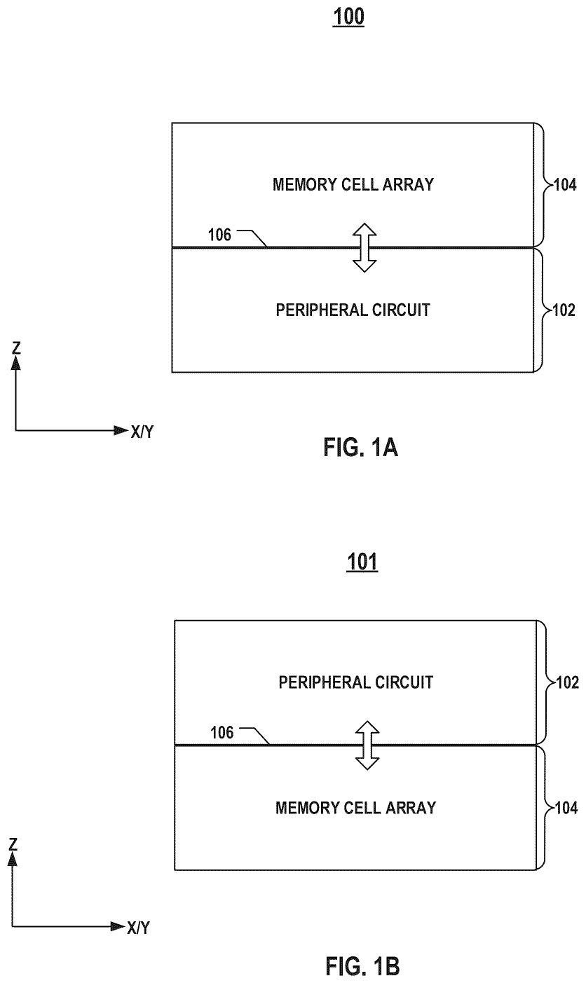

FIG. 1A illustrates a schematic view of a cross-section of a semiconductor device 100, according to some aspects of the present disclosure. Semiconductor device 100 represents an example of a bonded chip. The components of semiconductor device 100 (e.g., memory cell array and peripheral circuits) can be formed separately on different substrates and then jointed to form a bonded chip. Semiconductor device 100 can include a first semiconductor structure 102 including the peripheral circuits of a memory cell array. Semiconductor device 100 can also include a second semiconductor structure 104 including the memory cell array. The peripheral circuits (a.k.a. control and sensing circuits) can include any suitable digital, analog, and/or mixed-signal circuits used for facilitating the operations of the memory cell array. For example, the peripheral circuit can include one or more of a page buffer, a decoder (e.g., a row decoder and a column decoder), a sense amplifier, a driver (e.g., a word line driver), an input/output (I/O) circuit, a charge pump, a voltage source or generator, a current or voltage reference, any portions (e.g., a sub-circuit) of the functional circuits mentioned above, or any active or passive components of the circuit (e.g., transistors, diodes, resistors, or capacitors). The peripheral circuits in first semiconductor structure 102 use complementary metal-oxide-semiconductor (CMOS) technology, e.g., which can be implemented with logic processes (e.g., technology nodes of 90 nm, 65 nm, 60 nm, 45 nm, 32 nm, 28 nm, 22 nm, 20 nm, 16 nm, 14 nm, 10 nm, 7 nm, 5 nm, 3 nm, 2 nm, etc.), according to some implementations.

As shown in FIG. 1A, semiconductor device 100 can also include first semiconductor structure 102 including an array of memory cells (memory cell array) that can use transistors as the switch and selecting devices. In some implementations, the memory cell array includes an array of DRAM cells. For ease of description, a DRAM cell array may be used as an example for describing the memory cell array in the present disclosure. But it is understood that the memory cell array is not limited to DRAM cell array and may include any other suitable types of memory cell arrays that can use transistors as the switch and selecting devices, such as PCM cell array, static random-access memory (SRAM) cell array, FRAM cell array, resistive memory cell array, magnetic memory cell array, spin transfer torque (STT) memory cell array, to name a few, or any combination thereof.

Second semiconductor structure 104 can be a DRAM device in which memory cells are provided in the form of an array of DRAM cells. In some embodiments, each DRAM cell includes a capacitor for storing a bit of data as a positive or negative electrical charge as well as one or more transistors (a.k.a. pass transistors) that control (e.g., switch and selecting) access to it. In some implementations, each DRAM cell is a one-transistor, one-capacitor (1T1C) cell. Since transistors always leak a small amount of charge, the capacitors will slowly discharge, causing information stored in them to drain. As such, a DRAM cell has to be refreshed to retain data, for example, by the peripheral circuit in first semiconductor structure 102, according to some implementations.

As shown in FIG. 1A, semiconductor device 100 further includes a bonding interface 106 vertically between (in the vertical direction, e.g., the z-direction in FIG. 1A) first semiconductor structure 102 and second semiconductor structure 104. As described below in detail, first and second semiconductor structures 102 and 104 can be fabricated separately (and in parallel in some implementations) such that the thermal budget of fabricating one of first and second semiconductor structures 102 and 104 does not limit the processes of fabricating another one of first and second semiconductor structures 102 and 104. Moreover, a large number of interconnects (e.g., bonding contacts) can be formed through bonding interface 106 to make direct, short-distance (e.g., micron-level) electrical connections between first semiconductor structure 102 and second semiconductor structure 104, as opposed to the long-distance (e.g., millimeter or centimeter-level) chip-to-chip data bus on the circuit board, such as printed circuit board (PCB), thereby eliminating chip interface delay and achieving high-speed I/O throughput with reduced power consumption. Data transfer between the memory cell array in second semiconductor structure 104 and the peripheral circuits in first semiconductor structure 102 can be performed through the interconnects (e.g., bonding contacts) across bonding interface 106. By vertically integrating first and second semiconductor structures 102 and 104, the chip size can be reduced, and the memory cell density can be increased.

It is understood that the relative positions of stacked first and second semiconductor structures 102 and 104 are not limited. FIG. 1B illustrates a schematic view of a cross-section of another exemplary semiconductor device 101, according to some implementations. Different from semiconductor device 100 in FIG. 1A in which second semiconductor structure 104 including the memory cell array is above first semiconductor structure 102 including the peripheral circuits, in semiconductor device 101 in FIG. 1B, first semiconductor structure 102 including the peripheral circuit is above second semiconductor structure 104 including the memory cell array. Nevertheless, bonding interface 106 is formed vertically between first and second semiconductor structures 102 and 104 in semiconductor device 101, and first and second semiconductor structures 102 and 104 are jointed vertically through bonding (e.g., hybrid bonding) according to some implementations. Hybrid bonding, also known as “metal/dielectric hybrid bonding,” is a direct bonding technology (e.g., forming bonding between surfaces without using intermediate layers, such as solder or adhesives) and can obtain metal-metal (e.g., copper-to-copper) bonding and dielectric-dielectric (e.g., silicon oxide-to-silicon oxide) bonding simultaneously. Data transfer between the memory cell array in second semiconductor structure 104 and the peripheral circuits in first semiconductor structure 102 can be performed through the interconnects (e.g., bonding contacts) across bonding interface 106.

It is noted that x, y, and z axes are included in FIGS. 1A and 1B to further illustrate the spatial relationship of the components in semiconductor devices 100 and 101. The substrate of the semiconductor device includes two lateral surfaces extending laterally in the x-y plane: a top surface on the front side of the wafer on which the semiconductor devices can be formed, and a bottom surface on the backside opposite to the front side of the wafer. The z-axis is perpendicular to both the x and y axes. As used herein, whether one component (e.g., a layer or a device) is “on,” “above,” or “below” another component (e.g., a layer or a device) of the semiconductor device is determined relative to the substrate of the semiconductor device in the z-direction (the vertical direction perpendicular to the x-y plane, e.g., the thickness direction of the substrate) when the substrate is positioned in the lowest plane of the semiconductor device in the z-direction. The same notion for describing the spatial relationships is applied throughout the present disclosure.

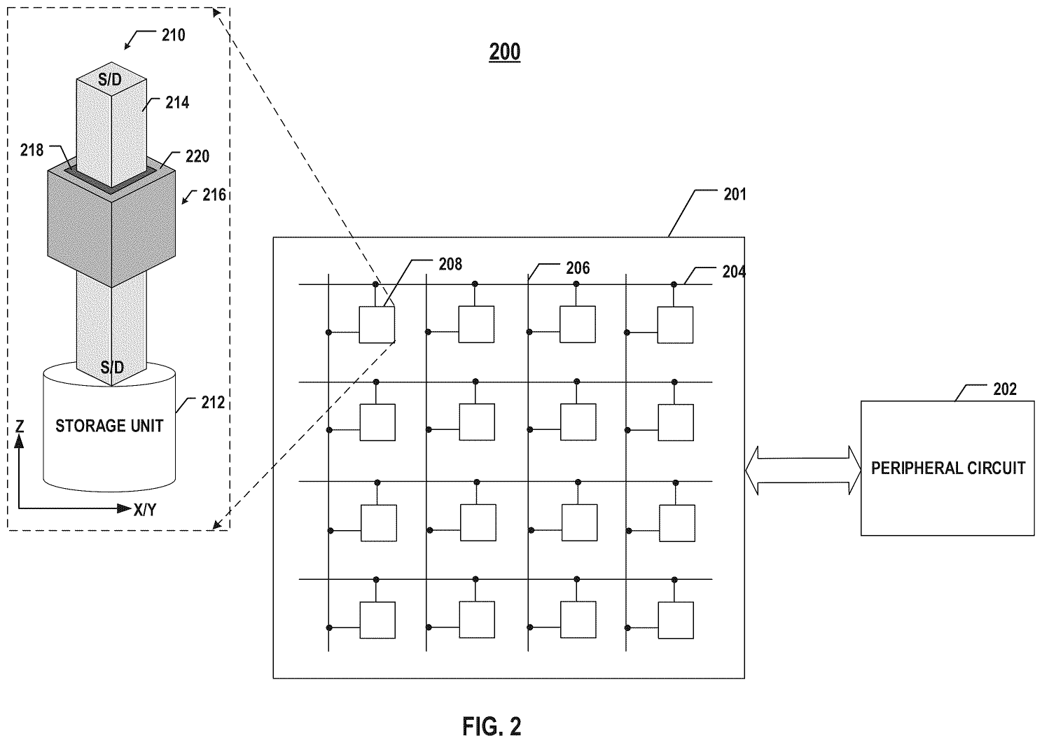

FIG. 2 illustrates a schematic diagram of a semiconductor device 200 including peripheral circuits and an array of memory cells each having a vertical transistor, according to some aspects of the present disclosure. Semiconductor device 200 can include a memory cell array 201 and peripheral circuits 202 coupled to memory cell array 201. Semiconductor devices 100 and 101 may be examples of semiconductor device 200 in which memory cell array 201 and peripheral circuits 202 may be included in second and first semiconductor structures 104 and 102, respectively. Memory cell array 201 can be any suitable memory cell array in which each memory cell 208 includes a vertical transistor 210 and a storage unit 212 coupled to vertical transistor 210. In some implementations, memory cell array 201 is a DRAM cell array, and storage unit 212 is a capacitor for storing charge as the binary information stored by the respective DRAM cell. In some implementations, memory cell array 201 is a PCM cell array, and storage unit 212 is a PCM element (e.g., including chalcogenide alloys) for storing binary information of the respective PCM cell based on the different resistivities of the PCM element in the amorphous phase and the crystalline phase. In some implementations, memory cell array 201 is a FRAM cell array, and storage unit 212 is a ferroelectric capacitor for storing binary information of the respective FRAM cell based on the switch between two polarization states of ferroelectric materials under an external electric field.

As shown in FIG. 2, memory cells 208 can be arranged in a two-dimensional (2D) array having rows and columns. Semiconductor device 200 can include word lines 204 coupling peripheral circuits 202 and memory cell array 201 for controlling the switch of vertical transistors 210 in memory cells 208 located in a row, as well as bit lines 206 coupling peripheral circuits 202 and memory cell array 201 for sending data to and/or receiving data from memory cells 208 located in a column. That is, each word line 204 is coupled to a respective row of memory cells 208, and each bit line is coupled to a respective column of memory cells 208.

Consistent with the scope of the present disclosure, vertical transistors 210, such as vertical metal-oxide-semiconductor field-effect transistors (MOSFETs), can replace the conventional planar transistors as the pass transistors of memory cells 208 to reduce the area occupied by the pass transistors, the coupling capacitance, as well as the interconnect routing complexity, as described below in detail. As shown in FIG. 2, in some implementations, different from planar transistors in which the active regions are formed in the substrates, vertical transistor 210 includes a semiconductor body 214 extending vertically (in the z-direction) above the substrate (not shown). That is, semiconductor body 214 can extend above the top surface of the substrate to expose not only the top surface of semiconductor body 214, but also one or more side surfaces thereof. As shown in FIG. 2, for example, semiconductor body 214 can have a cuboid shape to expose four sides thereof. It is understood that semiconductor body 214 may have any suitable shape, such as polyhedron shapes or a cylinder shape. That is, the cross-section of semiconductor body 214 in the plan view (e.g., in the x-y plane) can have a square shape, a rectangular shape (or a trapezoidal shape), a circular (or an oval shape), or any other suitable shapes. It is understood that consistent with the scope of the present disclosure, for semiconductor layers that have a circular or oval shape of their cross-sections in the plan view, the semiconductor layers may still be considered to have multiple sides, such that the gate structures are coupled with more than one side of the semiconductor layers. As described below with respect to the fabrication process, semiconductor body 214 can be formed from the substrate (e.g., by etching or epitaxy) and thus, has the same semiconductor material (e.g., crystalline silicon) as the substrate (e.g., a silicon substrate).

As shown in FIG. 2, vertical transistor 210 can also include a gate structure 216 coupled with one or more sides of semiconductor body 214, i.e., in one or more planes of the side surface(s) of the active region. In other words, the active region of vertical transistor 210, i.e., semiconductor body 214, can be at least partially surrounded by gate structure 216. Gate structure 216 can include a gate dielectric 218 over one or more sides of semiconductor body 214, e.g., coupled with four side surfaces of semiconductor body 214 as shown in FIG. 2. Gate structure 216 can also include a gate electrode 220 over and coupled with gate dielectric 218. Gate dielectric 218 can include any suitable dielectric materials, such as silicon oxide, silicon nitride, silicon oxynitride, or high-k dielectrics. For example, gate dielectric 218 may include silicon oxide, i.e., gate oxide. Gate electrode 220 can include any suitable conductive materials, such as polysilicon, metals (e.g., tungsten (W), copper (Cu), aluminum (Al), etc.), metal compounds (e.g., titanium nitride (TiN), tantalum nitride (TaN), etc.), or silicides. For example, gate electrode 220 may include doped polysilicon, i.e., a gate poly. In some implementations, gate electrode 220 includes multiple conductive layers, such as a W layer over a TiN layer. It is understood that gate electrode 220 and word line 204 may be a continuous conductive structure in some examples. In other words, gate electrode 220 may be viewed as part of word line 204 that forms gate structure 216, or word line 204 may be viewed as the extension of gate electrode 220 to be coupled to peripheral circuits 202.

As shown in FIG. 2, vertical transistor 210 can further include a pair of a source and a drain (S/D, dope regions, a.k.a., source electrode and drain electrode) formed at the two ends of semiconductor body 214 in the vertical direction (the z-direction), respectively. The source and drain can be doped with any suitable P-type dopants, such as boron (B) or Gallium (Ga), or any suitable N-type dopants, such as phosphorus (P) or arsenic (As). The source and drain can be separated by gate structure 216 in the vertical direction (the z-direction). In other words, gate structure 216 is formed vertically between the source and drain. As a result, one or more channels (not shown) of vertical transistor 210 can be formed in semiconductor body 214 vertically between the source and drain when a gate voltage applied to gate electrode 220 of gate structure 216 is above the threshold voltage of vertical transistor 210. That is, each channel of vertical transistors 210 is also formed in the vertical direction along which semiconductor body 214 extends, according to some implementations.

In some implementations, as shown in FIG. 2, vertical transistor 210 is a multi-gate transistor. That is, gate structure 216 can be coupled with more than one side of semiconductor body 214 (e.g., four sides in FIG. 2) to form more than one gate, such that more than one channel can be formed between the source and drain in operation. That is, different from the planar transistor that includes only a single planar gate (and resulting in a single planar channel), vertical transistor 210 shown in FIG. 2 can include multiple vertical gates on multiple sides of semiconductor body 214 due to the semiconductor structure of semiconductor body 214 and gate structure 216 that surrounds the multiple sides of semiconductor body 214. As a result, compared with planar transistors, vertical transistor 210 shown in FIG. 2 can have a larger gate control area to achieve better channel control with a smaller subthreshold swing. During the off state, since the channel is fully depleted, the leakage current of vertical transistor 210 can be significantly reduced as well. As described below in detail, the multi-gate vertical transistors can include double-gate vertical transistors (e.g., dual-side gate vertical transistors), tri-gate vertical transistors (e.g., tri-side gate vertical transistors), and GAA vertical transistors.

It is understood that although vertical transistor 210 is shown as a multi-gate transistor in FIG. 2, the vertical transistors disclosed herein may also include single-gate transistors as described below in detail. That is, gate structure 216 may be coupled with a single side of semiconductor body 214, for example, for the purpose of increasing the transistor and memory cell density. It is also understood that although gate dielectric 218 is shown as being separate (i.e., a separate structure) from other gate dielectrics of adjacent vertical transistors (not shown), gate dielectric 218 may be part of a continuous dielectric layer having multiple gate dielectrics of vertical transistors.

In planar transistors and some lateral multiple-gate transistors (e.g., FinFET), the active regions, such as semiconductor layers (e.g., Fins), extend laterally (in the x-y plane), and the source and the drain are disposed at different locations in the same lateral plane (the x-y plane). In contrast, in vertical transistor 210, semiconductor body 214 extends vertically (in the z-direction), and the source and the drain are disposed in the different lateral planes, according to some implementations. In some implementations, the source and the drain are formed at two ends of semiconductor body 214 in the vertical direction (the z-direction), respectively, thereby being overlapped in the plan view. As a result, the area (in the x-y plane) occupied by vertical transistor 210 can be reduced compared with planar transistor and lateral multiple-gate transistors. Also, the metal wiring coupled to vertical transistors 210 can be simplified as well since the interconnects can be routed in different planes. For example, bit lines 206 and storage units 212 may be formed on opposite sides of vertical transistor 210. In one example, bit line 206 may be coupled to the source or the drain at the upper end of semiconductor body 214, while storage unit 212 may be coupled to the other source or the drain at the lower end of semiconductor body 214.

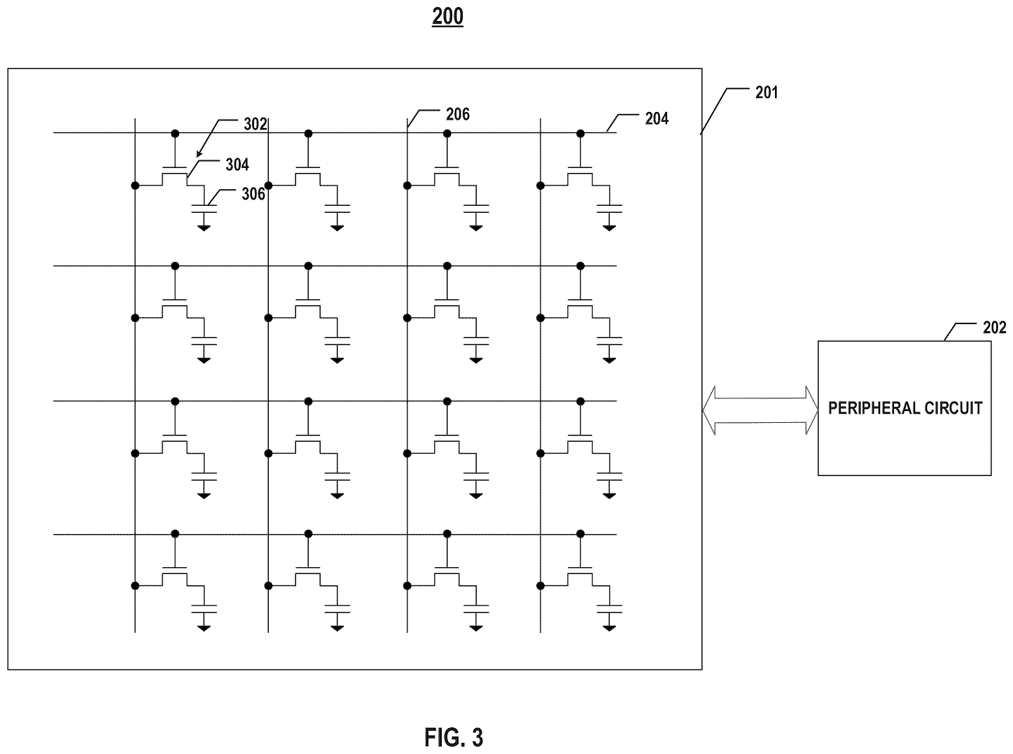

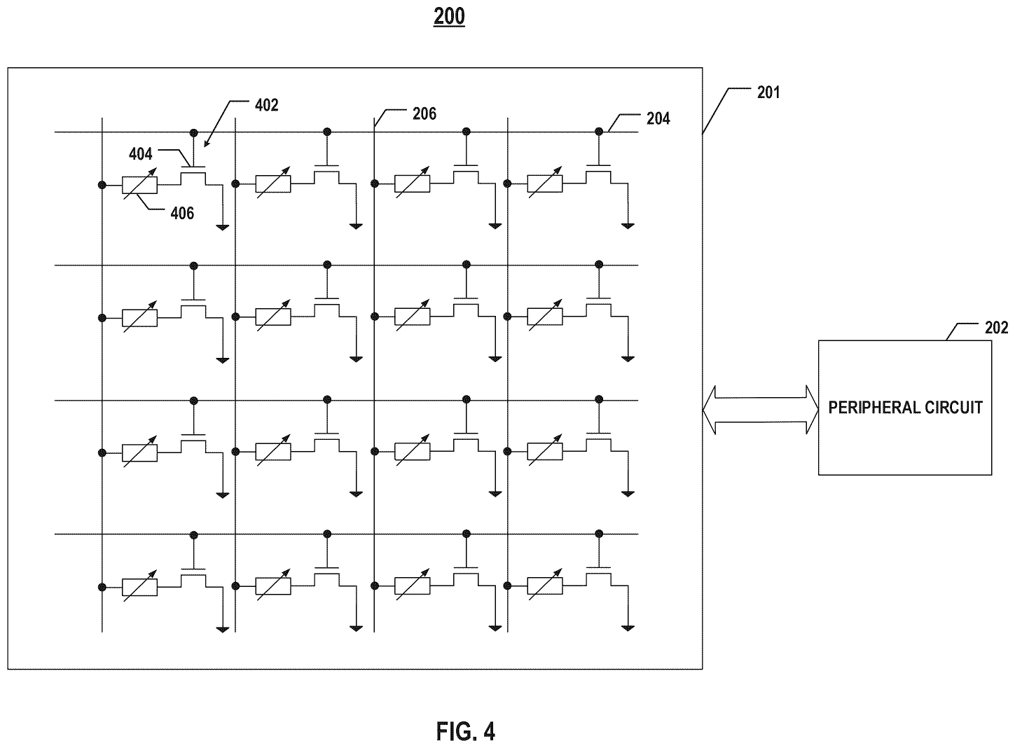

As shown in FIG. 2, storage unit 212 can be coupled to the source or the drain of vertical transistor 210. Storage unit 212 can include any devices that are capable of storing binary data (e.g., 0 and 1), including but not limited to, capacitors for DRAM cells and FRAM cells, and PCM elements for PCM cells. In some implementations, vertical transistor 210 controls the selection and/or the state switch of the respective storage unit 212 coupled to vertical transistor 210. In some implementations as shown in FIG. 3, each memory cell 208 is a DRAM cell 302 including a transistor 304 (e.g., implementing using vertical transistors 210 in FIG. 2) and a capacitor 306 (e.g., an example of storage unit 212 in FIG. 2). The gate of transistor 304 (e.g., corresponding to gate electrode 220) may be coupled to word line 204, one of the source and the drain of transistor 304 may be coupled to bit line 206, the other one of the source and the drain of transistor 304 may be coupled to one electrode of capacitor 306, and the other electrode of capacitor 306 may be coupled to the ground. In some implementations as shown in FIG. 4, each memory cell 208 is a PCM cell 402 including a transistor 404 (e.g., implementing using vertical transistors 210 in FIG. 2) and a PCM element 406 (e.g., an example of storage unit 212 in FIG. 2). The gate of transistor 404 (e.g., corresponding to gate electrode 220) may be coupled to word line 204, one of the source and the drain of transistor 404 may be coupled to the ground, the other one of the source and the drain of transistor 404 may be coupled to one electrode of PCM element 406, and the other electrode of PCM element 406 may be coupled to bit line 206.

Peripheral circuits 202 can be coupled to memory cell array 201 through bit lines 206, word lines 204, and any other suitable metal wirings. As described above, peripheral circuits 202 can include any suitable circuits for facilitating the operations of memory cell array 201 by applying and sensing voltage signals and/or current signals through word lines 204 and bit lines 206 to and from each memory cell 208. Peripheral circuits 202 can include various types of peripheral circuits formed using CMOS technologies.

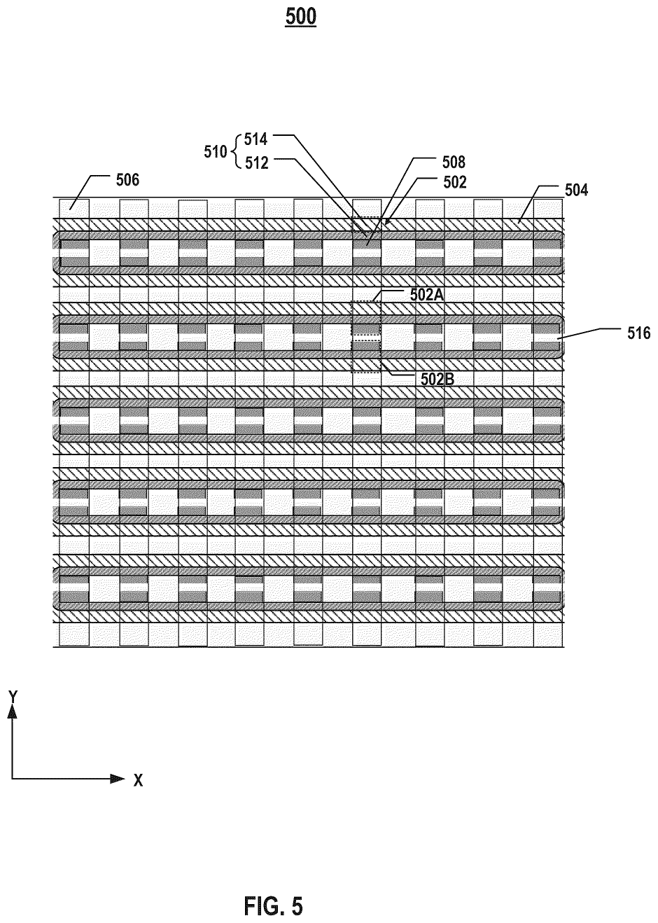

According to some aspects of the present disclosure, the vertical transistors of memory cells in a semiconductor device (e.g., semiconductor device 200) are single-gate transistors, and the gate dielectrics of vertical transistors in the word line direction are continuous. For example, FIG. 5 illustrates a plan view of still another array of memory cells 502 each including a vertical transistor in a semiconductor device 500, according to some aspects of the present disclosure. As shown in FIG. 5, semiconductor device 500 can include a plurality of word lines 504 each extending in a first lateral direction (the x-direction, referred to as the word line direction). Semiconductor device 500 can also include a plurality of bit lines 506 each extending in a second lateral direction perpendicular to the first lateral direction (the y-direction, referred to as the bit line direction). It is understood that FIG. 5 does not illustrate a cross-section of semiconductor device 500 in the same lateral plane, and word lines 504 and bit lines 506 may be formed in different lateral planes for ease of routing as described below in detail.

Memory cells 502 can be formed at the intersections of word lines 504 and bit lines 506. In some implementations, each memory cell 502 includes a vertical transistor (e.g., vertical transistor 210 in FIG. 2) having a semiconductor layer 508 and a gate structure 510. Semiconductor layer 508 can extend in a substrate in the vertical direction (the z-direction, not shown) perpendicular to the first and second lateral directions. The vertical transistor can be a single-gate transistor in which gate structure 510 is coupled with a single side (e.g., one of four sides in FIG. 5) of semiconductor layer 508 (the active region in which channels are formed). As shown in FIG. 5, the vertical transistor is a single-gate transistor in which gate structure 510 abuts one side of semiconductor layer 508 (having a rectangle or square-shaped cross-section) in the bit line direction (the y-direction) in the plan view. Gate structure 510 does not surround and contact other three sides of semiconductor layer 508, according to some implementations. Gate structure 510 can include a gate dielectric 512 abuts one side of semiconductor layer 508 in the plan view, and a gate electrode 514 coupled with gate dielectric 512. In some implementations, gate dielectric 512 is laterally between gate electrode 514 and semiconductor layer 508 in the bit line direction (the y-direction). As described above, gate electrode 514 may be part of word line 504, and word line 504 may be an extension of gate electrode 514. That is, gate electrodes 514 of adjacent vertical transistors in the word line direction (the x-direction) are continuous, e.g., parts of a continuous conductive layer having gate electrodes 514.

As shown in FIG. 5, gate dielectrics 512 of adjacent vertical transistors in the word line direction are continuous, e.g., parts of a continuous dielectric layer having gate dielectrics 512 and extending in the word line direction to abut vertical transistors in the same row on the same side. Gate structures 510 can be thus viewed as parts of a continuous structure extending in the word line direction at which the continuous structure abut vertical transistors in the same row on the same side.

As shown in FIG. 5, two adjacent vertical transistors of memory cells (e.g., 502A and 502B) in the bit line direction (the y-direction) are mirror-symmetric to one another, according to some implementations. As described below with respect to the fabrication process, semiconductor layers 508 of each pair of two adjacent vertical transistors of memory cells (e.g., 502A and 502B) in the bit line direction (the y-direction) can be formed by separating a semiconductor pillar into two pieces using a trench isolation 516 extending in the word line direction (the x-direction) and in parallel with word lines 504. Trench isolations 516 and word lines 504 can be disposed in an interleaved manner in the bit line direction. In some implementations, trench isolation 516 is formed in the middle of the semiconductor pillars (not shown) such that the resulting pair of semiconductor layers 508 are mirror-symmetric to one another with respect to trench isolation 516, so are the pair of vertical transistors having semiconductor layers 508 when the respective gate structures 510 are mirror-symmetric to one another with respect to trench isolation 516 as well.

It is understood that in some examples, trench isolations 516 extending in the word line directions may not be formed such that two adjacent semiconductor layers 508 separated by a respective trench isolation 516 may be merged as a single semiconductor layer having two opposite sides in the bit line direction coupled with gate structure 510. That is, without trench isolations 516, the adjacent single-gate vertical transistors may be merged to form a double-gate vertical transistor with increased gate control area and lower leakage current. The gate structure of the double-gate vertical transistor may include two mirror-symmetric gate structures 510 in FIG. 5, such that both sides of the merged semiconductor layer 508 in the bit line direction may be coupled with the gate structure in the double-gate vertical transistor. On the other hand, by splitting the double-gate vertical transistors into single-gate vertical transistors using trench isolations 516, the number of memory cells 502 (and the cell density) in the bit line direction can be doubled compared to double-gate vertical transistors without unduly complexing the fabrication process (e.g., compared with using SADP process).

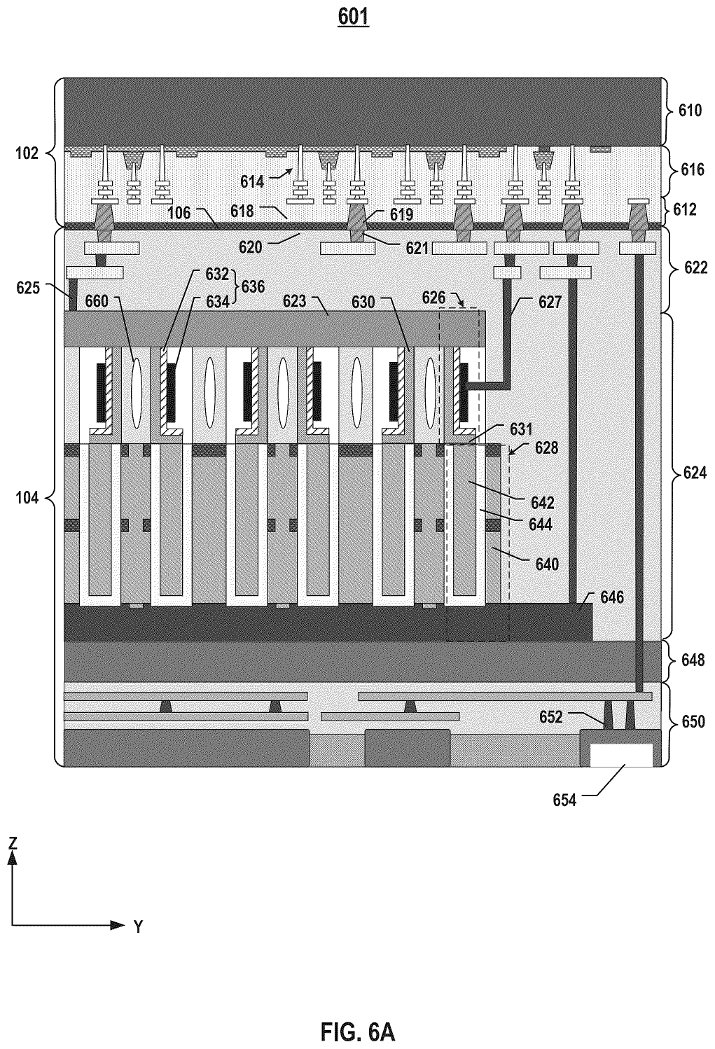

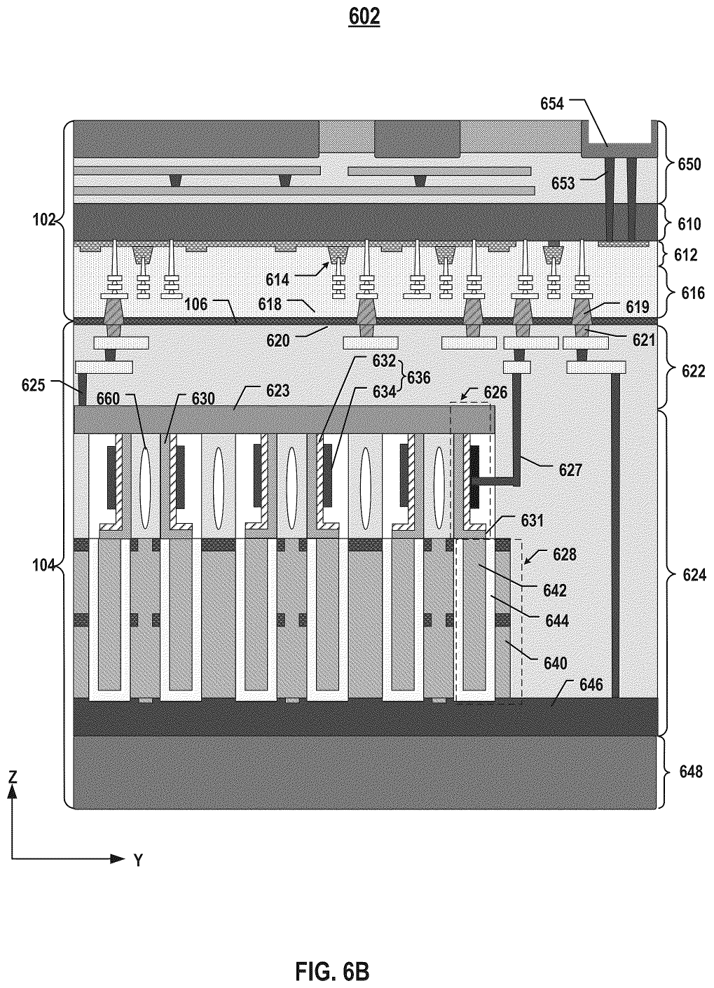

FIG. 6A illustrates a side view of a cross-section of a semiconductor device 601 including vertical transistors, according to some aspects of the present disclosure. It is understood that FIG. 6A is for illustrative purposes only and may not necessarily reflect the actual device structure (e.g., interconnections) in practice. As one example of semiconductor device 100 described above with respect to FIG. 1A, semiconductor device 601 is a bonded chip including first semiconductor structure 102 and second semiconductor structure 104 stacked over first semiconductor structure 102. First and second semiconductor structures 102 and 104 are jointed at bonding interface 106 therebetween, according to some implementations. As shown in FIG. 6A, first semiconductor structure 102 can include a substrate 610, which can include silicon (e.g., single crystalline silicon, c-Si), silicon germanium (SiGe), gallium arsenide (GaAs), germanium (Ge), silicon-on-insulator (SOI), or any other suitable materials.

First semiconductor structure 102 can include peripheral circuits 612 on substrate 610. In some implementations, peripheral circuits 612 includes a plurality of transistors 614 (e.g., planar transistors and/or semiconductor transistors). Trench isolations (e.g., shallow trench isolations (STIs)) and doped regions (e.g., wells, sources, and drains of transistors 614) can be formed on or in substrate 610 as well.

In some implementations, first semiconductor structure 102 further includes an interconnect layer 616 above peripheral circuits 612 to transfer electrical signals to and from peripheral circuits 612. Interconnect layer 616 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 616 can further include one or more interlayer dielectric (ILD) layers (also known as “intermetal dielectric (IMD) layers”) in which the interconnect lines and via contacts can form. That is, interconnect layer 616 can include interconnect lines and via contacts in multiple ILD layers. In some implementations, peripheral circuits 612 are coupled to one another through the interconnects in interconnect layer 616. The interconnects in interconnect layer 616 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 6A, first semiconductor structure 102 can further include a bonding layer 618 at bonding interface 106 and above interconnect layer 616 and peripheral circuits 612. Bonding layer 618 can include a plurality of bonding contacts 619 and dielectrics electrically isolating bonding contacts 619. Bonding contacts 619 can include conductive materials, such as Cu. The remaining area of bonding layer 618 can be formed with dielectric materials, such as silicon oxide. Bonding contacts 619 and surrounding dielectrics in bonding layer 618 can be used for hybrid bonding. Similarly, as shown in FIG. 6A, second semiconductor structure 104 can also include a bonding layer 620 at bonding interface 106 and above bonding layer 618 of first semiconductor structure 102. Bonding layer 620 can include a plurality of bonding contacts 621 and dielectrics electrically isolating bonding contacts 621. Bonding contacts 621 can include conductive materials, such as Cu. The remaining area of bonding layer 620 can be formed with dielectric materials, such as silicon oxide. Bonding contacts 621 and surrounding dielectrics in bonding layer 620 can be used for hybrid bonding. Bonding contacts 621 are coupled with bonding contacts 619 at bonding interface 106, according to some implementations.

Second semiconductor structure 104 can be bonded on top of first semiconductor structure 102 in a face-to-face manner at bonding interface 106. In some implementations, bonding interface 106 is disposed between bonding layers 620 and 618 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 106 is the place at which bonding layers 620 and 618 are met and bonded. In practice, bonding interface 106 can be a layer with a certain thickness that includes the top surface of bonding layer 618 of first semiconductor structure 102 and the bottom surface of bonding layer 620 of second semiconductor structure 104.

In some implementations, second semiconductor structure 104 further includes an interconnect layer 622 including bit lines 623 above bonding layer 620 to transfer electrical signals. Interconnect layer 622 can include a plurality of interconnects, such as MEOL interconnects and BEOL interconnects. In some implementations, the interconnects in interconnect layer 622 also include local interconnects, such as bit lines 623 (e.g., an example of bit lines 506 in FIG. 5), bit line contacts 625 (which may be omitted in some examples), word line contacts 627, and capacitor contacts 629. Interconnect layer 622 can further include one or more ILD layers in which the interconnect lines and via contacts can form. The interconnects in interconnect layer 622 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof. In some implementations, peripheral circuits 612 includes a word line driver/row decoder coupled to word line contacts 627 in interconnect layer 622 through bonding contacts 621 and 619 in bonding layers 620 and 618 and interconnect layer 616. In some implementations, peripheral circuits 612 includes a bit line driver/column decoder coupled to bit lines 623 and bit line contacts 625 in interconnect layer 622 through bonding contacts 621 and 619 in bonding layers 620 and 618 and interconnect layer 616.

In some implementations, second semiconductor structure 104 includes a DRAM device in which memory cells are provided in the form of an array of DRAM cells 624 (e.g., an example of memory cells 502 in FIG. 5) above interconnect layer 622 and bonding layer 620. That is, interconnect layer 622 including bit lines 623 can be disposed between bonding layer 620 and array of DRAM cells 624. It is understood that the cross-section of semiconductor device 601 in FIG. 6A may be made along the bit line direction (the y-direction), and one bit line 623 in interconnect layer 622 extending laterally in the y-direction may be coupled to a column of DRAM cells 624.

Each DRAM cell 624 can include a vertical transistor 626 (e.g., an example of vertical transistors 210 in FIG. 2) and capacitor 628 (e.g., an example of storage unit 212 in FIG. 2) coupled to the vertical transistor 626. DRAM cell 624 can be a 1T1C cell consisting of one transistor and one capacitor. It is understood that DRAM cell 624 may be of any suitable configurations, such as 2T1C cell, 3T1C cell, etc.

Vertical transistor 626 can be a MOSFET used to switch a respective DRAM cell 624. In some implementations, vertical transistor 626 includes a semiconductor layer 630 (i.e., the active region in which multiple channels can form) extending vertically (in the z-direction), and a gate structure 636 coupled with a plurality of sides of semiconductor layer 630. In some implementations, a leakage value of the semiconductor layer 630 is lower than a pico-ampere, for example, semiconductor layer 630 can include a metal oxide semiconductor material. The orbitals in the conduction band of metal oxide semiconductor are usually overlapped with each other, and the carrier mobility is less affected by the ordering degree of thin film material, thus the mobility of metal oxide semiconductor is about 1˜100 cm²·V⁻¹·s⁻¹, which is much higher than silicon. Therefore, metal oxide semiconductors have better electrical uniformity than silicon. The process temperature of metal oxide semiconductors is low and can be compatible with the a-Si thin film transistor (TFT) process, making it possible to fabricate on a flexible plastic substrate. It can also realize low-cost manufacturing since no ion implantation and crystallization equipment is needed. In a vertical structure, metal oxide semiconductors have some merits that others do not have, such as achieving short channel, reducing the device area, and suppressing mechanical stress in a flexible substrate. When the cracks are generated by compressive and tensile strain in the channel layer, the carriers could still be transported in the vertical direction. This structure has great potential for flexible application. In present implementation, the semiconductor layer can be one or more of indium gallium zinc oxide (InₓGa_{y}Zn_{z}O), indium gallium silicon oxide (InₓGa_{y}Si_{z}O), indium stannum zinc oxide (InₓSn_{y}Zn_{z}O), indium zinc oxide (InₓZn_{y}O), zinc oxide (ZnₓO), zinc stannum oxide (ZnₓSn_{y}O), zinc oxide nitride (ZnₓO_{y}N), zirconium zinc stannum oxide (ZrₓZn_{y}Sn_{z}O), stannum oxide (SnₓO), hafnium indium zinc oxide (HfₓIn_{y}Zn_{z}O), gallium zinc stannum oxide (GaₓZn_{y}Sn_{z}O), aluminum zinc stannum oxide (AlₓZn_{y}Sn_{z}O), ytterbium gallium zinc oxide (YbₓGa_{y}Zn_{z}O), indium gallium oxide (InₓGa_{y}O), etc.

As shown in FIG. 6A, in some implementations, semiconductor layer 630 has two ends (the upper end and lower end) in the vertical direction (the z-direction), and both ends extend beyond gate structure 636, respectively, in the vertical direction (the z-direction) into ILD layers. That is, semiconductor layer 630 can have a larger vertical dimension (e.g., the depth) than that of gate structure 636 (e.g., in the z-direction), and neither the upper end nor the lower end of semiconductor layer 630 is flush with the respective end of gate structure 636. Thus, short circuits between bit lines 623 and word lines/gate electrodes 634 or between word lines/gate electrodes 634 and capacitors 628 can be avoided.

As shown in FIG. 6A, in some implementations, an extending portion 631 extends along the second lateral direction (the y-direction) from an end of semiconductor layer 630 and extending portion 631 is coupled with the capacitor 628. That is, a contact area between capacitor 628 and vertical transistor 626 equals an area of extending portion 631 on the x-y plane, which is tens of times than an area of an end of semiconductor layer 630 on the x-y plane, the contact resistance can be reduced significantly due to the increasement of contact area. In some implementations, the two ILD layers into which semiconductor layer 630 extends (e.g., the ILD layer vertically between bit line contacts 625 and word lines 634, and the ILD layer vertically between word lines 634 and capacitors 628) include the same dielectric material, such as silicon oxide. Vertical transistor 626 can further include a source and a drain disposed at the two ends (the upper end and lower end) of semiconductor layer 630, respectively, in the vertical direction (the z-direction). In some implementations, one of source and drain (e.g., at the upper end in FIG. 6A) is coupled to capacitor 628, and the other one of source and drain (e.g., at the lower end in FIG. 6A) is coupled to bit line 623 (e.g., through bit line contact 625 or directly). Source and drain can be doped with N-type dopants (e.g., P or As) or P-type dopants (e.g., B or Ga) at a desired doping level.

In some implementations, gate structure 636 includes a gate dielectric 632 and a gate electrode 634. In some implementations, gate dielectric 632 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, gate electrode 634 includes conductive materials including, but not limited to W, Co, Cu, Al, TiN, TaN, polysilicon, silicide, or any combination thereof. In some implementations, gate electrode 634 includes multiple conductive layers, such as a W layer over a TiN layer. In one example, gate structure 636 may be a “gate oxide/gate poly” gate in which gate dielectric 632 includes silicon oxide and gate electrode includes doped polysilicon. In another example, gate structure 636 may be a high-k metal gate (HKMG) in which gate dielectric 632 includes a high-k dielectric and gate electrode includes a metal.

As described above, since gate electrode 634 may be part of a word line or extend in the word line direction (e.g., the x-direction in FIG. 5) as a word line, although not directly shown in FIG. 6A, second semiconductor structure 104 of semiconductor device 601 can also include a plurality of word lines (e.g., an example of word lines 504 in FIG. 5, referred to as 634 as well) each extending in the word line direction (the x-direction). Each word line 634 can be coupled to a row of DRAM cells 624. That is, bit line 623 and word line 634 can extend in two perpendicular lateral directions, and semiconductor layer 630 of vertical transistor 626 can extend in the vertical direction perpendicular to the two lateral directions in which bit line 623 and word line 634 extend. Word lines 634 are coupled with word line contacts 627 in the x-direction and word line contacts 627 are coupled with word lines 634 at an end of each word line 634 in the x-direction, according to some implementations. The relevant location of the word line contacts 627 and word lines 634 in FIGS. 6A and 6B are illustrative and should not be interpreted as a limitation of the present disclosure. In some implementations, word lines 634 include conductive materials including, but not limited to W, Co, Cu, Al, TiN, TaN, polysilicon, silicide, or any combination thereof. In some implementations, word line 634 includes multiple conductive layers, such as a W layer over a TiN layer.

As shown in FIG. 6A, vertical transistor 626 extends vertically through and is coupled with a corresponding word line 634, and source or drain of vertical transistor 626 at the lower end thereof is coupled with bit line contact 625 or coupled with bit line 623 directly, according to some implementations. Accordingly, word lines 634 and bit lines 623 can be disposed in different planes in the vertical direction due to the vertical arrangement of vertical transistor 626, which simplifies the routing of word lines 634 and bit lines 623. In some implementations, bit lines 623 are disposed vertically between bonding layer 620 and word lines 634, and word lines 634 are disposed vertically between bit lines 623 and capacitors 628. Word lines 634 can be coupled to peripheral circuits 612 in first semiconductor structure 102 through word line contacts 627 in interconnect layer 622, bonding contacts 621 and 619 in bonding layers 620 and 618, and the interconnects in interconnect layer 616. Similarly, bit lines 623 in interconnect layer 622 can be coupled to peripheral circuits 612 in first semiconductor structure 102 through bonding contacts 621 and 619 in bonding layers 620 and 618 and the interconnects in interconnect layer 616.

In some implementations, the rows of vertical transistors 626 separated by trench isolation 660 are mirror-symmetric to one another with respect to trench isolation 660. Trench isolation 660 can be formed with dielectric materials including, but not limited to, silicon oxide, silicon nitride, silicon oxynitride, low-k dielectrics, or any combination thereof. It is understood that trench isolation 660 may include an air gap each disposed laterally between adjacent semiconductor layers 630. As described below with respect to the fabrication process, air gaps may be formed due to the relatively small pitches of vertical transistors 626 in the bit line direction (e.g., the y-direction). On the other hand, the relatively large dielectric constant of air in air gaps (e.g., about 4 times the dielectric constant of silicon oxide) can improve the insulation effect between vertical transistors 626 compared with some dielectrics (e.g., silicon oxide). Similarly, in some implementations, air gaps are formed laterally between word lines/gate electrodes 634 in the bit line direction as well, depending on the pitches of word lines/gate electrodes 634 in the bit line direction.

As shown in FIG. 6A, in some implementations, capacitor 628 includes a first electrode 642 above and coupled with source or drain of vertical transistor 626, a capacitor dielectric 644 above and coupled with first electrode 642, and a second electrode 640 above and coupled with capacitor dielectric 644. That is, capacitor 628 can be a vertical capacitor in which first and second electrodes 642 and 640 and capacitor dielectric 644 are stacked vertically (in the z-direction), and capacitor dielectric 644 can be sandwiched between first and second electrodes 642 and 640. In some implementations, each first electrode 642 is coupled to source or drain of a respective vertical transistor 626 in the same DRAM cell, while all second electrodes 640 are parts of a common plate 646 coupled to the ground, e.g., a common ground.

As shown in FIG. 6A, vertical transistor 626 extends vertically through and is coupled with a corresponding word line 634, source or drain of vertical transistor 626 thereof is coupled with bit line contact or coupled with bit line 623 directly. That is, bit line 623 and capacitor 628 can be disposed in different planes in the vertical direction and coupled to opposite ends of vertical transistor 626 of DRAM cell 624 in the vertical direction due to the vertical arrangement of vertical transistor 626. In some implementations, bit line 623 and capacitor 628 are disposed on opposite sides of vertical transistor 626 in the vertical direction, which simplifies the routing of bit lines 623 and reduces the coupling capacitance between bit lines 623 and capacitors 628 compared with conventional DRAM cells in which the bit lines and capacitors are disposed on the same side of the planar transistors.

As shown in FIG. 6A, in some implementations, vertical transistors 626 are disposed vertically between capacitors 628 and bonding interface 106. That is, vertical transistors 626 can be arranged closer to peripheral circuits 612 of first semiconductor structure 102 and bonding interface 106 than capacitors 628. Since bit lines 623 and capacitors 628 are coupled to opposite ends of vertical transistors 626, as described above, bit lines 623 (as part of interconnect layer 622) are disposed vertically between vertical transistors 626 and bonding interface 106, according to some implementations. As a result, interconnect layer 622 including bit lines 623 can be arranged close to bonding interface 106 to reduce the interconnect routing distance and complexity.

In some implementations, second semiconductor structure 104 further includes a substrate 648 disposed above DRAM cells 624. As described below with respect to the fabrication process, substrate 648 can be part of a carrier wafer. It is understood that in some examples, substrate 648 may not be included in second semiconductor structure 104.

As shown in FIG. 6A, second semiconductor structure 104 can further include a pad-out interconnect layer 650 above substrate 648 and DRAM cells 624. Pad-out interconnect layer 650 can include interconnects, e.g., contact pads 654, in one or more ILD layers. Pad-out interconnect layer 650 and interconnect layer 622 can be formed on opposite sides of DRAM cells 624. Capacitors 628 are disposed vertically between vertical transistors 626 and pad-out interconnect layer 650, according to some implementations. In some implementations, the interconnects in pad-out interconnect layer 650 can transfer electrical signals between semiconductor device 601 and outside circuits, e.g., for pad-out purposes. In some implementations, second semiconductor structure 104 further includes one or more contacts 652 extending through part of pad-out interconnect layer 650 to couple pad-out interconnect layer 650 to interconnect layer 622. Peripheral circuits 612 can be coupled to DRAM cells 624 through interconnect layers 616 and 622 as well as bonding layers 620 and 618. Peripheral circuits 612 and DRAM cells 624 can be coupled to outside circuits through contacts 652 and pad-out interconnect layer 650. Contact pads 654 and contacts 652 can include conductive materials including, but not limited to, W, Co, Cu, Al, silicides, or any combination thereof. In one example, contact pad 654 may include Al, and contact 652 may include W. In some implementations, contact 652 includes a via surrounded by a dielectric spacer (e.g., having silicon oxide) to electrically separate the via from substrate 648. Depending on the thickness of substrate 648, contact 652 can be an interlayer via (ILV) having a depth in the submicron-level (e.g., between 10 nm and 1 μm), or a through substrate via (TSV) having a depth in the micron- or tens micron-level (e.g., between 1 μm and 100 μm).

It is understood that the pad-out of semiconductor devices is not limited to from second semiconductor structure 104 having DRAM cells 624 as shown in FIG. 6A and may be from first semiconductor structure 102 having peripheral circuit 612. For example, as shown in FIG. 6B, a semiconductor device 602 may include pad-out interconnect layer 650 in first semiconductor structure 102. Pad-out interconnect layer 650 can be disposed above and coupled with substrate 610 of first semiconductor structure 102 on which transistors 614 of peripheral circuit 612 are formed. In some implementations, first semiconductor structure 102 further includes one or more contacts 653 extending vertically to substrate 610. In some implementations, contact 653 couples the interconnects in interconnect layer 616 in first semiconductor structure 102 to contact pads 654 in pad-out interconnect layer 650 to make an electrical connection through substrate 610. Contacts 653 can include conductive materials including, but not limited to, W, Co, Cu, Al, silicide, or any combination thereof. In one example, contact 653 may include W. In some implementations, contact 653 includes a via surrounded by a dielectric spacer (e.g., having silicon oxide) to electrically separate the via from substrate 610. It is understood that in some examples, substrate 610 in FIG. 6B may be a thinned substrate, e.g., compared with substrate 610 in FIG. 6A. Depending on the thickness of substrate 610, contact 653 can be an ILV having a depth in the submicron-level (e.g., between 10 nm and 1 μm), or a TSV having a depth in the micron- or tens micron-level (e.g., between 1 μm and 100 μm). It is understood that the details of the same components (e.g., materials, fabrication process, functions, etc.) in both semiconductor devices 601 and 602 are not repeated for ease of description. Pad-out from first semiconductor structure 102 including peripheral circuits 612 can reduce the interconnect distance between contact pad 654 and peripheral circuits 612, thereby decreasing the parasitic capacitance from the interconnects and improving the electrical performance of semiconductor device 602.

It is also understood that the relative vertical positions between the semiconductor layer 630 and the respective gate structure 636 and word lines 634 are not limited to the example shown in FIG. 6A in which both the upper and lower ends of semiconductor layer 630 extend beyond gate structure 636 (and word line 634), respectively, depending on the various fabrication processes as described below in detail. It is understood that the details of the same components (e.g., materials, fabrication process, functions, etc.) in both semiconductor devices 601 and 602 are not repeated for ease of description.

It is understood that the vertical transistors 626 in DRAM cells 624 are not limited to single-gate transistors as shown in FIG. 6A and FIG. 6B and may be double-gate transistors or gate-all-around transistors, the structure of which will be detailed below.

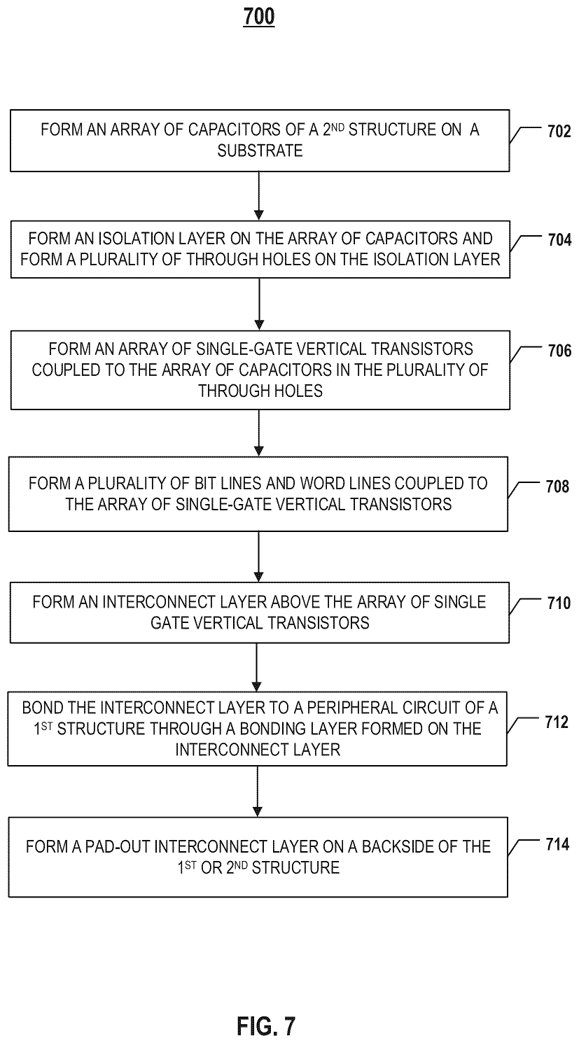

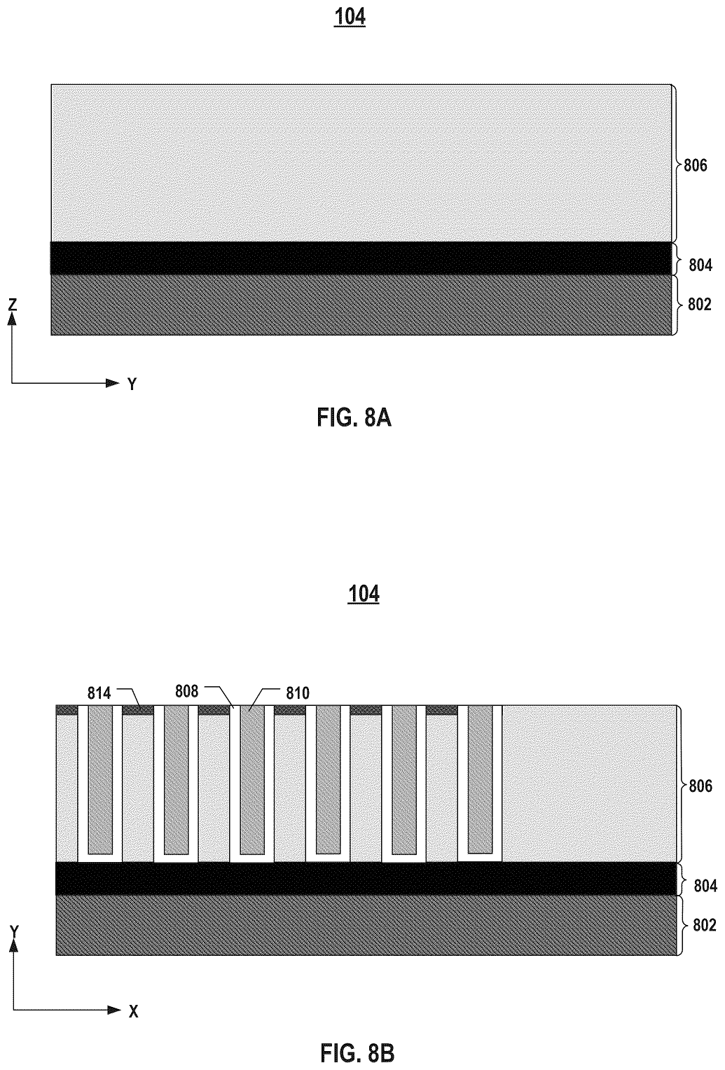

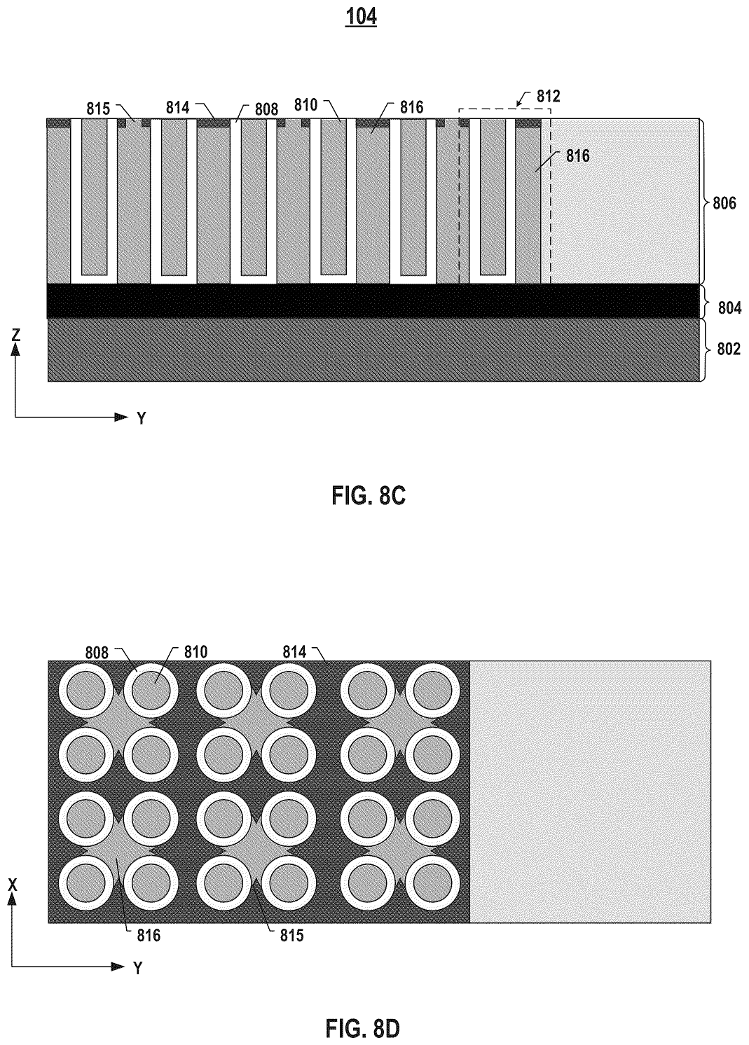

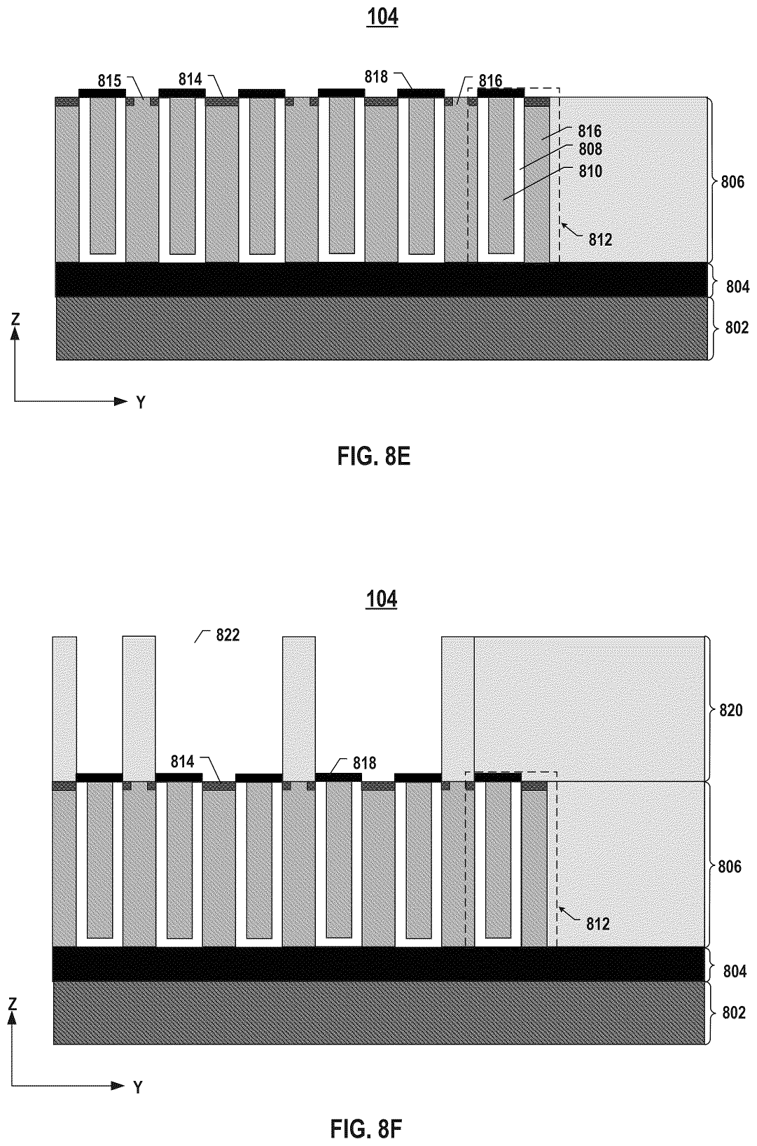

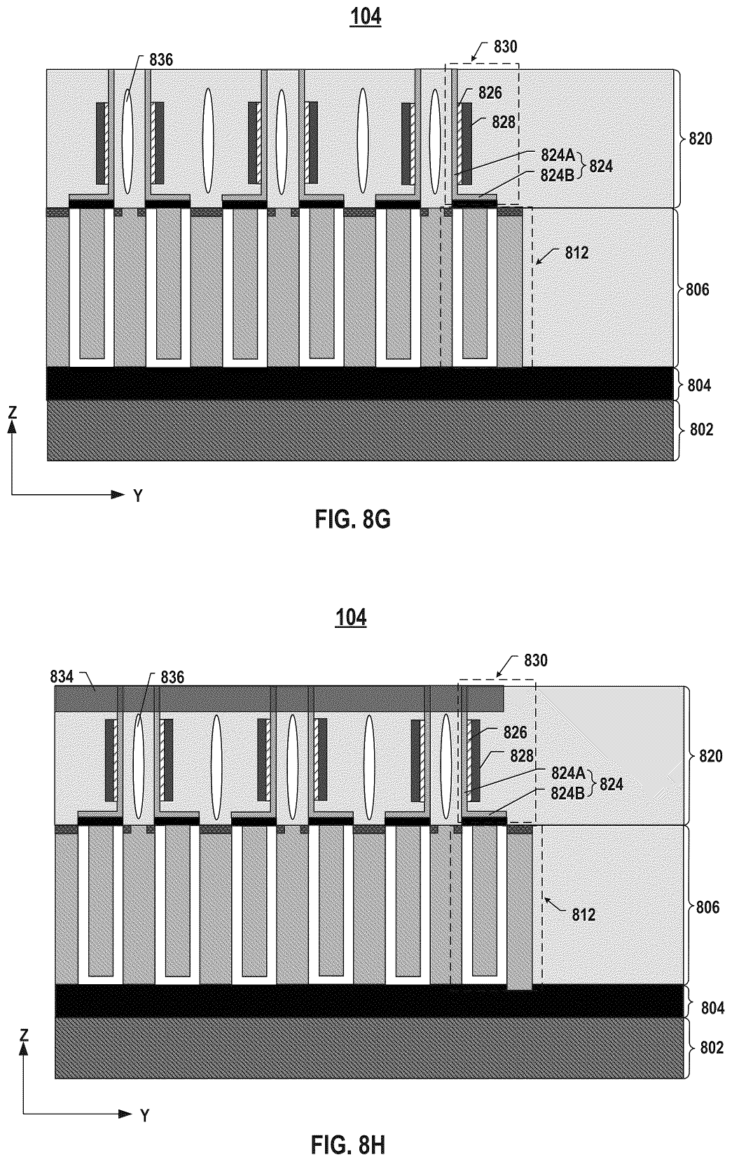

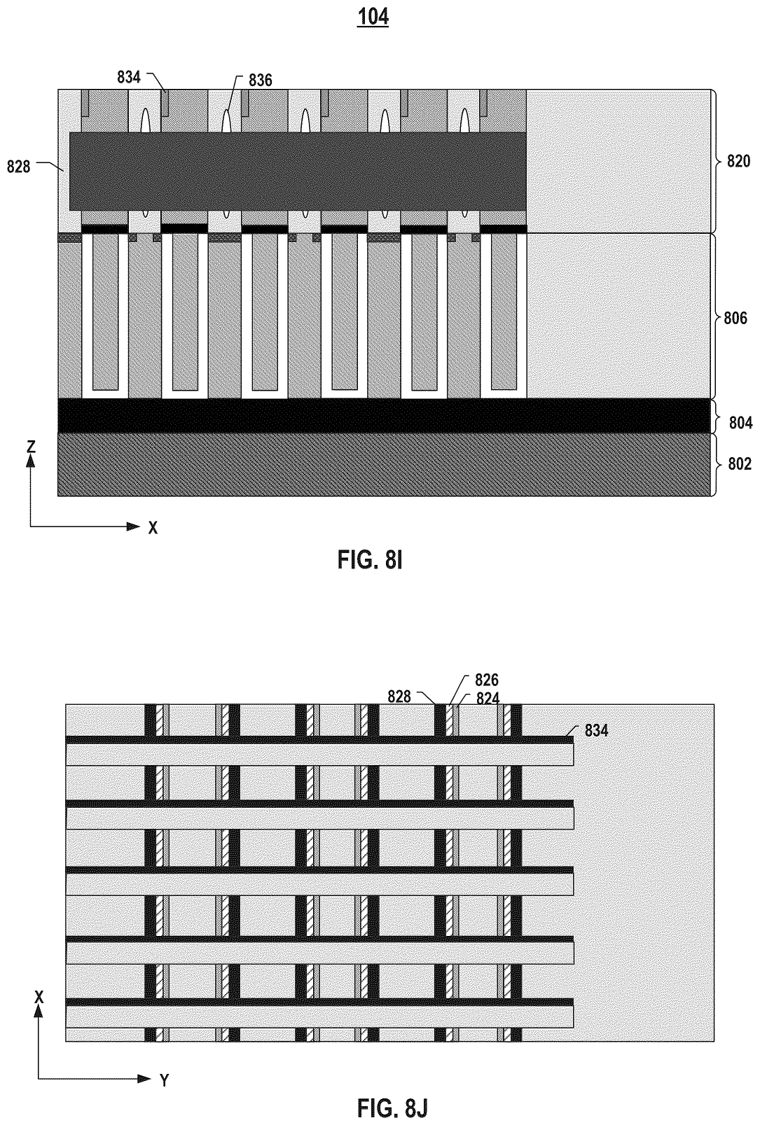

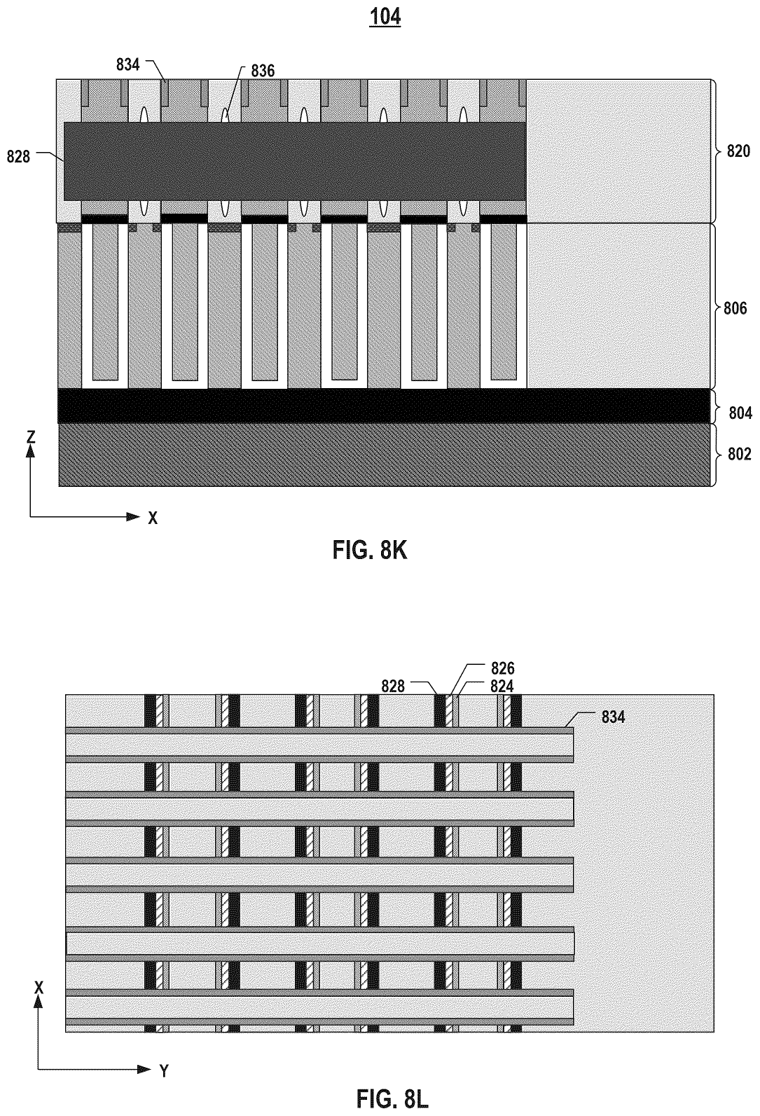

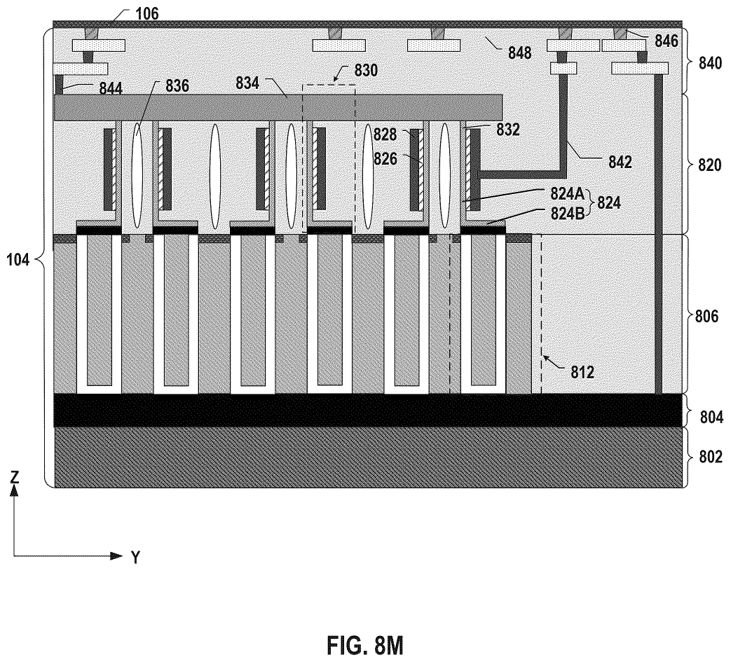

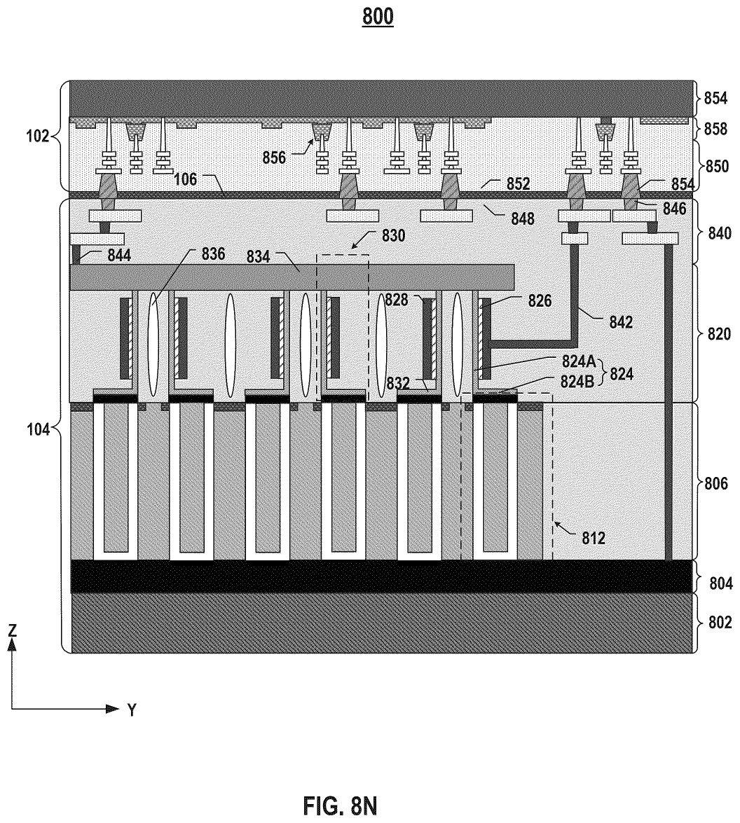

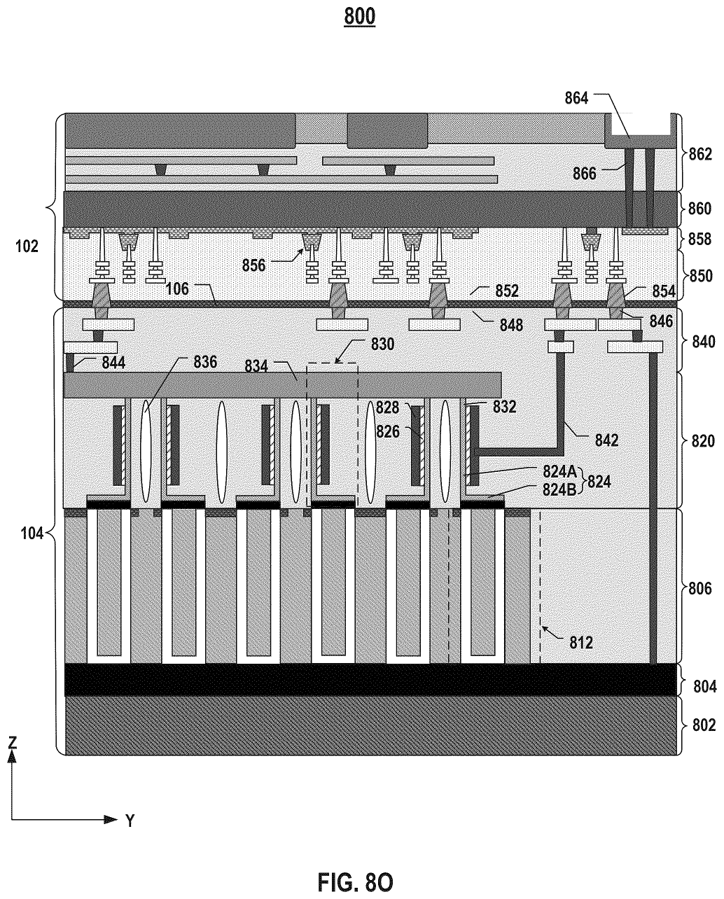

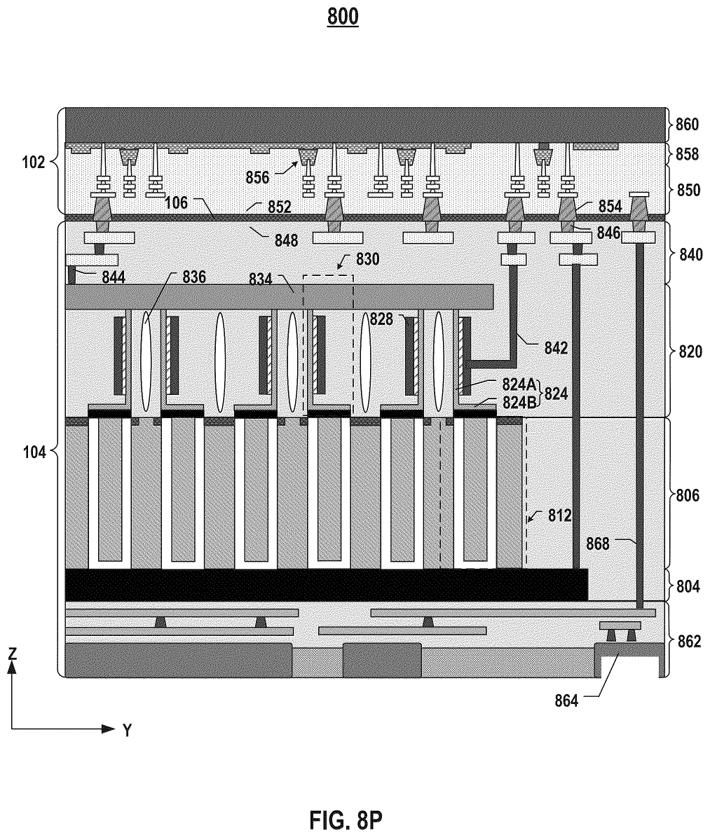

FIG. 7 illustrates a flowchart of a method 700 for forming a semiconductor device including single-gate vertical transistors, such as semiconductor device 601 described above in connection with FIG. 6A or semiconductor device 602 described above in connection with FIG. 6B, according to some implementations of the present disclosure. FIGS. 8A-8P illustrate a fabrication process for forming a semiconductor device 800 at certain fabricating stages of the method 700 shown in FIG. 7, according to various implementations of the present disclosure. It is understood that the operations shown in method 700 are not exhaustive and that other operations can be performed as well before, after, or between any of the illustrated operations. Further, some of the operations may be performed simultaneously, or in a different order than shown in FIG. 7.

As shown in FIG. 7, method 700 can start at operation 702, in which an array of capacitors 812 can be formed on a substrate 802. Referring to FIGS. 6A and 6B, the array of capacitors 812 is a part of second semiconductor structure 104 as discussed above. First semiconductor structure 102 and second semiconductor structure 104 can be formed separately through independent fabrication processes and will be bonded together after corresponding fabrication processes are completed. First semiconductor structure 102 may be formed before, after, or at the same time as second semiconductor structure 104. The sequence of the fabrication of first and second semiconductor structures 102 and 104 are not limited in the implementations of the present disclosure and can be arranged and adjusted according to practical needs.

In some implementations, a first step of operation 702 of method 700 is proceeded, as shown in FIG. 8A, in which a metal layer 804 is formed on first substrate 802 and a dielectric layer 806 is formed on metal layer 804, FIG. 8A illustrates a schematic side cross-sectional view of the semiconductor device in y-z plane after dielectric layer 806 is formed. Then a second step of operation 704 of method 700 proceeds, in which an array of through holes are formed on dielectric layer 806, then a capacitor dielectric 808 and a first electrode 810 of a capacitor 812 is formed in each of the through holes. FIG. 8B illustrates a schematic side cross-sectional view of the semiconductor device in y-z plane after first electrode 810 is formed.

In some implementations, the substrate 802 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the array of capacitors 812 can be formed directly on the semiconductor substrate 802, and the transistor can be formed on a front side of the array of capacitors 812 in subsequent processes. In some other implementations, the substrate 802 can be a carrier substrate, which can include any suitable semiconductor materials, or an electrically non-conductive material, such as a glass, a plastic, or a sapphire wafer. In such implementations, the array of capacitors 812 can be formed directly on another semiconductor substrate, and the carrier substrate 802 can be formed on a front side of the array of capacitors 812. After flipping over the structure and removing the semiconductor substrate, the transistor can be formed on a back side of the array of capacitors 812 in subsequent processes.

The array of capacitors 812 can include a second electrode 816 coupled to a common plate (i.e., metal layer 804), a plurality of first electrode 810, and a capacitor dielectric 808 between first electrodes 810 and second electrode 816. In some implementations, first electrodes 810 and/or the second electrode 816 can include conductive materials including, but not limited to, W, Co, Cu, Al, TiN, TaN, polysilicon, silicide, or any combination thereof. In some implementations, capacitor dielectric 808 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, capacitors 812 have a relatively large height and need to be mechanically stabilized with a mesh 814, as shown in FIG. 8C. As such, the spacing between capacitors 812 doesn't vary, thereby avoiding capacitor corrupts. Without mesh 814, the capacitors would lean over and contact adjacent capacitors. Mesh 814 includes larger dielectric materials with a Mohs scale larger than silicon oxide, which has a Mohs scale around six. In some implementations, mesh 814 can be silicon nitride, silicon carbide, corundum, boron carbide, boron nitride, or any combination thereof. In some implementations, with the increasement of the aspect ratio of the capacitors 812, two or more levels of mesh are required for mechanical stability. FIG. 8C illustrates a schematic side cross-sectional view of the semiconductor device in y-z plane after mesh 814 is formed. FIG. 8D illustrates a schematic side cross-sectional view of the semiconductor device in x-y plane after mesh 814 is formed. In some implementations, an opening 815 is formed on mesh 814 among a group of capacitors 812, and each capacitor is connected to at least one opening 815, as shown in FIG. 8D, every four capacitors 812 in a same group share a same opening 815. In the present implementation, opening 815 can be an irregular polygon, as shown in FIG. 8D. In some implementations, opening 815 can be, but not limited to, round, oval, triangle, rectangular, hexagonal, or other shapes. The number of capacitors in the same group can be set as needed, for example four, six, eight, etc. In some implementations, dielectric layer 806, also called sacrifice layer, positioned under mesh 814 can be replaced by a conductor to form second electrode 816 electrically connected with the common plate (i.e., metal layer) 804. The sacrifice layer can be moved by wet/dry etch, or any other suitable processes, and second electrode 816 includes conductive materials including, but not limited to, W, Co, Cu, Al, TiN, TaN, polysilicon, silicide, or any combination thereof.

In some implementations, the array of capacitors 812 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc. It is noted that, the fabricating processes and/or orders of forming first electrodes 810, second electrode 816, and the capacitor dielectric 808 can be varied depending on a front side process or a back side process.

In some implementations, to suppress drain induced barrier lowering (DIBL), the doping concentration of substrate is increased, resulting in an increasement of the junction leakage current. The increased leakage current can consume more power and deteriorate the retention capability of a semiconductor device. To solve this problem, storage node contacts 818 are introduced on the top of capacitor 812 as shown in FIG. 8E, FIG. 8E illustrates a schematic side cross-sectional view of the semiconductor device in y-z plane after storage node contacts 818 are formed. Storage node contacts 818 can be made of doped amorphous silicon, doped polysilicon, doped single crystal silicon, or doped silicon germanium (Si_{X}Ge_{1-X}). Thus, the resistance between capacitor 812 and a corresponding vertical transistor can be controlled by adjusting the doping concentration of storage node contacts 818.

As shown in FIG. 7, method 700 can proceed to operation 704, in which an isolation layer 820 is formed on dielectric layer 806 and a plurality of through holes 822 are formed in isolation layer 820. FIG. 8F illustrates a schematic side cross-sectional view of the semiconductor device in y-z plane after operation 704 of method 700. As shown in FIG. 8F, each through hole 822 penetrates isolation layer 820 to expose a corresponding one of the plurality of storage node contacts 818. In some other implementations not shown in the figures, storage node contacts 818 can be omitted from the top of capacitor 812. In such implementations, capacitors 812 are directly exposed by through holes 822. It should be noted that storage node contacts 818 can also be formed after forming the isolation layer 820. Isolation layer 820 may be formed by one or more thin film deposition processes including, but not limited to, CVD, PVD, ALD, or any combination thereof. The sequence of the fabrication of storage node contacts 818 and isolation layer 820 are not limited in the implementations of the present disclosure and can be arranged and adjusted according to practical needs.

As shown in FIG. 7, method 700 can proceed to operation 706, in which a semiconductor layer 824, a gate dielectric layer 826, and a gate electrode 828 can be formed in each through hole 822 to form a vertical transistor 830. FIG. 8G illustrates a schematic side cross-sectional view of the semiconductor device in y-z plane after operation 706 of method 700.

As shown in FIG. 8G, vertical transistor 830 may be an example of a single-gate vertical transistor. Gate structure can be coupled with one side of semiconductor layer 824 (the active region in which channels are formed). Each vertical transistor 830 includes semiconductor layer 824 extending vertically from an end of through hole 822 where storage node contacts 818 are positioned to another end opposite to storage node contact 818.

In some implementations, semiconductor layer 824 has two ends (the upper end and lower end) in the vertical direction (the z-direction). The lower end of semiconductor layer 824 covers a corresponding storage node contact 818 or covers a top surface of a corresponding capacitor 812 when storage node contacts 818 are omitted. A vertical portion of semiconductor layer 824 can be used as the channel of vertical transistor 830. In some implementations, semiconductor layer 824 can be formed from a deposition process. In some implementations, the semiconductor can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

In some implementations, semiconductor layer 824 includes a vertical portion 824A extending along the vertical direction (i.e., the z-direction), and an extending portion 824B extending from an end of vertical portion 824A towards an adjacent vertical transistor along a second lateral direction (i.e., the y-direction). Extending portion 824B is coupled with the storage unit or the source node contact. Semiconductor 824 has an L-shaped cross-section on the y-z plane, as shown in FIG. 8G. With extending portion 824B, a length of semiconductor layer 824 is extended, and a contact area between a source of the vertical transistor and the storage unit or the source node contact is expanded as well.

In some implementations, as shown in FIG. 8G, vertical transistors in the memory cells are mirror single-gate (MSG) transistors, i.e., semiconductor layers of two adjacent vertical transistors are isolated by dielectric structure and gate structure of each vertical transistor is formed on a side away from the dielectric structure. Therefore, the gate structures of the two adjacent vertical transistors are mirror symmetrical. In MSG transistors, forming semiconductor layer 824 may start from epitaxially growing an initial semiconductor layer covering a bottom and the two opposite sidewalls of each of the through hole 822, i.e., covering the surface of through hole 822 by the initial semiconductor layer. A trench can be formed on the initial semiconductor layer on the bottom of the through hole to punch through the initial semiconductor layer into two separate semiconductor layers 824 of two adjacent vertical transistors. Each semiconductor layer 824 includes a vertical portion 824A and an extending portion 824B, as shown in FIG. 8G. A length of each extending portion 824B along y-direction is larger than or equal to a length of the corresponding source node contract along y-direction as long as the two adjacent extending portions 824B being isolated.

Gate dielectric layer 826 can be formed to cover semiconductor layer 824, in the present implementation, to cover extending portion 824B of semiconductor layer 824. Gate dielectric layer 826 can include any suitable dielectric materials, such as silicon oxide, silicon nitride, silicon oxynitride, or high-k dielectrics. For example, gate dielectric layer 826 may include silicon oxide, i.e., gate oxide, which can be formed during the fabricating of gate electrode 828 and has a same material as isolation layer 820. In some implementations, gate dielectric layer 826 can be high-k dielectrics including, but not limited to, Al₂O₃, HfO₂, Ta₂O₅, ZrO₂, TiO₂, or any combination thereof, which has a different material with isolation layer 820, as shown in FIG. 8G. Gate electrode 828 can be formed to cover gate dielectric layer 826. Gate electrode 828 can include any suitable conductive materials, such as polysilicon, metals (e.g., W, Cu, Al, etc.), metal compounds (e.g., TiN, TaN, etc.), or silicide. For example, gate electrode 828 may include doped polysilicon, i.e., a gate poly. In some implementations, gate electrode 828 includes multiple conductive layers, such as a W layer over a TiN layer.

In some implementations, at least one end of vertical portion 824A of semiconductor layer 824 extends beyond gate dielectric layer 826 in the vertical direction (the z-direction). In some implementations, one end of vertical portion 824A of semiconductor layer 824 is flush with the respective end of gate dielectric layer 826. In some implementations, both ends of semiconductor layer 824 extend beyond gate electrode 828, respectively, in the vertical direction (the z-direction). That is, semiconductor layer 824 can have a larger vertical dimension (e.g., the depth) than that of gate electrode 828. Vertical transistor 830 can further include a source and a drain disposed at the two ends of semiconductor layer 824, respectively, in the vertical direction. In some implementations, one of source and drain 832, i.e., extending portion 824B, is coupled to capacitor 812, and the other one of source and drain 832 is coupled to a bit line.

As shown in FIG. 7, method 700 can proceed to operation 708, in which a plurality of bit lines 834 and word lines 828 (referred to as gate electrodes 828 as well) can be formed on the array of vertical transistors 830. FIG. 8H illustrates a schematic side cross-sectional view of the semiconductor device in y-z plane after operation 708 of method 700. FIG. 8I illustrates a schematic side cross-sectional view of the semiconductor device in x-z plane after operation 708 of method 700. FIG. 8J illustrates a schematic side cross-sectional view of the semiconductor device in x-y plane after operation 708 of method 700.

As shown in FIGS. 8H and 8I, vertical transistor 830 extends vertically through and is coupled with a corresponding word line 828, and source or drain 832 of vertical transistor 830 at the upper end thereof is coupled with bit line 834 (or bit line contact if any), according to some implementations. Accordingly, word lines 828 and bit lines 834 can be disposed in different planes in the vertical direction due to the vertical arrangement of vertical transistors 830, which simplifies the routing of word lines 828 and bit lines 834. Referring to FIGS. 8I and 8J, bit lines 834 extend along y direction and are coupled with one side of semiconductor layer 824, while word lines 828 are disposed vertically between bit lines 834 and capacitors 812. In some implementations, bit lines 834 extend along y-direction and are coupled with two opposite sides of semiconductor layer 824, as shown in FIGS. 8K and 8L.

In some implementations, the rows of vertical transistors 830 separated by trench isolation 836 are mirror-symmetric to one another with respect to trench isolation 836. Trench isolation 836 can be formed with dielectric materials including, but not limited to, silicon oxide, silicon nitride, silicon oxynitride, low-k dielectrics, or any combination thereof. It is understood that trench isolation 836 may include an air gap each disposed laterally between adjacent semiconductor layer 824. As described below with respect to the fabrication process, air gaps may be formed due to the relatively small pitches of vertical transistors 830 in the bit line direction (e.g., the y-direction). On the other hand, the relatively large dielectric constant of air in the air gap can improve the insulation effect between vertical transistors 830 compared with some dielectrics (e.g., silicon oxide). Similarly, in some implementations, air gaps are formed laterally between word lines/gate electrodes 828 in the bit line direction as well, depending on the pitches of word lines/gate electrodes 828 in the bit line direction.

As shown in FIG. 7, method 700 can proceed to operation 710, in which an interconnect layer 840 is formed above the array of vertical transistors 830. FIG. 8M illustrates a schematic side cross-sectional view of the semiconductor device in y-z plane after operation 710 of method 700.

As shown in FIG. 8M, second semiconductor structure 104 can also include a bonding layer 848 at bonding interface 106 to be coupled to a bonding layer of first semiconductor structure 102. Bonding layer 848 can include a plurality of bonding contacts 846 and dielectrics electrically isolating bonding contacts 846. Bonding contacts 846 can include conductive materials, such as Cu. The remaining area of bonding layer 848 can be formed with dielectric materials, such as silicon oxide. Bonding contacts 846 and surrounding dielectrics in bonding layer 848 can be used for hybrid bonding. Bonding contacts 846 are coupled with bonding contacts of first semiconductor structure 102 at bonding interface 106, according to some implementations.

In some implementations, interconnect layer 840 can include a plurality of interconnects, such as MEOL interconnects and BEOL interconnects. In some implementations, the interconnects in interconnect layer 840 also include local interconnects, such as bit lines 834 (e.g., an example of bit lines 506 in FIG. 5), bit line contacts 844 (which may be omitted in some examples), and word line contacts 842. Interconnect layer 840 can further include one or more ILD layers in which the interconnect lines and via contacts can form. The interconnects in interconnect layer 840 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof. In some implementations, interconnect layer 840 including bit lines 834 can be disposed between bonding layer 848 and array of vertical transistors 830.

As shown in FIG. 7, method 700 can proceed to operation 712, in which interconnect layer 840 is bonded to a peripheral circuit 858 of first semiconductor structure 102 through a bonding layer 852 formed above the interconnect layer 840. FIG. 8N illustrates a schematic side cross-sectional view of semiconductor device 800 in y-z plane after operation 712 of method 700.

First semiconductor structure 102 can include peripheral circuits 858 on substrate 860. In some implementations, peripheral circuits 858 includes a plurality of transistors 856 (e.g., planar transistors and/or semiconductor transistors). Trench isolations (e.g., shallow trench isolations (STIs)) and doped regions (e.g., wells, sources, and drains of transistors 856) can be formed on or in substrate 860 as well. In some implementations, first semiconductor structure 102 further includes an interconnect layer 850 under peripheral circuits 858 to transfer electrical signals to and from peripheral circuits 858. Interconnect layer 850 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 850 can further include one or more interlayer dielectric (ILD) layers (also known as “intermetal dielectric (IMD) layers”) in which the interconnect lines and via contacts can form. That is, interconnect layer 850 can include interconnect lines and via contacts in multiple ILD layers. In some implementations, peripheral circuits 858 are coupled to one another through the interconnects in interconnect layer 850. The interconnects in interconnect layer 850 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

As shown in FIG. 8N, first semiconductor structure 102 can further include a bonding layer 852 at bonding interface 106 and above interconnect layer 850 and peripheral circuits 858. Bonding layer 852 can include a plurality of bonding contacts 854 and dielectrics electrically isolating bonding contacts 854. Bonding contacts 854 can include conductive materials, such as Cu. The remaining area of bonding layer 852 can be formed with dielectric materials, such as silicon oxide. Bonding contacts 854 and surrounding dielectrics in bonding layer 852 can be used for hybrid bonding. In some implementations, peripheral circuits 858 includes a word line driver/row decoder coupled to word line contacts 842 in interconnect layer 840 through bonding contacts 846 and 854 in bonding layers 848 and 852 and interconnect layer 850. In some implementations, peripheral circuits 858 include a bit line driver/column decoder coupled to bit lines 834 and bit line contacts 844 in interconnect layer 840 through bonding contacts 846 and 854 in bonding layers 848 and 852 and interconnect layer 850.

As shown in FIG. 7, method 700 can proceed to operation 714, in which a pad-out interconnect layer 862 is formed. FIG. 8O illustrates a schematic side cross-sectional view of semiconductor device 800 in y-z plane after operation 714 of method 700, in which pad-out interconnect layer 862 is formed on the backside of the first semiconductor structure 102. FIG. 8P illustrates a schematic side cross-sectional view of semiconductor device 800 in y-z plane after operation 714 of method 700, in which pad-out interconnect layer 862 is formed on the backside of the second semiconductor structure 104.

As shown in FIG. 8O, a pad-out interconnect layer 862 is formed on the backside of substrate 860 of first semiconductor structure 102. Pad-out interconnect layer 862 can include interconnects, e.g., contact pads 864, in one or more ILD layers. Pad-out interconnect layer 862 and first semiconductor structure 102 can be formed on a same side as second semiconductor structure 104. In some implementations, the interconnects in pad-out interconnect layer 862 can transfer electrical signals between the semiconductor device and outside circuits, e.g., for pad-out purposes. In some implementations, second semiconductor structure 104 further includes one or more contacts 866 extending through substrate 860 and part of pad-out interconnect layer 862 to couple pad-out interconnect layer 862 to DRAM cells (e.g., vertical transistors 830 and capacitors 812) and interconnect layer 840. As a result, peripheral circuits 858 can be coupled to DRAM cells through interconnect layers 840 and 850 as well as bonding layers 848 and 852, and peripheral circuits 858 and DRAM cells can be coupled to outside circuits through contacts 866 and pad-out interconnect layer 862. Contact pads 864 and contacts 866 can include conductive materials including, but not limited to, W, Co, Cu, Al, silicide, or any combination thereof. In one example, contact pad 864 may include Al, and contact 866 may include W. In some implementations, contact 866 includes a via surrounded by a dielectric spacer (e.g., having silicon oxide) to electrically separate the via from substrate 860. Depending on the thickness of substrate 860, contact 866 can be an ILV having a depth in the submicron-level (e.g., between 10 nm and 1 μm), or a TSV having a depth in the micron- or tens micron-level (e.g., between 1 μm and 100 μm).

In some implementations, a pad-out interconnect layer 862 is formed on the backside of second semiconductor structure 104, i.e., pad-out interconnect layer 862 and first semiconductor structure 102 can be formed on opposite sides of second semiconductor structure 104, as shown in FIG. 8P. In some implementations, at operation 714 in FIG. 7, substrate 802 is removed or thinned to couple with pad-out interconnect layer 862. In some implementations, planarization processes (e.g., CMP) and/or etching processes are performed to remove substrate 802 until being stopped by metal layer 804. As shown in FIG. 8P, pad-out interconnect layer 862 is removed to expose metal layer 804, so that the thickness of the semiconductor device can be reduced. In some implementations, one or more contacts 866 extend through dielectric layer 806 and isolation layer 820 to couple pad-out interconnect layer 862 to peripheral circuit 858 through interconnect layers 840 and 850. Contact pad 868 may include Al, and contact 866 may include W.

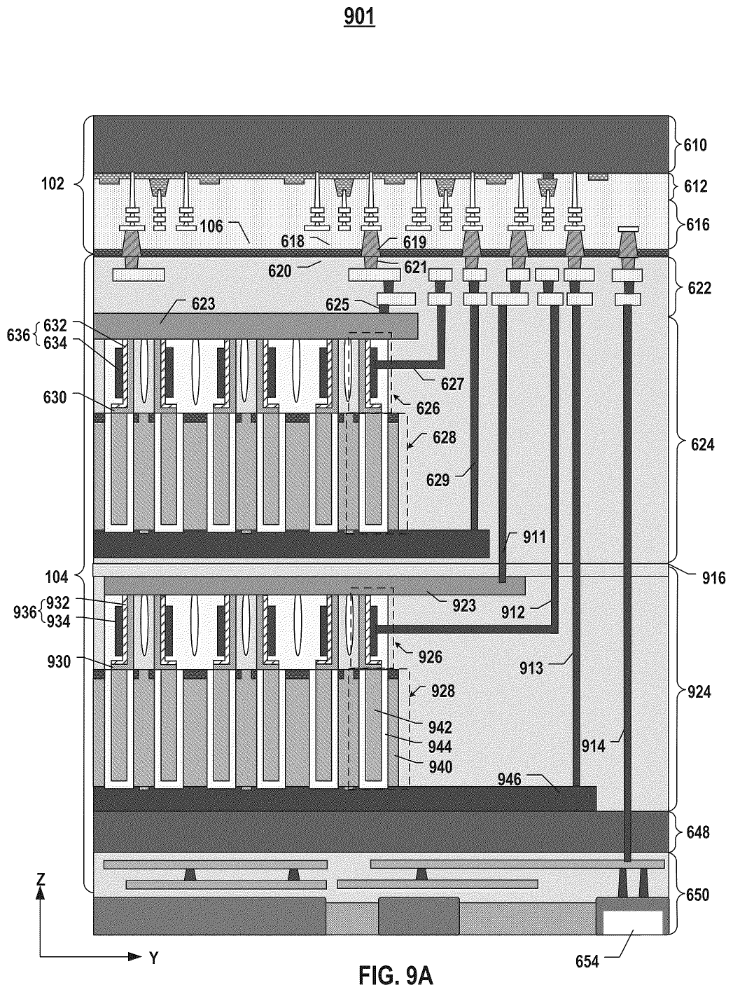

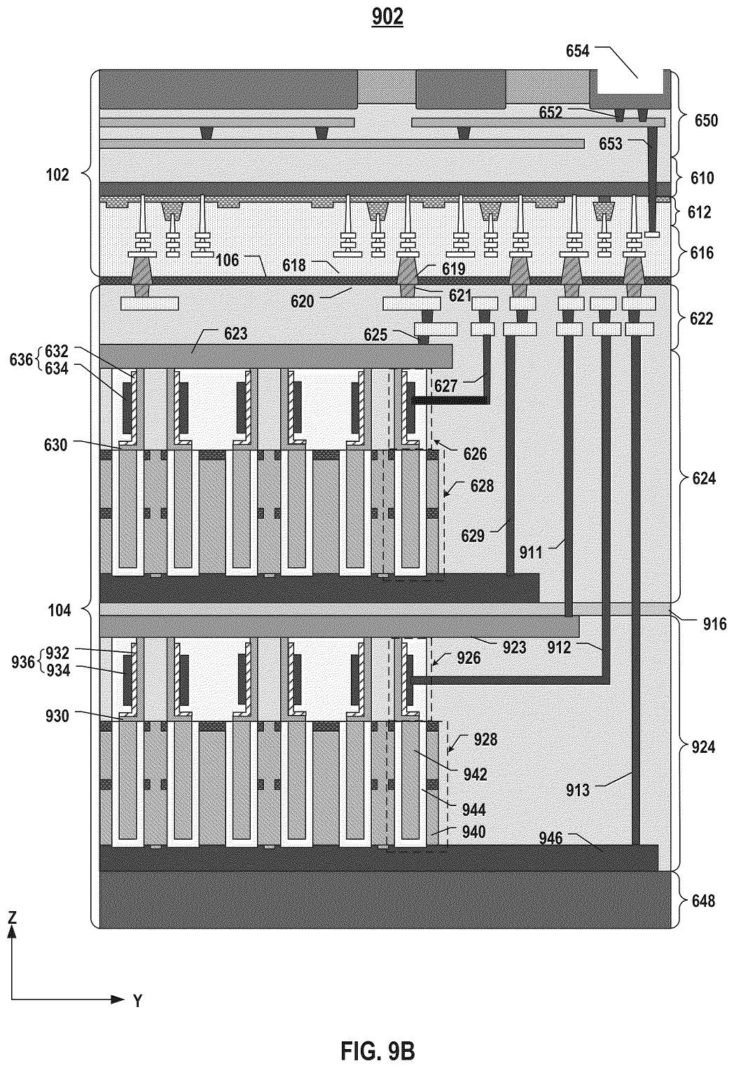

It is understood that more than one DRAM cell array may be stacked over one another to vertically scale up the number of DRAM cells. For example, as shown in FIG. 9A, a semiconductor device 901 may include a first semiconductor structure 102 including a peripheral circuit 612 and a second semiconductor structure 104 including a first set of DRAM cells 624 and a second set of DRAM cells 924 stacked on the first set of DRAM cells 624. Each DRAM cell 624 of the first set includes a vertical transistor 626 and a capacitor 628 coupled to the vertical transistor 626. The vertical transistor 626 includes a semiconductor layer 630 extending along a vertical direction (i.e., the z-direction) and a gate structure 636 coupled to the semiconductor layer 630. A leakage value of the semiconductor layer 630 is lower than a pico-ampere. The second set of DRAM cells 924 are formed after first set of DRAM cells 624 and is electrically insulated from first array of DRAM cells 624 by an isolation layer 916. Each DRAM cell 924 of the second set includes a vertical transistor 926 and a capacitor 928 coupled to the vertical transistor 926. The vertical transistor 926 includes a semiconductor layer 930 extending along a vertical direction (i.e., the z-direction) and a gate structure 936 coupled to the semiconductor layer 930, a leakage value of the semiconductor layer 930 is lower than a pico-ampere. In present implementation, the semiconductor layers 630 and 930 can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

First set of DRAM cells 624 may have a same or similar structure as DRAM cells 624 of semiconductor device 601 in FIG. 6A or semiconductor device 602 in FIG. 6B and will not repeat here for ease of description. Second set of DRAM cells 924 may have a same or similar structure as first set of DRAM cells 624.

In some implementations, gate structure 936 of second set of DRAM cells 924 includes a gate dielectric 932 and a gate electrode 934. In some implementations, gate dielectric 932 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. In some implementations, gate electrode 634 includes conductive materials including, but not limited to W, Co, Cu, Al, TiN, TaN, polysilicon, silicide, or any combination thereof. In some implementations, gate electrode 634 includes multiple conductive layers, such as a W layer over a TiN layer. In one example, gate structure 636 may be a “gate oxide/gate poly” gate in which gate dielectric 632 includes silicon oxide and gate electrode includes doped polysilicon. In another example, gate structure 636 may be a high-k metal gate (HKMG) in which gate dielectric 632 includes a high-k dielectric and gate electrode includes a metal.

In some implementations, gate structure 936 of second set of DRAM cells 924 includes a gate dielectric 932 and a gate electrode 934. In some implementations, gate dielectric 932 includes dielectric materials, such as silicon oxide, silicon nitride, or high-k dielectrics. Gate electrode 934 includes conductive materials including, but not limited to W, Co, Cu, Al, TiN, TaN, polysilicon, silicide, or any combination thereof. In some implementations, gate electrode 934 includes multiple conductive layers, such as a W layer over a TiN layer. In one example, gate structure 936 may be a “gate oxide/gate poly” gate in which gate dielectric 932 includes silicon oxide and gate electrode includes doped polysilicon. In another example, gate structure 936 may be a high-k metal gate (HKMG) in which gate dielectric 932 includes a high-k dielectric and gate electrode includes a metal.

As described above, since gate electrode 934 may be part of a word line or extend in the word line direction (e.g., the x-direction in FIG. 5) as a word line, although not directly shown in FIG. 9A, second semiconductor structure 104 of semiconductor device 601 can also include a plurality of word lines (e.g., an example of word lines 504 in FIG. 5, referred to as 934 as well) each extending in the word line direction (the x-direction). Each word line 934 can be coupled to a row of DRAM cells 924. That is, bit line 923 and word line 934 can extend in two perpendicular lateral directions, and semiconductor layer 930 of vertical transistor 926 can extend in the vertical direction perpendicular to the two lateral directions in which bit line 923 and word line 934 extend. Word lines 934 are coupled with word line contacts 912 in the x-direction and word line contacts 912 are coupled with word lines 934 at an end of each word line 934 in the x-direction, according to some implementations. The relevant location of the word line contacts 912 and word lines 934 in FIG. 9A is illustrative and should not be interpreted as a limitation of the present disclosure. In some implementations, word lines 934 include conductive materials including, but not limited to W, Co, Cu, Al, TiN, TaN, polysilicon, silicide, or any combination thereof. In some implementations, word line 934 includes multiple conductive layers, such as a W layer over a TiN layer.

As shown in FIG. 9A, vertical transistor 926 extends vertically through and is coupled with a corresponding word line 934, and source or drain of vertical transistor 926 at the lower end thereof is coupled with bit line contact 911, according to some implementations. Accordingly, word lines 934 and bit lines 923 can be disposed in different planes in the vertical direction due to the vertical arrangement of vertical transistor 926, which simplifies the routing of word lines 934 and bit lines 923. In some implementations, bit lines 923 are disposed vertically between isolation layer 916 and word lines 934, and word lines 934 are disposed vertically between bit lines 923 and capacitors 928. Word lines 934 can be coupled to peripheral circuits 612 in first semiconductor structure 102 through word line contacts 912 and interconnect layer 622. Similarly, bit lines 923 can be coupled to peripheral circuits 612 in first semiconductor structure 102 through bit line contacts 911 and interconnect layer 622.

As shown in FIG. 9A, in some implementations, capacitor 928 of second set of DRAM cells 924 includes a first electrode 942 above and coupled with source or drain of vertical transistor 926, a capacitor dielectric 944 above and coupled with first electrode 942, and a second electrode 940 above and coupled with capacitor dielectric 944. That is, capacitor 928 can be a vertical capacitor in which first and second electrodes 942 and 940 and capacitor dielectric 944 are stacked vertically (in the z-direction), and capacitor dielectric 944 can be sandwiched between first and second electrodes 942 and 940. In some implementations, each first electrode 942 is coupled to source or drain of a respective vertical transistor 926 in the same DRAM cell, while all second electrodes 940 are parts of a common plate 946 coupled to the ground, e.g., a common ground. In some implementations, all second electrodes 940 can be coupled to peripheral circuits 612 in first semiconductor structure 102 through capacitor contacts 913 and interconnect layer 622.

As shown in FIG. 9A, vertical transistor 926 extends vertically through and is coupled with a corresponding word line 934. Source or drain of vertical transistor 926 thereof is coupled with bit line contact or coupled with bit line 923 directly. That is, bit line 923 and capacitor 928 can be disposed in different planes in the vertical direction and coupled to opposite ends of vertical transistor 926 of DRAM cell 924 in the vertical direction due to the vertical arrangement of vertical transistor 926. In some implementations, bit line 923 and capacitor 928 are disposed on opposite sides of vertical transistor 926 in the vertical direction, which simplifies the routing of bit lines 923 and reduces the coupling capacitance between bit lines 923 and capacitors 928 compared with conventional DRAM cells in which the bit lines and capacitors are disposed on the same side of the planar transistors.

As shown in FIG. 9A, in some implementations, vertical transistors 926 are disposed vertically between capacitors 928 and bonding interface 106. That is, vertical transistors 926 can be arranged closer to peripheral circuits 612 of first semiconductor structure 102 and bonding interface 106 than capacitors 928. Since bit lines 923 and capacitors 928 are coupled to opposite ends of vertical transistors 926, as described above, bit lines 923 are disposed vertically between vertical transistors 926 and bonding interface 106, according to some implementations.

As shown in FIG. 9A, second semiconductor structure 104 can further include a pad-out interconnect layer 650. Pad-out interconnect layer 650 can include interconnects, e.g., contact pads 654, in one or more ILD layers. Pad-out interconnect layer 650 and interconnect layer 622 can be formed on opposite sides of the stack of first set of DRAM cells 624 and second set of DRAM cells 924. Capacitors 928 of second set of DRAM cells 924 are disposed vertically between vertical transistors 626 of second set of DRAM cells 924 and pad-out interconnect layer 650, according to some implementations. In some implementations, the interconnects in pad-out interconnect layer 650 can transfer electrical signals between semiconductor device 601 and outside circuits, e.g., for pad-out purposes. In some implementations, second semiconductor structure 104 further includes one or more contacts 914 extending through part of pad-out interconnect layer 650 to couple pad-out interconnect layer 650 to interconnect layer 622. Peripheral circuits 612 can be coupled to the first set and second set of DRAM cells 624 and 924 through interconnect layers 616 and 622 as well as bonding layers 620 and 618. Contact pads 654 and contacts 652 can include conductive materials including, but not limited to, W, Co, Cu, Al, silicides, or any combination thereof. In one example, contact pad 654 may include Al, and contact 652 may include W. In some implementations, contact 652 includes a via surrounded by a dielectric spacer (e.g., having silicon oxide) to electrically separate the via from substrate 648. Depending on the thickness of substrate 648, contact 652 can be an interlayer via (ILV) having a depth in the submicron-level (e.g., between 10 nm and 1 μm), or a through substrate via (TSV) having a depth in the micron- or tens micron-level (e.g., between 1 μm and 100 μm).

It is understood that the pad-out of semiconductor devices is not limited to be from second semiconductor structure 104 having first set and second set of DRAM cells 624 and 924 as shown in FIG. 9A and may be from first semiconductor structure 102 having peripheral circuit 612. For example, as shown in FIG. 9B, a semiconductor device 902 may include pad-out interconnect layer 650 in first semiconductor structure 102. Pad-out interconnect layer 650 can be disposed above and coupled with substrate 610 of first semiconductor structure 102 on which transistors 614 of peripheral circuit 612 are formed. In some implementations, first semiconductor structure 102 further includes one or more contacts 653 extending vertically to substrate 610. In some implementations, contact 653 couples the interconnects in interconnect layer 616 in first semiconductor structure 102 to contact pads 654 in pad-out interconnect layer 650 to make an electrical connection through substrate 610. Contacts 653 can include conductive materials including, but not limited to, W, Co, Cu, Al, silicide, or any combination thereof. In one example, contact 653 may include W. In some implementations, contact 653 includes a via surrounded by a dielectric spacer (e.g., having silicon oxide) to electrically separate the via from substrate 610. It is understood that in some examples, substrate 610 in FIG. 9B may be a thinned substrate, e.g., compared with substrate 610 in FIG. 9A. Depending on the thickness of substrate 610, contact 653 can be an ILV having a depth in the submicron-level (e.g., between 10 nm and 1 μm), or a TSV having a depth in the micron- or tens micron-level (e.g., between 1 μm and 100 μm). It is understood that the details of the same components (e.g., materials, fabrication process, functions, etc.) in both semiconductor devices 901 and 902 are not repeated for ease of description. Pad-out from first semiconductor structure 102 including peripheral circuits 612 can reduce the interconnect distance between contact pad 654 and peripheral circuits 612, thereby decreasing the parasitic capacitance from the interconnects and improving the electrical performance of semiconductor device 602.

It is understood that the vertical transistors 626 in first set of DRAM cells 624 and vertical transistors 926 in second set of DRAM cells 924 are not limited to single-gate transistors as shown in FIG. 9A and FIG. 9B and may be double-gate transistors or gate-all-around transistors, the structure of which will be detailed below. It is understood that the architecture of multiple memory cell arrays shown in FIGS. 9A and 9B are not limited to the design of DRAM cells 624 and may be applied to any suitable memory cells disclosed herein. It is also understood that various designs of memory cells disclosed herein may be mixed in the architecture of multiple memory cell arrays shown in FIG. 9A or 9B. For example, first and second semiconductor structures 102 and 104 may include different designs of memory cells disclosed herein.

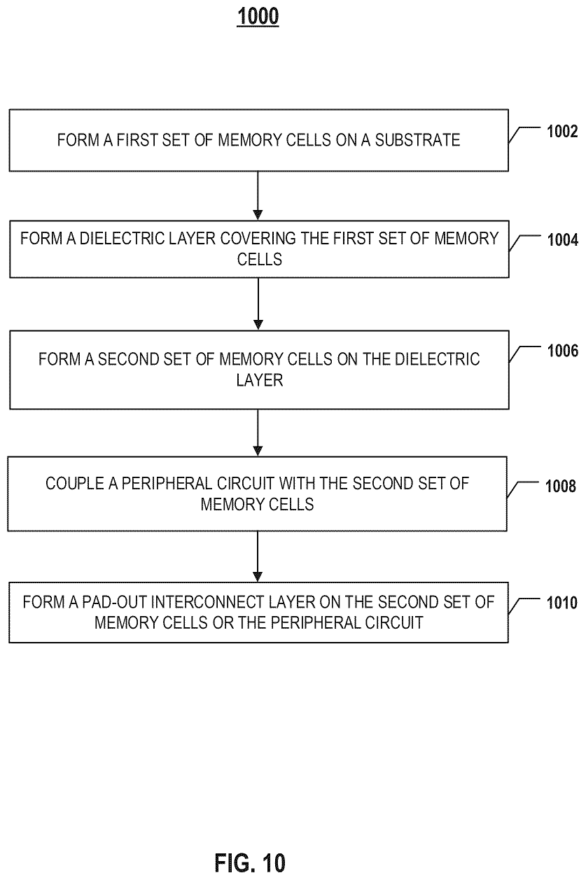

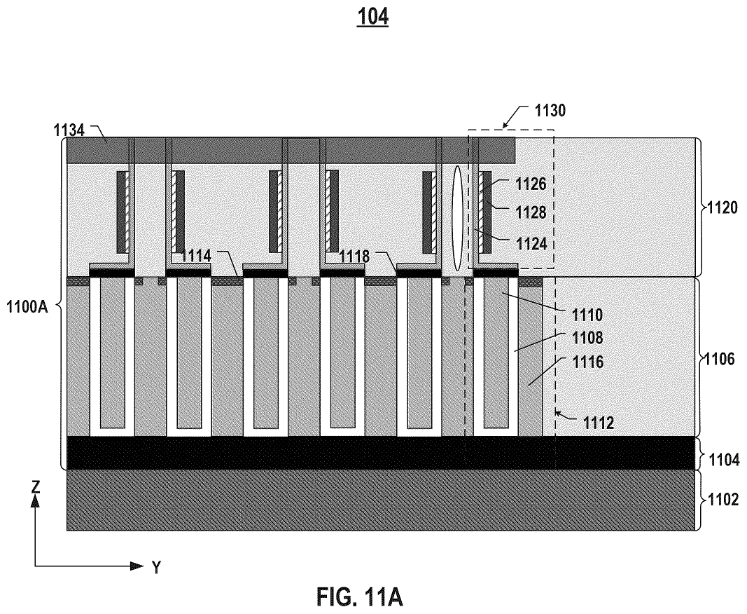

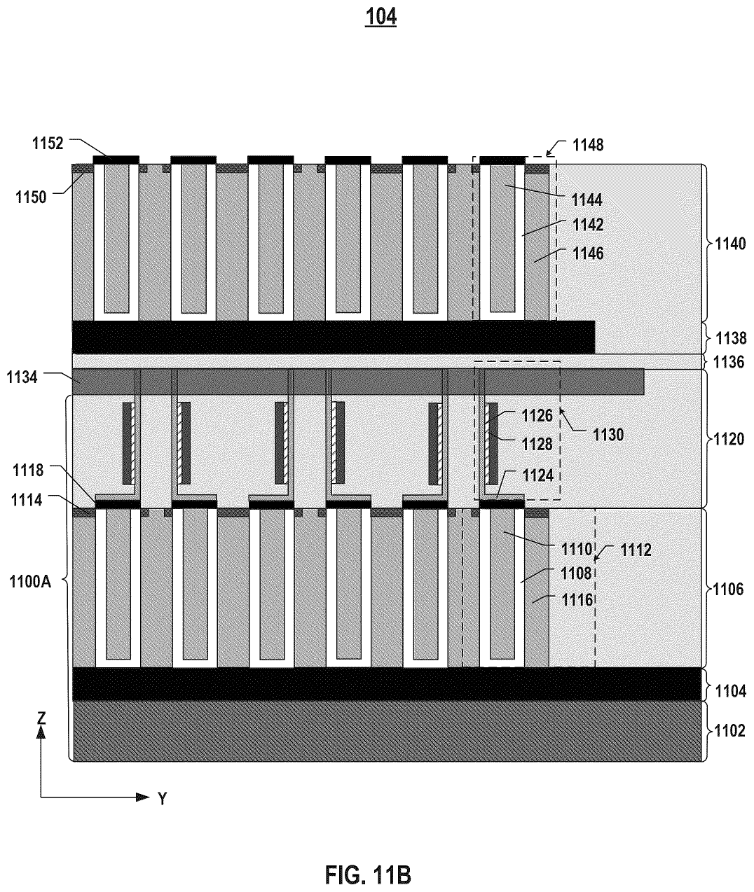

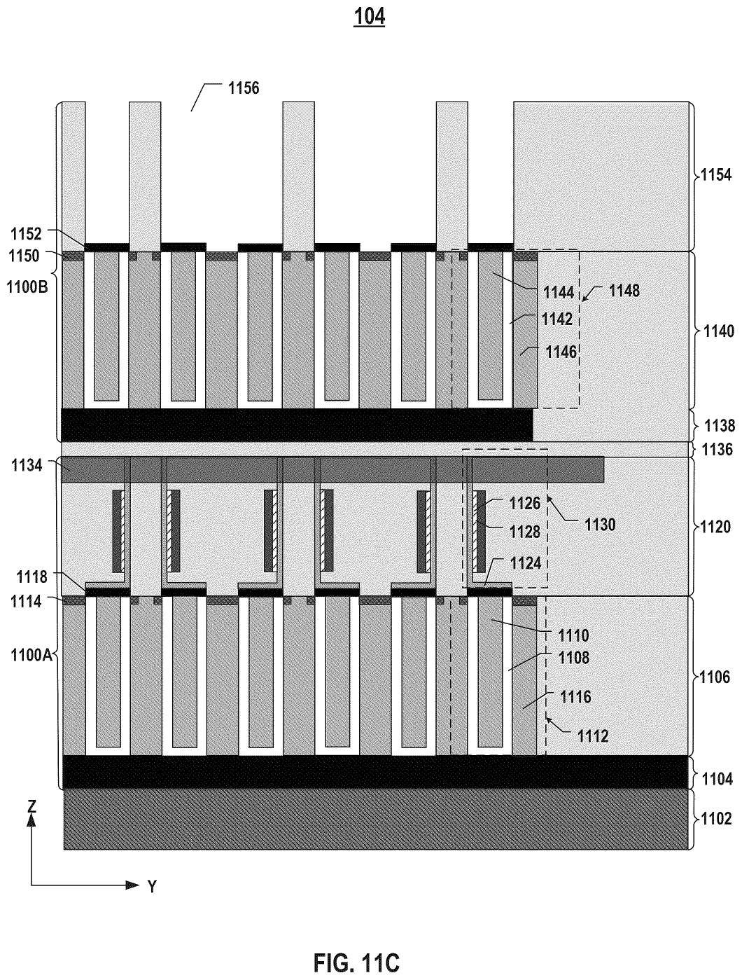

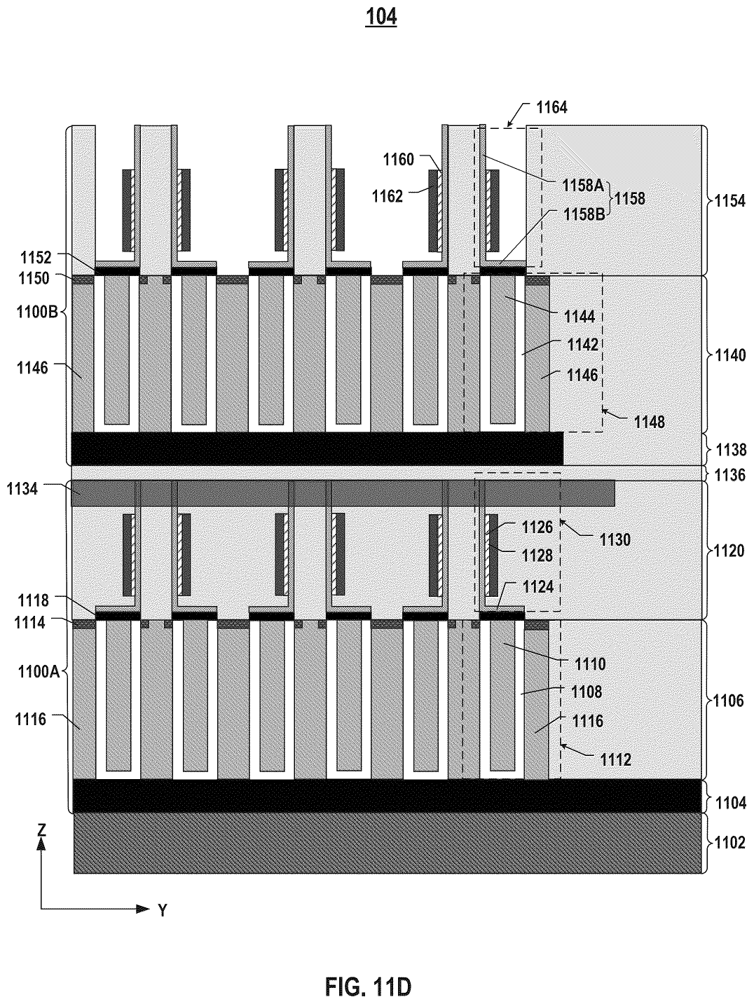

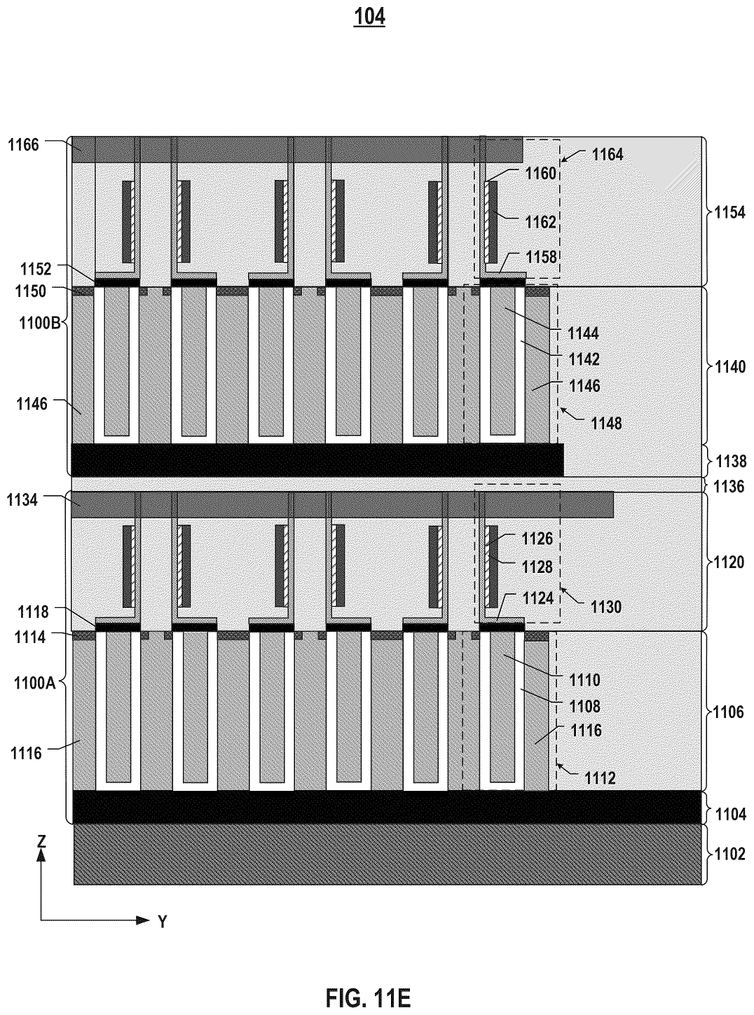

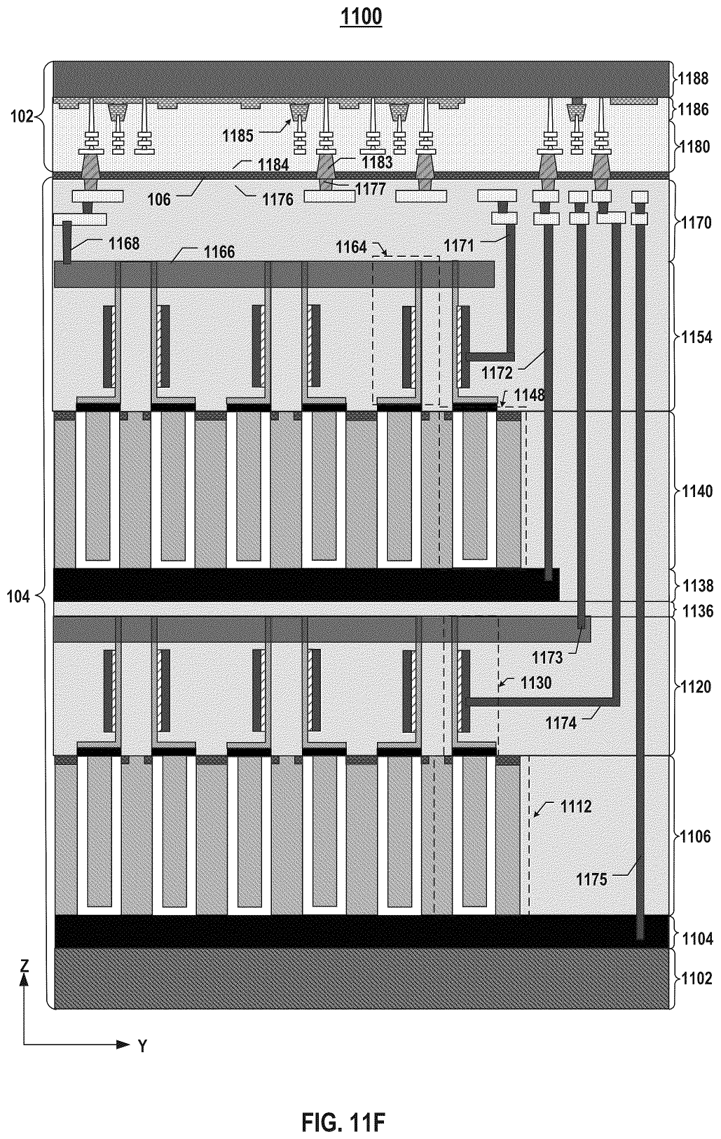

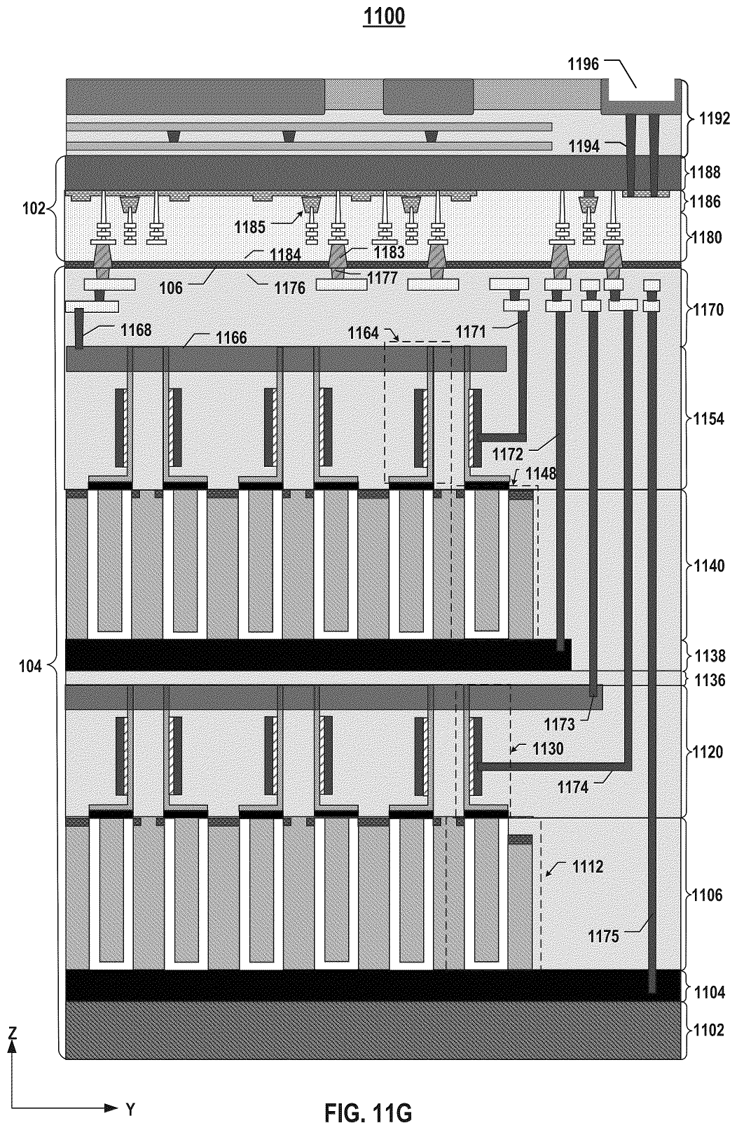

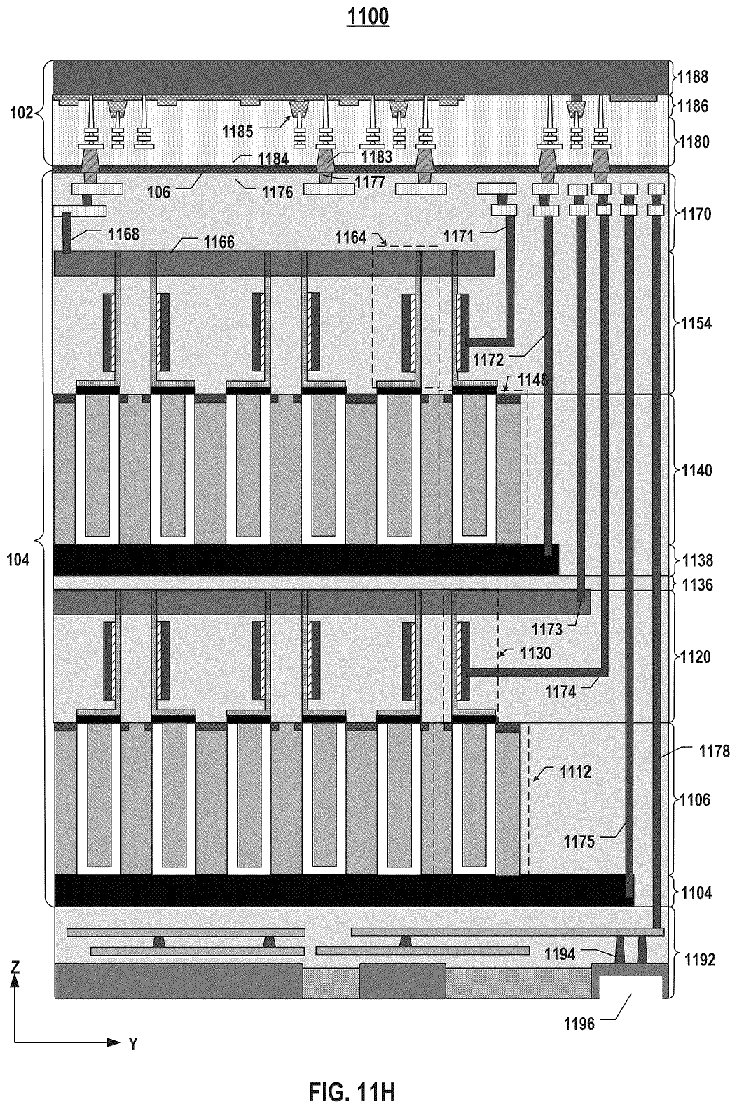

FIG. 10 illustrates a flowchart of a method 1000 for forming a semiconductor device including more than two sets of memory cells stacked together, such as semiconductor device 901 and 902 described above in connection with FIGS. 9A and 9B, according to some implementations of the present disclosure. FIGS. 11A-11H illustrate a fabrication process for forming a semiconductor device 1100 at certain fabricating stages of the method 1000 shown in FIG. 10, according to various implementations of the present disclosure. It is understood that the operations shown in method 1000 are not exhaustive and that other operations can be performed as well before, after, or between any of the illustrated operations. Further, some of the operations may be performed simultaneously, or in a different order than shown in FIG. 10.

As shown in FIG. 10, method 1000 can start at operation 1002, in which a first set of memory cells 1100A can be formed on a substrate 1102. Referring to FIGS. 11A, first set of memory cells 1100A is a part of second semiconductor structure 104 as discussed above. First semiconductor structure 102 and second semiconductor structure 104 can be formed separately through independent fabrication processes and will be bonded together after corresponding fabrication processes are completed. First semiconductor structure 102 may be formed before, after, or at the same time as second semiconductor structure 104. The sequence of the fabrication of first and second semiconductor structures 102 and 104 are not limited in the implementations of the present disclosure and can be arranged and adjusted according to practical needs.

In some implementations, the structure of first set of memory cells 1100A is same as or similar to the array of DRAM cells 624 in FIGS. 6A and 6B. Thus, the formation of first set of memory cells 1100A may refer to the formation of second semiconductor structure 104 of semiconductor device 800 described previous with reference to FIGS. 8A-8G and will not repeat here for ease of description. Referring to FIG. 11A, first set of memory cells 1100A is formed on a substrate 1102. FIG. 11A illustrates a schematic side cross-sectional view of the semiconductor device in y-z plane after first set of memory cells 1100A is formed.

In some implementations, first set of memory cells 1100A includes a vertical transistor 1130 and a capacitor 1112 coupled to the vertical transistor 1130. Capacitor 1112 may be a vertical capacitor formed in a first isolation layer 1106. Capacitor 1112 can include a first electrode 1110 coupled with a source or drain of vertical transistor 1130, a capacitor dielectric 1108 surround and coupled with first electrode 1110, and a second electrode 1116 coupled with capacitor dielectric 1108. As a vertical capacitor, first and second electrodes 1110 and 1116 and capacitor dielectric 1108 are stacked vertically (in the z-direction), and capacitor dielectric 1108 can be sandwiched between first and second electrodes 1110 and 1116. In some implementations, each first electrode 1110 is coupled to source or drain of a respective vertical transistor 1130 in the same memory cell 1100A, while all second electrodes 1116 are parts of a common plate 1104 coupled to the ground, e.g., a common ground. In some implementations, a mesh 1114 is formed among capacitors 1112 so the spacing between them doesn't vary, as shown in FIG. 11A. In some implementations, each first electrode 1110 is coupled to a source of the respective vertical transistor 1130 through a source node contact 1118 to ease alignment in the subsequent operations and reduce conduct resistance between the source or drain of the vertical transistor 1130 and the first electrode 1110 of the capacitors 1112. Vertical transistor 1130 includes a semiconductor layer 1124 extending along a vertical direction (i.e., the z-direction) and a gate structure coupled to the semiconductor layer 1124. A leakage value of the semiconductor layer 1124 is lower than a pico-ampere. The gate structure includes a gate dielectric 1126 coupled with semiconductor layer 1124 along the vertical direction and a gate electrode 1128 coupled with gate dielectric 1126 along the vertical direction. In some implementations, semiconductor layer 1124 includes a vertical portion extending along the vertical direction (i.e., the z-direction), and an extending portion extending from an end of vertical portion towards an adjacent vertical transistor along a second lateral direction (i.e., the y-direction). The vertical portion of semiconductor layer 1124 can be used as the channel of vertical transistor 1130. The gate structure includes a gate dielectric 1126 coupled with the vertical portion of semiconductor layer 1124 and a gate electrode 1128 coupled with gate dielectric 1126. The extending portion of semiconductor layer 1124 is coupled with source node contact 1118. In some implementations, gate electrode 1128 may be part of word line, and word line may be an extension of gate electrode 514. That is, gate electrodes 1128 of adjacent vertical transistors in the word line direction (the x-direction) are continuous, e.g., parts of a continuous conductive layer having gate electrodes 514. In some implementations, vertical transistor 1130 further includes a bit lines 1134 coupled with a drain of vertical transistor 1130 to transfer electrical signals. The structure of the first set of memory cells 1100A and fabrication thereof will not be repeated in detail here for ease of description.

Then a second step of operation 1004 of method 1000 is proceeded, in which a dielectric layer 1136 is formed covering the first set of memory cells 1100A. FIG. 11B illustrates a schematic side cross-sectional view of the semiconductor device in y-z plane after dielectric layer 1136 is formed. Dielectric layer 1136 may be silicon oxide or silicon nitride and may be formed by one or more thin film deposition processes including, but not limited to, CVD, PVD, ALD, or any combination thereof. A thickness of dielectric layer 1136 can be thinned as long as the dielectric layer 1136 is thick enough to isolate first set of memory cells 1100A from subsequent set of memory cells.

Then a second step of operation 1006 of method 1000 is proceeded, in which a second set of memory cells 1100B are formed on dielectric layer 1136. As shown in FIG. 11B, an array of capacitor 1148 of the second set of memory cells 1100B can be formed on dielectric layer 1136. In some implementations, the array of capacitors 1148 can include a second electrode 1146 coupled with a common plate 1138, a plurality of first electrode 1144, and a capacitor dielectric 1142 between first electrodes 1144 and second electrode 1146. In some implementations, first electrodes 1144 and/or the second electrode 1146 can include conductive materials including, but not limited to, W, Co, Cu, Al, TiN, TaN, polysilicon, silicide, or any combination thereof. In some implementations, capacitor dielectric 1142 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, capacitors 1148 have a relatively large height and need to be mechanically stabilized with a mesh 1150, as shown in FIG. 11B. As such, the spacing between capacitors 1148 doesn't vary, thereby avoiding capacitor corrupts. Without mesh 1150, the capacitors would lean over and contact adjacent capacitors. Mesh 1150 includes larger dielectric materials with a Mohs scale larger than silicon oxide, which has a Mohs scale of around six. In some implementations, mesh 1150 can be silicon nitride, silicon carbide, corundum, boron carbide, boron nitride, or any combination thereof. In some implementations, with the increasement of the aspect ratio of the capacitors 1148, two or more levels of mesh are required for mechanical stability. In some implementations, an opening is formed on mesh 1150 among a group of capacitors 1148. Each capacitor is connected to at least one opening so that third isolation layer 1140, also called sacrifice layer, positioned under mesh 1150 can be replaced by a conductor to form second electrode 1146 which is electrically coupled with common plate 1138. The sacrifice layer can be moved by wet/dry etch, or any other suitable processes, and second electrode 1146 includes conductive materials including, but not limited to, W, Co, Cu, Al, TiN, TaN, polysilicon, silicide, or any combination thereof.

In some implementations, the array of capacitors 1148 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc. It is noted that, the fabricating processes and/or orders of forming the first electrodes 1144, the second electrode 1146, and the capacitor dielectric 1142 can be varied depending on a front side process or a back side process.

In some implementations, to suppress drain induced barrier lowering (DIBL), the doping concentration of substrate is increased, resulting in an increasement of the junction leakage current. The increased leakage current can consume more power and deteriorate the retention capability of a semiconductor device. To solve this problem, storage node contacts 1152 are introduced on the top of capacitor 1148 as shown in FIG. 11B. Storage node contacts 1152 can be made of doped amorphous silicon, doped polysilicon, doped single crystal silicon, or doped silicon germanium (Si_{X} Ge_{1-X}). Thus, the resistance between capacitor 1148 and a corresponding vertical transistor can be controlled by adjusting the doping concentration of storage node contacts 1152.

In some implementations, a fourth isolation layer 1154 is formed on third isolation layer 1140, and a plurality of through holes 1156 are formed in fourth isolation layer 1154. FIG. 11C illustrates a schematic side cross-sectional view of the semiconductor device in y-z plane after through holes 1156 are formed. As shown in FIG. 11C, each through hole 1156 penetrates fourth isolation layer 1154 to expose a corresponding one of the plurality of storage node contacts 1152. In some other implementations not shown in the figures, storage node contacts 1152 can be omitted from the top of capacitor 1148. In such implementations, capacitors 1148 are directly exposed by through holes 1156. It should be noted that storage node contacts 1152 can also be formed after forming fourth isolation layer 1154. The sequence of the fabrication of storage node contacts 1152 and fourth isolation layer 1154 are not limited in the implementations of the present disclosure and can be arranged and adjusted according to practical needs.

As shown in FIG. 11D, a semiconductor layer 1158, a gate dielectric layer 1160, and a gate electrode 1162 can be formed in each through hole 1156 to form a vertical transistor 1164. FIG. 11D illustrates a schematic side cross-sectional view of the semiconductor device in y-z plane after the gate structures are formed.

As shown in FIG. 11D, vertical transistor 1164 may be an example of a single-gate vertical transistor. Gate structure can be coupled with one side of semiconductor layer 1158 (the active region in which channels are formed). Each vertical transistor 1164 includes semiconductor layer 1158 extending vertically from an end of through hole 1156 where storage node contacts 1152 are positioned to another end opposite to storage node contact 1152.

In some implementations, semiconductor layer 1158 has two ends (the upper end and lower end) in the vertical direction (the z-direction). The lower end of semiconductor layer 1158 covers corresponding storage node contact 1152 or covers a top surface of a corresponding capacitor 1148 when storage node contacts 1152 are omitted. A vertical portion of semiconductor layer 1158 can be used as the channel of vertical transistor 1164. In some implementations, semiconductor layer 1158 can be formed from a deposition process. In some implementations, the semiconductor can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

In some implementations, semiconductor layer 1158 includes a vertical portion 1158A extending along the vertical direction (i.e., the z-direction), and an extending portion 1158B extending from an end of vertical portion 1158A towards an adjacent vertical transistor along a second lateral direction (i.e., the y-direction). Extending portion 1158B is coupled with the storage unit or the source node contact. Semiconductor 1158 has an L-shaped cross-section on the y-z plane, as shown in FIG. 11D. With extending portion 1158B, a length of semiconductor layer 1158 is extended, and a contact area between a source of the vertical transistor and the storage unit or the source node contact is expanded as well.

In some implementations, as shown in FIG. 11D, vertical transistors in the memory cells are mirror single-gate (MSG) transistors, i.e., semiconductor layers of two adjacent vertical transistors are isolated by dielectric structure, and gate structure of each vertical transistor is formed on a side away from the dielectric structure. Therefore, the gate structure of the two adjacent vertical transistors are mirror symmetrical. In MSG transistors, forming semiconductor layer 1158 may start from epitaxially growing an initial semiconductor layer covering a bottom and the two opposite sidewalls of each of the through hole 1156, i.e., covering the surface of through hole 1156 by the initial semiconductor layer. A trench can be formed on the initial semiconductor layer on the bottom of the through hole to punch through the initial semiconductor layer into two separate semiconductor layers 1158 of two adjacent vertical transistors. Each semiconductor layer 1158 includes a vertical portion 1158A and an extending portion 1158B, as shown in FIG. 11D. The length of each extending portion 1158B along y-direction is larger than or equal to a length of the corresponding source node contract along y-direction as long as the two adjacent extending portions 1158B are isolated.

Gate dielectric layer 1160 can be formed to cover semiconductor layer 1158, in the present implementation, to cover vertical portion 1158A of semiconductor layer 1158. Gate dielectric layer 1160 can include any suitable dielectric materials, such as silicon oxide, silicon nitride, silicon oxynitride, or high-k dielectrics. For example, gate dielectric layer 1160 may include silicon oxide, i.e., gate oxide, which can be formed during the fabricating of gate electrode 1162 and has a same material as fourth isolation layer 1154. In some implementations, gate dielectric layer 1160 can be high-k dielectrics including, but not limited to, Al₂O₃, HfO₂, Ta₂O₅, ZrO₂, TiO₂, or any combination thereof, which has a different material with fourth isolation layer 1154, as shown in FIG. 11D. Gate electrode 1162 can be formed to cover gate dielectric layer 1160. Gate electrode 828 can include any suitable conductive materials, such as polysilicon, metals (e.g., W, Cu, Al, etc.), metal compounds (e.g., TiN, TaN, etc.), or silicide. For example, gate electrode 1162 may include doped polysilicon, i.e., a gate poly. In some implementations, gate electrode 1162 includes multiple conductive layers, such as a W layer over a TiN layer.

In some implementations, at least one end of vertical portion 1158A of semiconductor layer 1158 extends beyond gate dielectric layer 1160 in the vertical direction (the z-direction). In some implementations, one end of vertical portion 1158A of semiconductor layer 1158 is flush with the respective end of gate dielectric layer 1160. In some implementations, both ends of semiconductor layer 1158 extend beyond gate electrode 1162, respectively, in the vertical direction (the z-direction). That is, semiconductor layer 1158 can have a larger vertical dimension (e.g., the depth) than that of gate electrode 1162. Vertical transistor 1164 can further include a source and a drain disposed at the two ends of semiconductor layer 1158, respectively, in the vertical direction. In some implementations, one of source and drain is coupled to capacitor 1148, and the other one of source and drain is coupled to a bit line.

In some implementations, referring to FIG. 11E, through holes 1156 are then filled with dielectric materials after the gate structure is formed, and a plurality of bit lines 1166 and word lines 1162 (referred to as gate electrodes 1162 as well) can be formed on the array of vertical transistors 1164. As shown in FIG. 11E, vertical transistor 1164 extends vertically through and is coupled with a corresponding word line 1162, and source or drain of vertical transistor 1164 at the upper end thereof is coupled with bit line 1166 (or bit line contact if any), according to some implementations. Accordingly, word lines 1162 and bit lines 1166 can be disposed in different planes in the vertical direction due to the vertical arrangement of vertical transistor 1164, which simplifies the routing of word lines 1162 and bit lines 1166. Bit line 1166 extends along y-direction and is coupled with one side of semiconductor layer 1158, word lines 1162 are disposed vertically between bit lines 1166 and capacitors 1148. In some implementations, bit lines 1166 extends along y-direction and is coupled with two opposite sides of semiconductor layer 1158.

As shown in FIG. 10, method 1000 can proceed to operation 1008, in which a peripheral circuit is coupled with the second set of memory cells 1100B. FIG. 11F illustrates a schematic side cross-sectional view of the semiconductor device in y-z plane after operation 1008 of method 1000.

As shown in FIG. 11F, second semiconductor structure 104 can also include an bonding layer 1176 at bonding interface 106 to be coupled to a bonding layer 1184 of first semiconductor structure 102. Bonding layer 1176 can include a plurality of bonding contacts 1177 and dielectrics electrically isolating bonding contacts 1177. Bonding contacts 1177 can include conductive materials, such as Cu. The remaining area of bonding layer 1176 can be formed with dielectric materials, such as silicon oxide. Bonding contacts 1177 and surrounding dielectrics in bonding layer 1176 can be used for hybrid bonding. Bonding contacts 1177 are coupled with bonding contacts of first semiconductor structure 102 at bonding interface 106, according to some implementations.

In some implementations, interconnect layer 1170 can include a plurality of interconnects, such as MEOL interconnects and BEOL interconnects. In some implementations, the interconnects in interconnect layer 1170 also include local interconnects, such as bit lines 1166 and bit line contacts 1168 of the second set of memory cells, word line contacts 1171 and capacitor connector 1172 of the second set of memory cells, bit line contacts 1173 of the first set of memory cells, word line contacts 1174 of the first set of memory cells, and capacitor connector 1175 of the second set of memory cells. Interconnect layer 1170 can further include one or more ILD layers in which the interconnect lines and via contacts can form. The interconnects in interconnect layer 1170 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

As shown in FIG. 11F, interconnect layer 1170 is bonded to a peripheral circuit 1186 of first semiconductor structure 102 through a bonding layer 1184 formed above the interconnect layer 1170. First semiconductor structure 102 can include peripheral circuits 1186 on substrate 1188. In some implementations, peripheral circuits 1186 includes a plurality of transistors 1185 (e.g., planar transistors and/or semiconductor transistors). Trench isolations (e.g., shallow trench isolations (STIs)) and doped regions (e.g., wells, sources, and drains of transistors 1185) can be formed on or in substrate 1188 as well. In some implementations, first semiconductor structure 102 further includes an interconnect layer 1180 under peripheral circuits 1186 to transfer electrical signals to and from peripheral circuits 1186. Interconnect layer 1180 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 1180 can further include one or more interlayer dielectric (ILD) layers (also known as “intermetal dielectric (IMD) layers”) in which the interconnect lines and via contacts can form. That is, interconnect layer 1180 can include interconnect lines and via contacts in multiple ILD layers. In some implementations, peripheral circuits 1186 are coupled to one another through the interconnects in interconnect layer 1180. The interconnects in interconnect layer 1180 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

First semiconductor structure 102 can further include a bonding layer 1184 at bonding interface 106 and under interconnect layer 1180 and peripheral circuits 1186. Bonding layer 1184 can include a plurality of bonding contacts 1183 and dielectrics electrically isolating bonding contacts 1183. Bonding contacts 1183 include conductive materials, such as Cu. The remaining area of bonding layer 1184 can be formed with dielectric materials, such as silicon oxide. Bonding contacts 1183 and surrounding dielectrics in bonding layer 1184 can be used for hybrid bonding. In some implementations, peripheral circuits 1186 includes a word line driver/row decoder coupled to word line contacts 1171 in interconnect layer 1170 through bonding contacts 1177 and 1183 in bonding layers 1176 and 1184 and interconnect layer 1180.

As shown in FIG. 10, method 1000 can proceed to operation 1010, in which a pad-out interconnect layer 1192 is formed. FIG. 11G illustrates a schematic side cross-sectional view of semiconductor device 1100 in y-z plane after operation 1010 of method 1000, in which pad-out interconnect layer 1192 is formed on the backside of the first semiconductor structure 102. FIG. 11H illustrates a schematic side cross-sectional view of semiconductor device 1100 in y-z plane after operation 1010 of method 1000, in which pad-out interconnect layer 1192 is formed on the backside of the second semiconductor structure 104.

As shown in FIG. 11G, a pad-out interconnect layer 1192 is formed on the backside of substrate 1188 of first semiconductor structure 102. Pad-out interconnect layer 1192 can include interconnects, e.g., contact pads 1196, in one or more ILD layers. Pad-out interconnect layer 1192 and first semiconductor structure 102 can be formed on a same side as second semiconductor structure 104. In some implementations, the interconnects in pad-out interconnect layer 1192 can transfer electrical signals between the semiconductor device and outside circuits, e.g., for pad-out purposes. In some implementations, second semiconductor structure 104 further includes one or more contacts 1194 extending through substrate 1188 and part of pad-out interconnect layer 1192 to couple pad-out interconnect layer 1192 to DRAM cells and interconnect layer 1180. As a result, peripheral circuits 1186 can be coupled to DRAM cells through interconnect layers 1170 and 1180 as well as bonding layers 1176 and 1184, and peripheral circuits 1186 and DRAM cells can be coupled to outside circuits through contacts 1194 and pad-out interconnect layer 1192. Contact pads 1196 and contacts 1194 can include conductive materials including, but not limited to, W, Co, Cu, Al, silicide, or any combination thereof. In one example, contact pad 1196 may include Al, and contact 1194 may include W. In some implementations, contact 1194 includes a via surrounded by a dielectric spacer (e.g., having silicon oxide) to electrically separate the via from substrate 1188. Depending on the thickness of substrate 1188, contact 1194 can be an ILV having a depth in the submicron-level (e.g., between 10 nm and 1 μm), or a TSV having a depth in the micron- or tens micron-level (e.g., between 1 μm and 100 μm).

In some implementations, a pad-out interconnect layer 1192 is formed on the backside of second semiconductor structure 104, i.e., pad-out interconnect layer 1192 and first semiconductor structure 102 can be formed on opposite sides of second semiconductor structure 104, as shown in FIG. 11H. In some implementations, at operation 1010, in FIG. 7, substrate 1102 is removed or thinned to couple with pad-out interconnect layer 1192. In some implementations, planarization processes (e.g., CMP) and/or etching processes are performed to remove substrate 1102 until being stopped by common plate 1104. Pad-out interconnect layer 1192 is removed to expose common plate 1104, so that the thickness of the semiconductor device can be reduced. In some implementations, one or more contacts 1178 extend through first isolation layer 1106, second isolation layer 1120, third isolation layer 1140, and fourth isolation layer 1154 to couple pad-out interconnect layer 1192 to peripheral circuit 1186 through interconnect layer 1170 and 1180. Contact pad 1196 may include Al, and contact 866 may include W.

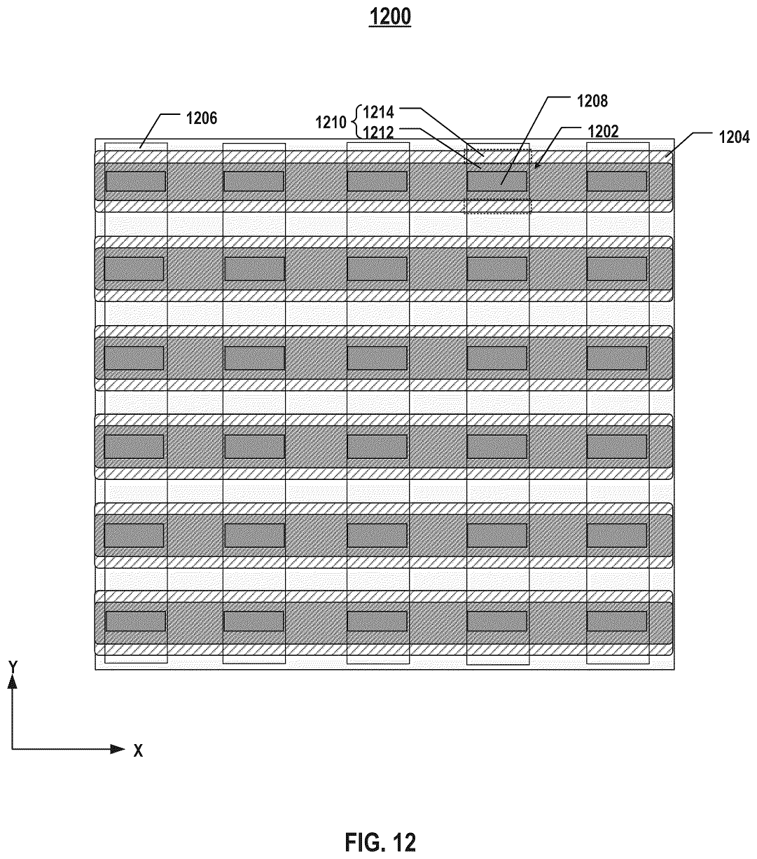

It is understood that the vertical transistors 1130 in first set of memory cells 1100A or vertical transistors 1164 in second set of memory cells 1100B are not limited to single-gate transistors as shown in FIGS. 9A-11H and may be double-gate transistors. As described above, in some examples, trench isolations 516 extending in the word line directions in FIG. 5 may not be formed such that two adjacent semiconductor layers 508 separated by a respective trench isolation 516 may be merged as a single semiconductor layer having two opposite sides in the bit line direction coupled with gate structure 510. That is, without trench isolations 516, the adjacent single-gate vertical transistors may be merged to form a double-gate vertical transistor (e.g., dual-side gate vertical transistor) with an increased gate control area and lower leakage current. For example, FIG. 12 illustrates a plan view of yet another array of memory cells 1202 each including a vertical transistor in a semiconductor device 1200, according to some aspects of the present disclosure. As shown in FIG. 12, semiconductor device 1200 can include a plurality of word lines 1204 each extending in a first lateral direction (the x-direction, referred to as the word line direction). Semiconductor device 1200 can also include a plurality of bit lines 1206 each extending in a second lateral direction perpendicular to the first lateral direction (the y-direction, referred to as the bit line direction). It is understood that FIG. 12 does not illustrate a cross-section of semiconductor device 1200 in the same lateral plane, and word lines 1204 and bit lines 1206 may be formed in different lateral planes for ease of routing as described below in detail.

Memory cells 1202 can be formed at the intersections of word lines 1204 and bit lines 1206. In some implementations, each memory cell 1202 includes a vertical transistor (e.g., vertical transistor 210 in FIG. 2) having a semiconductor layer 1208 and a gate structure 1210. Semiconductor layer 1208 can extend in a substrate in the vertical direction (the z-direction, not shown) perpendicular to the first and second lateral directions. The vertical transistor can be a double-gate transistor in which gate structure 1210 is coupled with two sides (e.g., two of four sides in FIG. 12) of semiconductor layer 1208 (the active region in which channels are formed). As shown in FIG. 12, the vertical transistor is a double-gate transistor in which gate structure 1210 abuts two opposite sides of semiconductor layer 1208 (having a rectangle or square-shaped cross-section) in the bit line direction (the y-direction) in the plan view. Gate structure 1210 does not surround and contact the other two sides of semiconductor layer 1208 in the word line direction (the x-direction), according to some implementations. That is, gate structure 1210 can partially circumscribe semiconductor layer 1208 in the plan view. Gate structure 1210 can include a gate dielectric 1212 abuts two opposite sides of semiconductor layer 1208 in the plan view, and a gate electrode 1214 coupled with gate dielectric 1212. In some implementations, gate dielectric 1212 is laterally between gate electrode 1214 and semiconductor layer 1208 in the bit line direction (the y-direction). As described above, gate electrode 1214 may be part of word line 1204, and word line 1204 may be an extension of gate electrode 1214. That is, gate electrodes 514 of adjacent vertical transistors in the word line direction (the x-direction) are continuous, e.g., parts of a continuous conductive layer having gate electrodes 1214 and 1204. In FIG. 12, gate dielectrics 1212 of adjacent vertical transistors in the word line direction are continuous, e.g., parts of a continuous dielectric layer having gate dielectrics 1212 and extending in the word line direction. Gate structures 1210 can be thus viewed as parts of a continuous structure extending in the word line direction at which the continuous structure intersects vertical transistors in the same row.

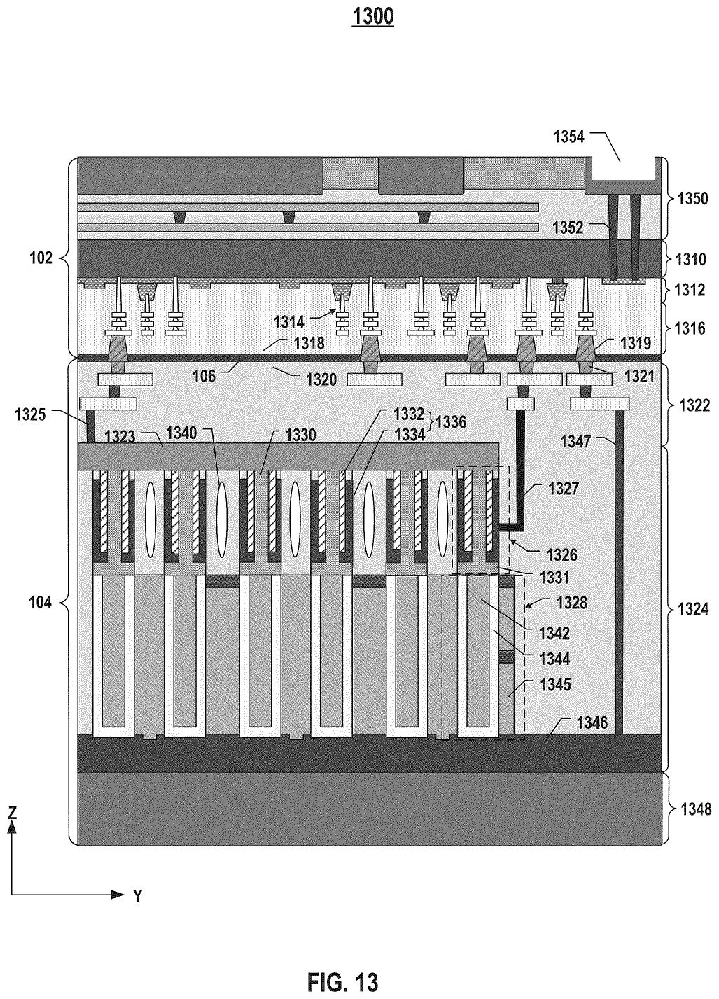

FIG. 13 illustrates a side view of a cross-section of yet another semiconductor device 1300 including vertical transistors, according to some aspects of the present disclosure, semiconductor device 1300 may be one example of semiconductor device 1200 including double-gate vertical transistors in which gate structures 1210 abut two sides of semiconductor layer 1208 in the plan view. It is understood that FIG. 13 is for illustrative purposes only and may not necessarily reflect the actual device structure (e.g., interconnections) in practice. As one example of semiconductor device 100 described above with respect to FIG. 1A, semiconductor device 1300 is a bonded chip including first semiconductor structure 102 and second semiconductor structure 104 stacked under first semiconductor structure 102. First and second semiconductor structures 102 and 104 are jointed at bonding interface 106 therebetween, according to some implementations. As shown in FIG. 13, first semiconductor structure 102 can include a substrate 1310, second semiconductor structure 104 can include a substrate 1348. Both substrates 1310 and 1348 can include silicon (e.g., single crystalline silicon, c-Si), SiGe, GaAs, Ge, SOI, or any other suitable materials.

First semiconductor structure 102 can include peripheral circuits 1312 formed on substrate 1310. In some implementations, peripheral circuits 1312 include a plurality of transistors 1314 (e.g., planar transistors and/or semiconductor transistors). Trench isolations (e.g., shallow trench isolations (STIs)) and doped regions (e.g., wells, sources, and drains of transistors 1314) can be formed on or in substrate 1310 as well.

In some implementations, first semiconductor structure 102 further includes an interconnect layer 1316 above peripheral circuits 1312 to transfer electrical signals to and from peripheral circuits 1312. Interconnect layer 1316 can include a plurality of interconnects (also referred to herein as “contacts”), including lateral interconnect lines and VIA contacts. Interconnect layer 1316 can further include one or more ILD layers in which the interconnect lines and via contacts can form. That is, interconnect layer 1316 can include interconnect lines and via contacts in multiple ILD layers. In some implementations, peripheral circuits 1312 are coupled to one another through the interconnects in interconnect layer 1316. The interconnects in interconnect layer 1316 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

As shown in FIG. 13, first semiconductor structure 102 can further include a bonding layer 1318 at bonding interface 106 and under interconnect layer 1316 and peripheral circuits 1312. Bonding layer 1318 can include a plurality of bonding contacts 1319 and dielectrics electrically isolating bonding contacts 1319. Bonding contacts 1319 can include conductive materials, such as Cu. The remaining area of bonding layer 1318 can be formed with dielectric materials, such as silicon oxide. Bonding contacts 1319 and surrounding dielectrics in bonding layer 1318 can be used for hybrid bonding. Similarly, as shown in FIG. 13, second semiconductor structure 104 can also include a bonding layer 1320 at bonding interface 106 and under bonding layer 1318 of first semiconductor structure 102. Bonding layer 1320 can include a plurality of bonding contacts 1321 and dielectrics electrically isolating bonding contacts 1321. Bonding contacts 1321 can include conductive materials, such as Cu. The remaining area of bonding layer 1320 can be formed with dielectric materials, such as silicon oxide. Bonding contacts 1321 and surrounding dielectrics in bonding layer 1320 can be used for hybrid bonding. Bonding contacts 1321 are coupled with bonding contacts 1319 at bonding interface 106, according to some implementations.

First semiconductor structure 102 can be bonded on top of second semiconductor structure 104 in a face-to-face manner at bonding interface 106. In some implementations, bonding interface 106 is disposed between bonding layers 1320 and 1318 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 106 is the place at which bonding layers 1320 and 1318 are met and bonded. In practice, bonding interface 106 can be a layer with a certain thickness that includes the bottom surface of bonding layer 1318 of first semiconductor structure 102 and the top surface of bonding layer 1320 of second semiconductor structure 104.

In some implementations, second semiconductor structure 104 further includes an interconnect layer 1322 including bit lines 1323 above bonding layer 1320 to transfer electrical signals. Interconnect layer 1322 can include a plurality of interconnects, such as MEOL interconnects and BEOL interconnects. In some implementations, the interconnects in interconnect layer 1322 also include local interconnects, such as bit lines 1323 and word line contacts 1327. Interconnect layer 1322 can further include one or more ILD layers in which the interconnect lines and via contacts can form. The interconnects in interconnect layer 1322 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof. In some implementations, peripheral circuits 1312 include a word line driver/row decoder coupled to the word line contacts in interconnect layer 1322 through bonding contacts 1321 and 1319 in bonding layers 1320 and 1318 and interconnect layer 1316. In some implementations, peripheral circuits 1312 include a bit line driver/column decoder coupled to bit lines 1323 and bit line contacts 1325 in interconnect layer 1322 through bonding contacts 1321 and 1319 in bonding layers 1320 and 1318 and interconnect layer 1316.

In some implementations, second semiconductor structure 104 includes a DRAM device in which memory cells are provided in the form of an array of DRAM cells 1324 (e.g., an example of memory cells 1202 in FIG. 12) under interconnect layer 1322 and bonding layer 1320. That is, interconnect layer 1322 including bit lines 1323 can be disposed between bonding layer 1320 and array of DRAM cells 1324. It is understood that the cross-section of semiconductor device 1300 in FIG. 13 may be made along the bit line direction (the y-direction), and one bit line 1323 in interconnect layer 1322 extending laterally in the y-direction may be coupled to a column of DRAM cells 1324.

Each DRAM cell 1324 can include a vertical transistor 1326 (e.g., an example of vertical transistors 210 in FIG. 2) and capacitor 1328 (e.g., an example of storage unit 212 in FIG. 2) coupled to the vertical transistor 1326. DRAM cell 1324 can be a 1T1C cell consisting of one transistor and one capacitor. It is understood that DRAM cell 1324 may be of any suitable configurations, such as 2T1C cell, 3T1C cell, etc.

Vertical transistor 1326 can be a MOSFET used to switch a respective DRAM cell 1324. In some implementations, vertical transistor 1326 includes a semiconductor layer 1330 (i.e., the active region in which channels can form) extending vertically (in the z-direction), and a gate structure 1336 coupled with two opposite sides of semiconductor layer 1330 in the bit line direction (the y-direction). In some implementations, the leakage value of the semiconductor layer is lower than a pico-ampere. For example, semiconductor layer 1330 can include a metal oxide semiconductor material. In present implementation, the metal oxide semiconductor can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

As described above, as in a double-gate vertical transistor, semiconductor layer 1330 can have a cuboid shape or a cylinder shape, and gate structure 1336 abuts two sides of semiconductor layer 1330 in the plan view, for example, as shown in FIG. 13. Gate structure 1336 includes a gate electrode 1334 and a gate dielectric 1332 laterally between gate electrode 1334 and semiconductor layer 1330 in the bit line direction, according to some implementations.

As shown in FIG. 13, in some implementations, an extending portion 1331 extends along the second lateral direction (the y-direction) from an end of semiconductor layer 630 and extending portion 1331 is coupled with the capacitor 1328. That is, a contact area between capacitor 1328 and vertical transistor 1326 equals an area of extending portion 1331 on the x-y plane, which is tens of times than an area of an end of semiconductor layer 1330 on the x-y plane. The contact resistance can be reduced significantly due to the increasement of contact area.

Vertical transistor 1326 can further include a source and a drain disposed at the two ends (the upper end and lower end) of semiconductor layer 1330, respectively, in the vertical direction (the z-direction). In some implementations, one of source and drain (e.g., at the lower end in FIG. 13) is coupled to capacitor 1328, and the other one of source and drain (e.g., at the upper end in FIG. 13) is coupled to bit line 1323. Source and drain can be doped with N-type dopants (e.g., P or As) or P-type dopants (e.g., B or Ga) at a desired doping level. In some implementations, a silicide layer, such as a metal silicide layer, is formed between source and drain and bit line 1323 or first electrode 1342 to reduce the contact resistance. In some implementations, gate dielectric 1332 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 1334 includes conductive materials including, but not limited to W, Co, Cu, Al, TiN, TaN, polysilicon, silicides, or any combination thereof. In some implementations, gate electrode 1334 includes multiple conductive layers, such as a W layer over a TiN layer. In one example, gate structure 1336 may be a “gate oxide/gate poly” gate in which gate dielectric 1332 includes silicon oxide and gate electrode 1334 includes doped polysilicon. In another example, gate structure 1336 may be an HKMG in which gate dielectric 1332 includes a high-k dielectric and gate electrode 1334 includes a metal.

As described above, since gate electrode 1334 may be part of a word line or extend in the word line direction as a word line, second semiconductor structure 104 of semiconductor device 1300 can also include a plurality of word lines 1334 (referred to as 1334 as well) each extending in the word line direction. Each word line 1334 can be coupled to a row of DRAM cells 1324. That is, bit line 1323 and word line 1334 can extend in two perpendicular lateral directions, and semiconductor layer 1330 of vertical transistor 1326 can extend in the vertical direction perpendicular to the two lateral directions in which bit line 1323 and word line 1334 extend. Word lines 1334 are coupled with word line contacts (not shown), according to some implementations. In some implementations, word lines 1334 include conductive materials including, but not limited to W, Co, Cu, Al, TiN, TaN, polysilicon, silicides, or any combination thereof. In some implementations, word line 1334 includes multiple conductive layers, such as a W layer over a TiN layer.

As shown in FIG. 13, vertical transistor 1326 extends vertically through and is coupled with a corresponding word line 1334, and source or drain of vertical transistor 1326 at the upper end thereof is coupled with bit line 1323 (or bit line contact 1325), according to some implementations. Accordingly, word lines 1334 and bit lines 1323 can be disposed in different planes in the vertical direction due to the vertical arrangement of vertical transistor 1326, which simplifies the routing of word lines 1334 and bit lines 1323. In some implementations, bit lines 1323 are disposed vertically between bonding layer 1320 and word lines 1334, and word lines 1334 are disposed vertically between bit lines 1323 and capacitors 1328. Word lines 1334 can be coupled to peripheral circuits 1312 in first semiconductor structure 102 through word line contacts in interconnect layer 1322, bonding contacts 1321 and 1319 in bonding layers 1320 and 1318, and the interconnects in interconnect layer 1316. Similarly, bit lines 1323 in interconnect layer 1322 can be coupled to peripheral circuits 1312 in first semiconductor structure 102 through bonding contacts 1321 and 1319 in bonding layers 1320 and 1318 and the interconnects in interconnect layer 1316.

In some implementations, second semiconductor structure 104 further includes a plurality of air gaps 1340 each disposed laterally between adjacent word lines 1334. Each air gap 1340 can be a trench extending in the word line direction (e.g., the x-direction) in parallel with word lines 1334 to separate adjacent rows of vertical transistors 1326. As described below with respect to the fabrication process, air gaps 1340 may be formed due to the relatively small pitches of word lines 1334 (and rows of DRAM cells 1324) in the bit line direction (e.g., the y-direction). On the other hand, the relatively large dielectric constant of air in air gaps 1340 (e.g., about 4 times of the dielectric constant of silicon oxide) can improve the insulation effect between word lines 1334 (and rows of DRAM cells 1324) compared with some dielectrics (e.g., silicon oxide).

As shown in FIG. 13, in some implementations, capacitor 1328 includes a first electrode 1342 above and is coupled with source or drain of vertical transistor 1326, e.g., the lower end of semiconductor layer 1330. Capacitor 1328 can also include a capacitor dielectric 1344 above and coupled with first electrode 1342, and a second electrode 1345 above and coupled with capacitor dielectric 1344. That is, capacitor 1328 can be a vertical capacitor in which first electrodes 1342, second electrode 1345, and capacitor dielectric 1344 are stacked vertically (in the z-direction), and capacitor dielectric 1344 can be sandwiched between first and second electrodes 1342 and 1345. In some implementations, each first electrode 1342 is coupled to source or drain of a respective vertical transistor 1326 in the same DRAM cell, while all second electrodes 1345 are parts of a common plate 1346 coupled to the ground, e.g., a common ground. As shown in FIG. 13, second semiconductor structure 104 can further include a capacitor contact 1347 coupled with the common plate 1346 of second electrodes 1345 for coupling second electrodes 1345 of capacitor 1328 to peripheral circuits 1312 or to the ground directly. In some implementations, the ILD layer in which capacitors 1328 are formed has the same dielectric material as the two ILD layers into which semiconductor layer 1330 extends, such as silicon oxide.

It is understood that the structure and configuration of capacitor 1328 are not limited to the example in FIG. 13 and may include any suitable structure and configuration, such as a planar capacitor, a stack capacitor, a multi-fins capacitor, a cylinder capacitor, a trench capacitor, or a substrate-plate capacitor. In some implementations, capacitor dielectric 1344 includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, capacitor 1328 may be a ferroelectric capacitor used in a FRAM cell, and capacitor dielectric 1344 may be replaced by a ferroelectric layer having ferroelectric materials, such as (PZT or SBT. In some implementations, first and second electrodes 1342 and 1345 include conductive materials including, but not limited to W, Co, Cu, Al, TiN, TaN, polysilicon, silicides, or any combination thereof.

As shown in FIG. 13, vertical transistor 1326 extends vertically through and is coupled with a corresponding word line 1334. Source or drain of vertical transistor 1326 at the upper end thereof is coupled with bit line 1323 directly or through the bit line contact 1325, and source or drain of vertical transistor 1326 at the lower end thereof is coupled with first electrode 1342 of capacitor 1328, according to some implementations. That is, bit line 1323 and capacitor 1328 can be disposed in different planes in the vertical direction and coupled to opposite ends of vertical transistor 1326 of DRAM cell 1324 in the vertical direction due to the vertical arrangement of vertical transistor 1326. In some implementations, bit line 1323 and capacitor 1328 are disposed on opposite sides of vertical transistor 1326 in the vertical direction, which simplifies the routing of bit lines 1323 and reduces the coupling capacitance between bit lines 1323 and capacitors 1328 compared with conventional DRAM cells in which the bit lines and capacitors are disposed on the same side of the planar transistors.

As shown in FIG. 13, in some implementations, vertical transistors 1326 are disposed vertically between capacitors 1328 and bonding interface 106. That is, vertical transistors 1326 can be arranged closer to peripheral circuits 1312 of first semiconductor structure 102 and bonding interface 106 than capacitors 1328. Since bit lines 1323 and capacitors 1328 are coupled to opposite ends of vertical transistors 1326, as described above, bit lines 1323 (as part of interconnect layer 1322) are disposed vertically between vertical transistors 1326 and bonding interface 106, according to some implementations. As a result, interconnect layer 1322 including bit lines 1323 can be arranged close to bonding interface 106 to reduce the interconnect routing distance and complexity.

In some implementations, first semiconductor structure 102 further includes a substrate 1348 disposed under DRAM cells 1324. As described below with respect to the fabrication process, substrate 1348 can be part of a carrier wafer. It is understood that in some examples, substrate 1348 may not be included in second semiconductor structure 104.

As shown in FIG. 13, second semiconductor structure 104 can further include a pad-out interconnect layer 1350 above peripheral circuit 1312 and substrate 1348. Pad-out interconnect layer 1350 can include interconnects, e.g., contact pads 1354, in one or more ILD layers. Pad-out interconnect layer 1350 and interconnect layer 1316 can be formed on opposite sides of peripheral circuit 1312. In some implementations, the interconnects in pad-out interconnect layer 1350 can transfer electrical signals between semiconductor device 1300 and outside circuits, e.g., for pad-out purposes. In some implementations, first semiconductor structure 102 further includes one or more contacts 1352 extending through substrate 1310 and part of pad-out interconnect layer 1350 to couple pad-out interconnect layer 1350 to peripheral circuit 1312 and interconnect layer 1316.

As a result, DRAM cells 1324 can be coupled to peripheral circuit 1312 through interconnect layers 1316 and 1322 as well as bonding layers 1320 and 1318, and peripheral circuits 1312 and DRAM cells 1324 can be coupled to outside circuits through contacts 1352 and pad-out interconnect layer 1350. Contact pads 1354 and contacts 1352 can include conductive materials including, but not limited to, W, Co, Cu, Al, silicide, or any combination thereof. In one example, contact pad 1354 may include Al, and contact 1352 may include W. In some implementations, contact 1352 includes a via surrounded by a dielectric spacer (e.g., having silicon oxide) to electrically separate the via from substrate 1310. Depending on the thickness of substrate 1310, contact 1352 can be an ILV having a depth in the submicron-level (e.g., between 10 nm and 1 μm), or a TSV having a depth in the micron- or tens micron-level (e.g., between 1 μm and 100 μm).

Although not shown, it is understood that the pad-out of semiconductor devices is not limited to from first semiconductor structure 102 having peripheral circuit 1312 as shown in FIG. 13 and may be from second semiconductor structure 104 having DRAM cells 1324 in the similar manner as described above with respect to FIG. 6A. Although not shown, it is also understood that the air gaps 1340 between word lines 1334 may be partially or fully filled with dielectrics in the similar manner as described above. Although not shown, it is further understood that more than one array of DRAM cells 1324 may be stacked over one another to vertically scale up the number of DRAM cells 1324 in the similar manner as described above with respect to FIGS. 9A and 9B.

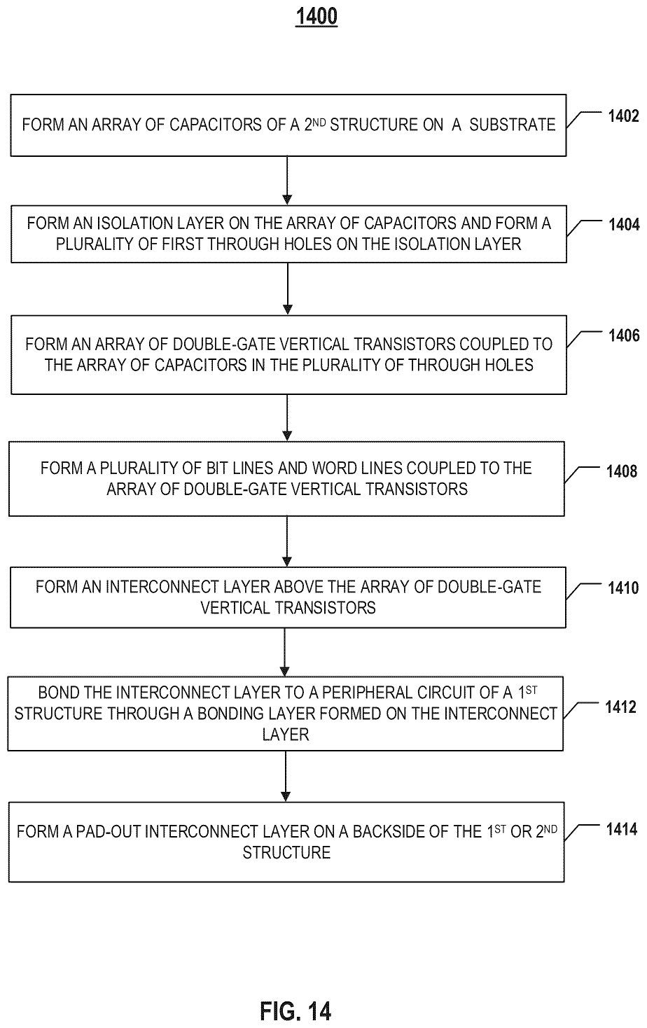

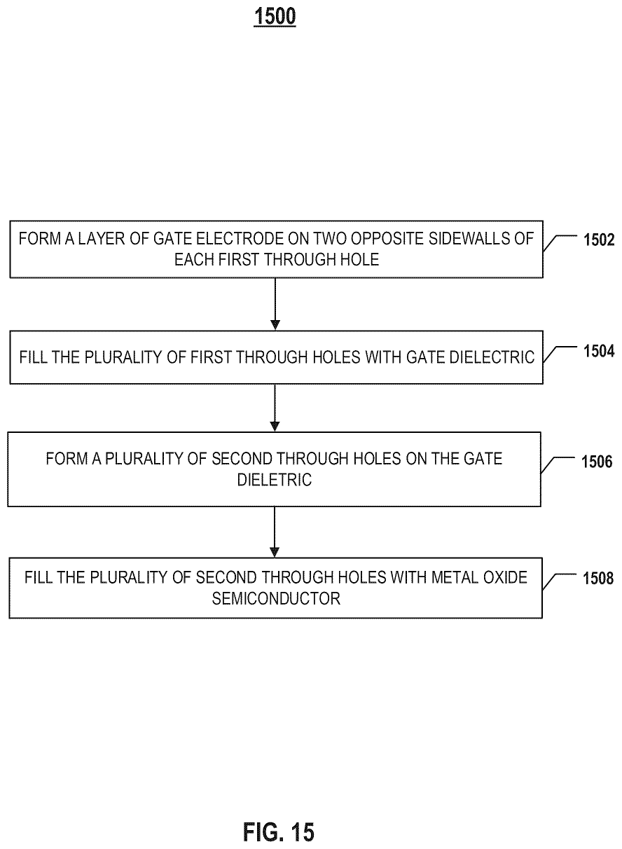

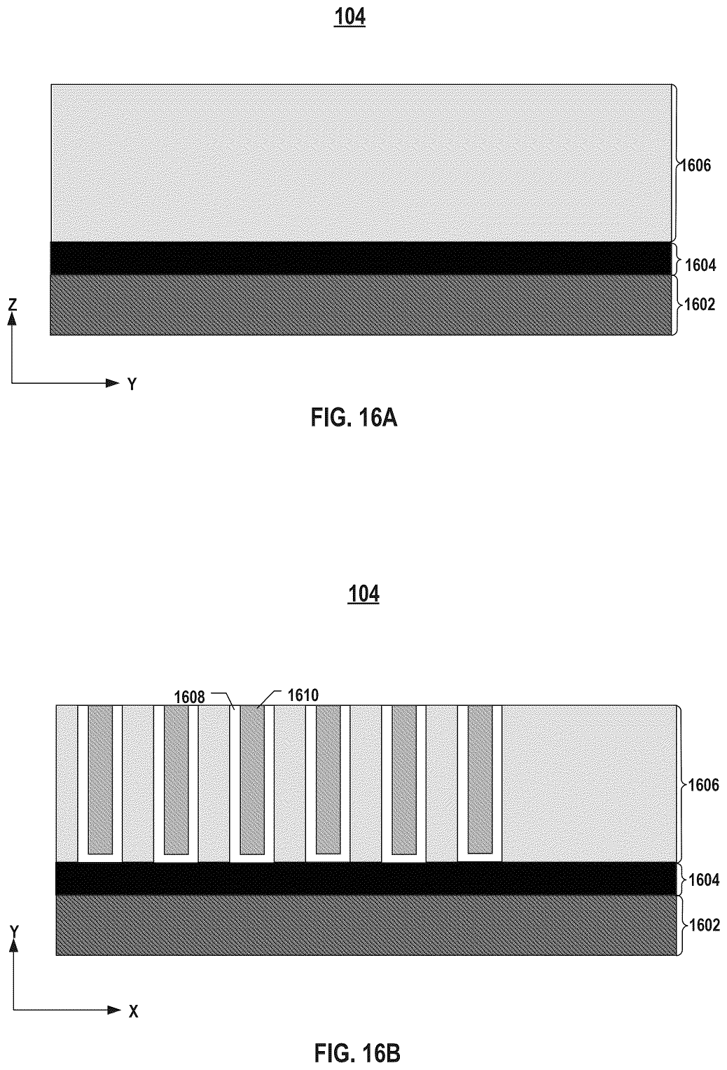

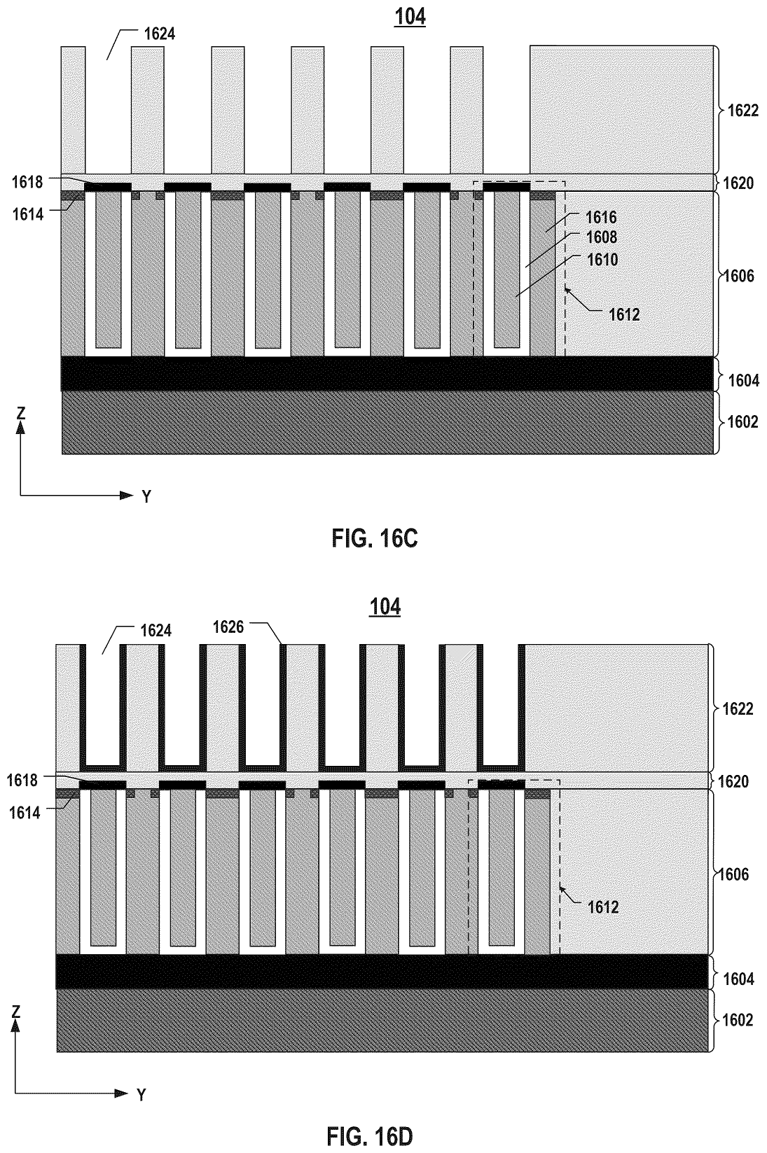

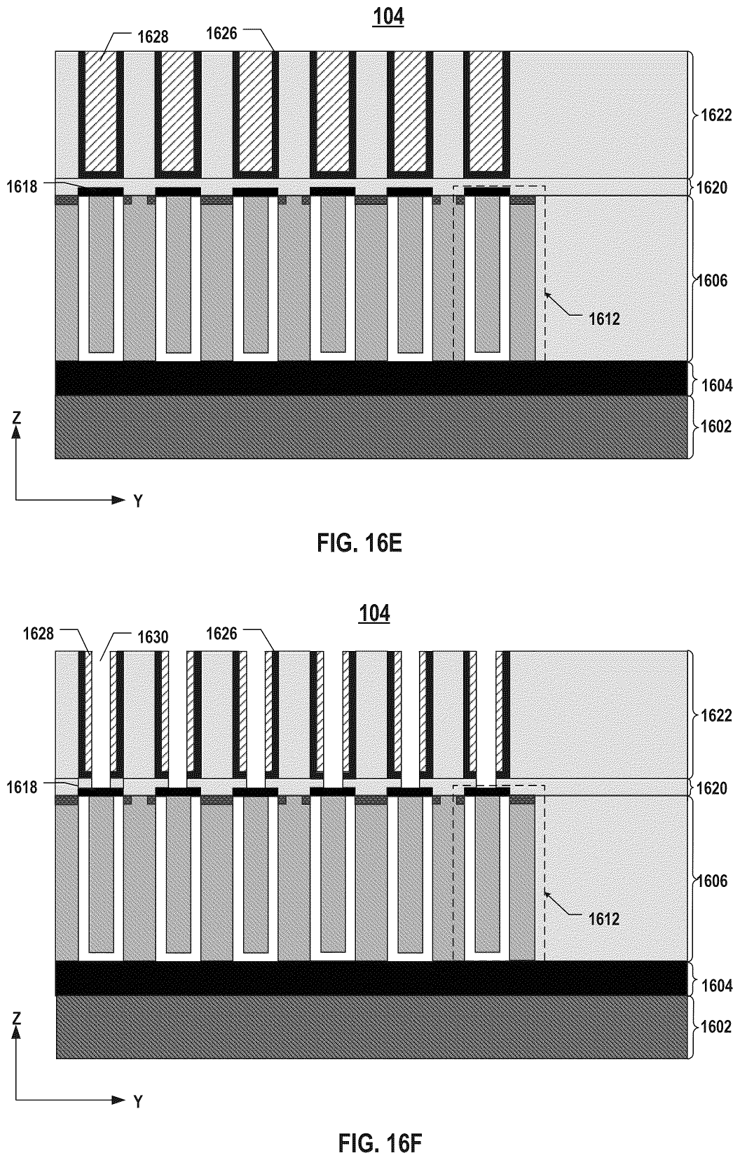

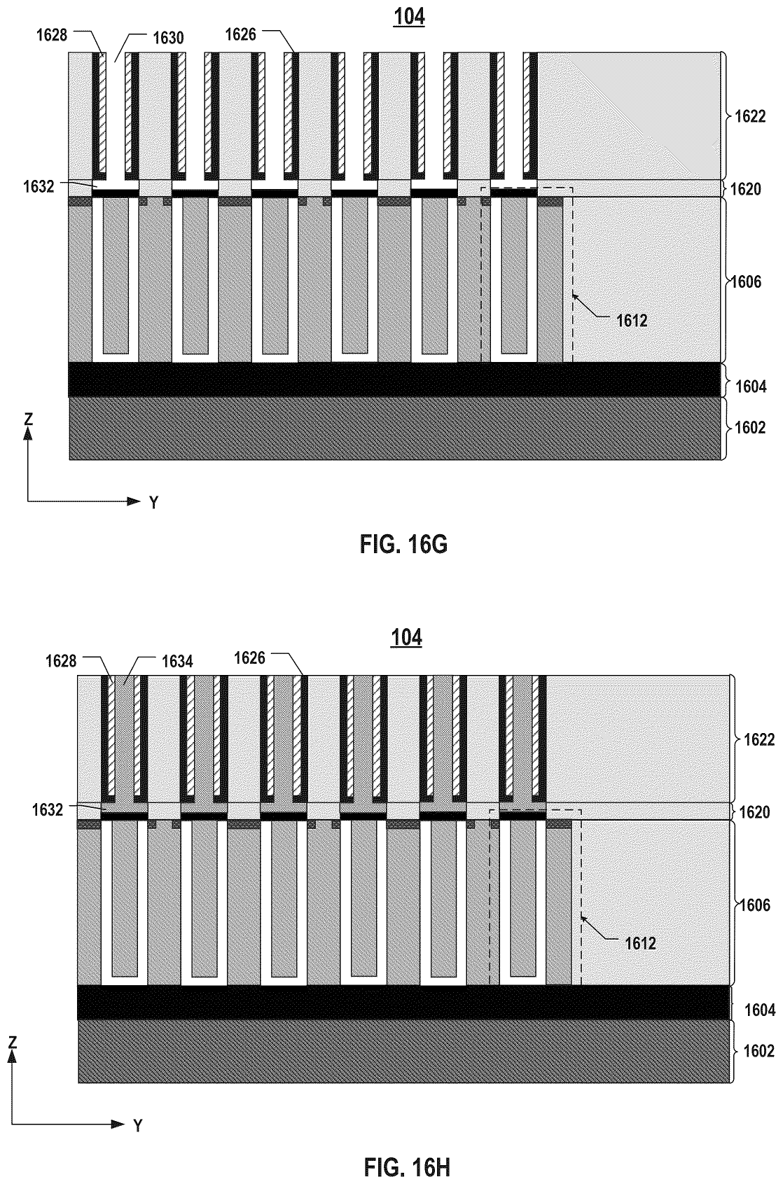

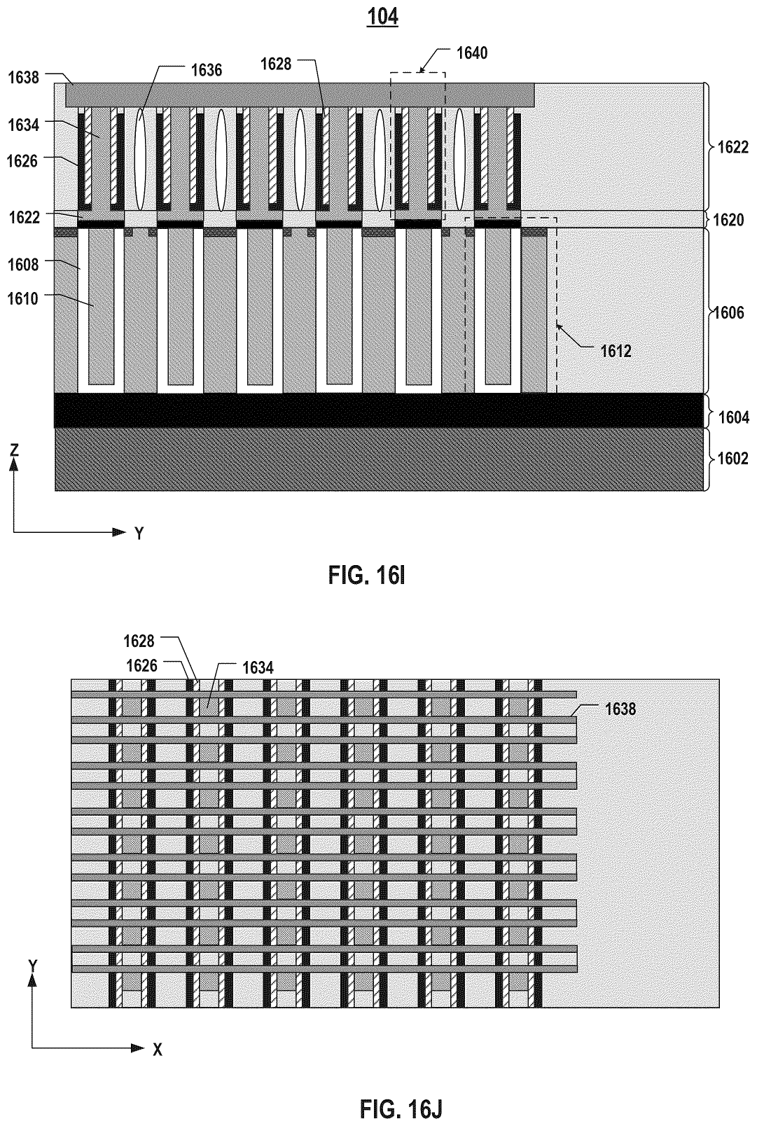

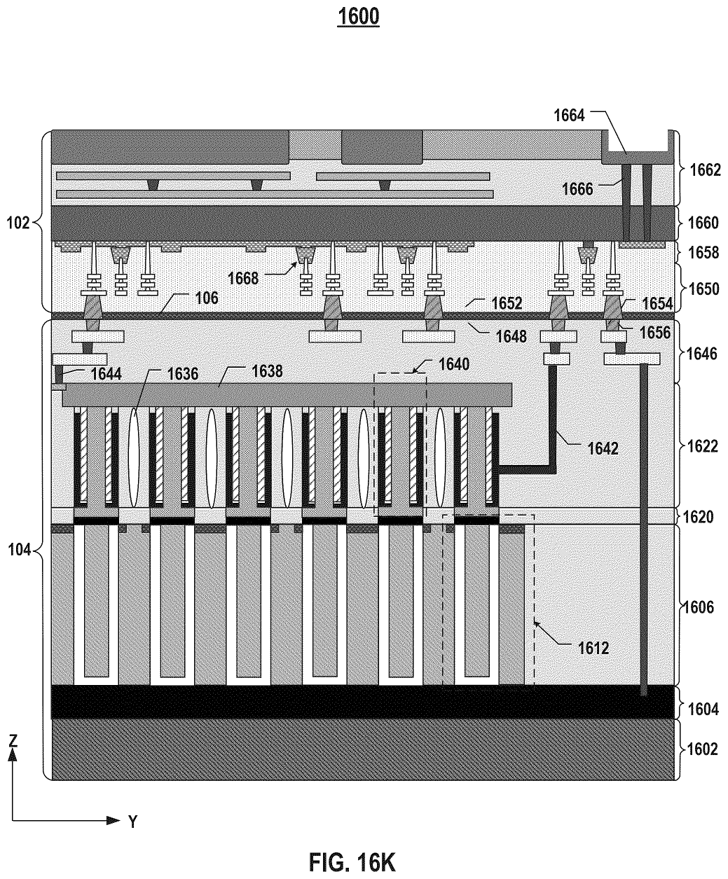

FIG. 14 illustrates a flowchart of a method 1400 for forming a semiconductor device including double-gate vertical transistors, such as semiconductor device 1300 described above in connection with FIG. 13, according to some implementations of the present disclosure. FIG. 15 illustrates a flowchart of a method 1500 for forming double-gate vertical transistors in semiconductor device 1300 according to some implementations of the present disclosure. FIGS. 16A-16K illustrate a fabrication process for forming a semiconductor device 1300 at certain fabricating stages of the method 1400 shown in FIG. 14, according to various implementations of the present disclosure. It is understood that the operations shown in method 1400 are not exhaustive and that other operations can be performed as well before, after, or between any of the illustrated operations. Further, some of the operations may be performed simultaneously, or in a different order than shown in FIG. 14.

As shown in FIG. 14, method 1400 can start at operation 1402, in which an array of capacitors 1612 can be formed on a substrate 1602. Referring to FIG. 16B, the array of capacitors 1612 is a part of second semiconductor structure 104 as discussed above. First semiconductor structure 102 and second semiconductor structure 104 can be formed separately through independent fabrication processes and will be bonded together after corresponding fabrication processes are completed. First semiconductor structure 102 may be formed before, after, or at the same time as second semiconductor structure 104. The sequence of the fabrication of first and second semiconductor structures 102 and 104 are not limited in the implementations of the present disclosure and can be arranged and adjusted according to practical needs.

In some implementations, a first step of operation 1402 of method 1400 is proceeded, as shown in FIG. 16A, in which a metal layer 1604 is formed on first substrate 1602 and a dielectric layer 1606 is formed on metal layer 1604, FIG. 16A illustrates a schematic side cross-sectional view of the semiconductor device in y-z plane after dielectric layer 1606 is formed. Then a second step of operation 1402 of method 1400 is proceeded, in which an array of through holes are formed on dielectric layer 1606, then a capacitor dielectric 1608 and a first electrode 1610 of a capacitor 1612 is formed in each of the through holes. FIG. 16B illustrates a schematic side cross-sectional view of the semiconductor device in y-z plane after first electrode 1610 is formed.

In some implementations, the substrate 1602 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the array of capacitors 1612 can be formed directly on the semiconductor substrate 1602, and the transistor can be formed on a front side of the array of capacitors 1612 in subsequent processes. In some other implementations, the substrate 1602 can be a carrier substrate, which can include any suitable semiconductor materials, or an electrically non-conductive material, such as a glass, a plastic, or a sapphire wafer. In such implementations, the array of capacitors 1612 can be formed directly on another semiconductor substrate, and the carrier substrate 1602 can be formed on a front side of the array of capacitors 1612. After flipping over the structure and removing the semiconductor substrate, the transistor can be formed on a back side of the array of capacitors 1612 in subsequent processes.

The array of capacitors 1612 can include a second electrode 1616 coupled with a common plate, i.e., metal layer 1604, a plurality of first electrode 1610, and a capacitor dielectric 1608 between first electrodes 1610 and second electrode 1616. As shown, the array of capacitors 1612 can be an array. In some implementations, first electrodes 1610 and/or the second electrode 1616 can include conductive materials including, but not limited to, W, Co, Cu, Al, TiN, TaN, polysilicon, silicide, or any combination thereof. In some implementations, capacitor dielectric 808 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, capacitors 1612 have a relatively large height and need to be mechanically stabilized with a mesh 1614, as shown in FIG. 16C. As such, the spacing between them doesn't vary, thereby avoiding capacitor corrupts. Without mesh 1614, the capacitors would lean over and contact adjacent capacitors. Mesh 1614 includes larger dielectric materials with a Mohs scale larger than silicon oxide, which has a Mohs scale around six. In some implementations, mesh 1614 can be silicon nitride, silicon carbide, corundum, boron carbide, boron nitride, or any combination thereof. In some implementations, with the increasement of the aspect ratio of the capacitors 1612, two or more levels of mesh are required for mechanical stability. In some implementations, an opening is formed on mesh 1614 among a group of capacitors 1612, each capacitor is connected to at least one opening, every four capacitors 1612 in a same group share a same opening. In the present implementation, the openings can be, but not limited to, irregular polygon, round, oval, triangle, rectangular, hexagonal, or other shapes. The number of capacitors in the same group can be set as needed, for example four, six, eight, etc. In some implementations, dielectric layer 1606, also called sacrifice layer, positioned under mesh 1614 can be replaced by a conductor to form second electrode 1616 electrically connected with the common plate. The sacrifice layer can be moved by wet/dry etch, or any other suitable processes, and second electrode 1616 includes conductive materials including, but not limited to, W, Co, Cu, Al, TiN, TaN, polysilicon, silicide, or any combination thereof.

In some implementations, to suppress drain induced barrier lowering (DIBL), the doping concentration of substrate is increased, resulting in an increasement of the junction leakage current. The increased leakage current can consume more power and deteriorate the retention capability of a semiconductor device. To solve this problem, storage node contacts 1618 are introduced on the top of capacitor 1612 as shown in FIG. 16B. Storage node contacts 1618 can be made of doped amorphous silicon, doped polysilicon, doped single crystal silicon, or doped silicon germanium (SiₓGe₁₋ₓ). Thus the resistance between capacitor 1612 and a corresponding vertical transistor can be controlled by adjusting the doping concentration of storage node contacts 1618.

In some implementations, the array of capacitors 1612 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc. It is noted that, the fabricating processes and/or orders of forming the first electrodes 1610, the second electrode 1616, and the capacitor dielectric 1608 can be varied depending on a front side process or a back side process.

As shown in FIG. 14, method 1400 can proceed to operation 1404, in which an isolation layer is formed on dielectric layer 1606, and a plurality of first through holes 1624 are formed on the isolation layer, as shown in FIG. 16C.

In some implementations, the isolation layer includes a first isolation layer 1620 and a second isolation layer 1622 covering first isolation layer 1620. First isolation layer 1620 is formed on storage node contacts 1618 to isolate storage node contacts 1618 from the double-gate vertical transistors which will be formed subsequently. In some implementations, the thickness of first isolation layer 1620 is equal to or larger than a thickness of storage node contacts 1618 to avoid leakage current and parasitic capacitance. Second isolation layer 1622 is formed as a frame to form the double-gate vertical transistors.

In some implementations, a plurality of first through holes 1624 is formed on and penetrates second isolation layer 1622. The plurality of first through holes 1624 corresponds to the array of capacitors 1612 one by one. First through holes 1624 are stopped at a top surface of first isolation layer 1620 which covers storage node contacts 1618 and the array of capacitors 1612. First isolation layer 1620 and second isolation layer 1622 can be formed with dielectric materials including, but not limited to, silicon oxide, silicon nitride, silicon oxynitride, low-k dielectrics, or any combination thereof. In some implementations, first isolation layer 1620 and second isolation layer 1622 may be made of different dielectrics for easy fabrication. For example, first isolation layer 1620 is made of silicon oxide and second isolation layer 1622 silicon nitride or silicon oxynitride.

As shown in FIG. 14, method 1400 can proceed to operation 1406, in which an array of double-gate vertical transistors 1640 coupled to the array of capacitors is formed in the plurality of through holes 1624. FIG. 15 illustrates a flowchart of a method 1500 for forming double-gate vertical transistors 1326 in semiconductor device 1300 according to some implementations of the present disclosure.

In some implementations, as shown in FIG. 15, method 1500 can proceed to operation 1502, in which a layer of gate electrode 1626 is formed on two opposite sidewalls of each first through holes 1624, as shown in FIG. 16D, FIG. 16D illustrates a schematic side cross-sectional view of the semiconductor device 1600 in y-z plane after operation 1506 of method 1500. Gate electrode 1626 can include any suitable conductive materials, such as polysilicon, metals (e.g., W, Cu, Al, etc.), metal compounds (e.g., TiN, TaN, etc.), or silicide. For example, gate electrode 1626 may include doped polysilicon, i.e., a gate poly. In some implementations, gate electrode 1626 includes multiple conductive layers, such as a W layer over a TiN layer. Gate electrode 1626 can be deposited by one or more thin film deposition processes including, but not limited to, chemical vapor deposition (CVD), physical vapor deposition (PVD), atomic layer deposition (ALD), electroplating, electroless plating, or any combination thereof.

As shown in FIG. 15, method 1500 can proceed to operation 1504, in which first through holes 1624 are filled with gate dielectric 1628, as shown in FIG. 16E, FIG. 16E illustrates a schematic side cross-sectional view of the semiconductor device 1600 in y-z plane after operation 1504 of method 1500. Gate dielectric 1628 can include any suitable dielectric materials, such as silicon oxide, silicon nitride, silicon oxynitride, or high-k dielectrics. For example, gate dielectric layer 826 may include silicon oxide, i.e., gate oxide.

As shown in FIG. 15, method 1500 can proceed to operation 1506, in which a plurality of second through holes 1630 are formed in gate dielectric 1628, as shown in FIG. 16F, FIG. 16F illustrates a schematic side cross-sectional view of the semiconductor device 1600 in y-z plane after operation 1506 of method 1500.

In some implementations, a lithography process is performed to pattern the array of second through holes 1630 using an etch mask (e.g., a photoresist mask), for example, one or more dry etching and/or wet etching processes, such as reactive ion etch (RIE), are performed to etch second through holes 1630 through gate dielectric 1628 and first isolation layer 1620 until being stopped by storage node contacts 1618. In some implementations, a selective etching is performed against first isolation layer 1620 along x-y plane to form a cavity 1632 at an end of second through holes 1630 close to storage node contacts 1618, as shown in FIG. 16G. By forming cavity 1632, a part of first isolation layer 1620 covering storage node contacts 1618 would be replaced by semiconductor materials in subsequent processes, thus a contact area between the array of capacitors and the array of double-gate vertical transistors can be expended to reduce the contact resistance.

As shown in FIG. 15, method 1500 can proceed to operation 1508, in which the plurality of second through holes 1630 are filled with semiconductor layer 1634, as shown in FIG. 16H, FIG. 16H illustrates a schematic side cross-sectional view of the semiconductor device 1600 in y-z plane after operation 1508 of method 1500.

As shown in FIG. 16H, each double-gate vertical transistor 1640 includes a semiconductor layer 1634 extending vertically from an end of second through hole 1630 where storage node contacts 1618 are positioned to another end opposite to storage node contact 1618. Gate dielectric 1628 is coupled to semiconductor layer 1634 on two opposite sides of semiconductor layer 1634 of each vertical transistor 1640. Gate electrode 1626 is coupled to gate dielectric 1628 of each vertical transistor 1640. With a gate structure (e.g., gate electrode 1626 and gate dielectric 1628) on two opposite sides of semiconductor layer 1634, double-gate vertical transistor 1640 can achieve an increased gate control area and lower leakage current. In some implementations, semiconductor layer 1634 can be formed from a deposition process. In some implementations, the semiconductor can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

Vertical transistor 1640 can further include a source and a drain disposed at the two ends of semiconductor layer 1634, respectively, in the vertical direction. In some implementations, one of source and drain is coupled to capacitor 1612, and the other one of source and drain is coupled to bit line. In some implementations, gate electrode 1626 is etched to expose an end of semiconductor layer 1634 so that at least one end of semiconductor layer 1634 extends beyond gate electrode 1626 along vertical direction (e.g., z direction), as shown in FIG. 16I.

As shown in FIG. 16I, method 1400 can proceed to operation 1408, in which a plurality of bit lines 1638 and word lines 1626 (referred to 1626 as well) can be formed on the array of vertical transistors 1640. FIG. 16I illustrates a schematic side cross-sectional view of the semiconductor device in y-z plane after operation 1408 of method 1400. FIG. 16J illustrates a schematic side cross-sectional view of the semiconductor device in x-y plane after operation 1408 of method 1400.

As shown in FIGS. 16H and 16I, vertical transistor 1640 extends vertically through and is coupled with a corresponding word line 1626, and source or drain of vertical transistor 1640 at the upper end thereof is coupled with bit line 1638 (or bit line contact if any), according to some implementations. Accordingly, word lines 1626 and bit lines 1638 can be disposed in different planes in the vertical direction due to the vertical arrangement of vertical transistor 1640, which simplifies the routing of word lines 1626 and bit lines 1638. Bit lines 1638 extend along y direction and are coupled with two opposite sides of semiconductor layer 1634, word lines 1626 are disposed vertically between bit lines 1638 and capacitors 1612. In some implementations, bit lines 1638 extend along y direction and are coupled with one side of semiconductor layer 1634 (not shown).

In some implementations, the rows of vertical transistors 1640 separated by trench isolation 1636 are mirror-symmetric to one another with respect to trench isolation 1636. Trench isolation 1636 can be formed with dielectric materials including, but not limited to, silicon oxide, silicon nitride, silicon oxynitride, low-k dielectrics, or any combination thereof. It is understood that trench isolation 1636 may include an air gap each disposed laterally between adjacent semiconductor layers 1634. As described below with respect to the fabrication process, air gaps may be formed due to the relatively small pitches of vertical transistors 1640 in the bit line direction (e.g., the y-direction). On the other hand, the relatively large dielectric constant of air in the air gap can improve the insulation effect between vertical transistors 1640 compared with some dielectrics (e.g., silicon oxide). Similarly, in some implementations, air gaps are formed laterally between word lines/gate electrodes 1626 in the bit line direction as well, depending on the pitches of word lines/gate electrodes 1626 in the bit line direction.

As shown in FIG. 14, method 1400 can proceed to operation 1410, in which an interconnect layer 1646 is formed above the array of vertical transistors 1640. Method 1400 can then proceed to operation 1412, in which interconnect layer 1646 is bonded to a peripheral circuit 1658 of first semiconductor structure 102 through a bonding layer 1652 formed above interconnect layer 1646. Method 1400 can then proceed to operation 1414, in which a pad-out interconnect layer 1662 is formed. FIG. 16K illustrates a schematic side cross-sectional view of the semiconductor device 1600 in y-z plane after operation 1414 of method 1400.

As shown in FIG. 16K, second semiconductor structure 104 can also include a bonding layer 1648 at bonding interface 106 to be coupled to a bonding layer of first semiconductor structure 102. Bonding layer 1648 can include a plurality of bonding contacts 1656 and dielectrics electrically isolating bonding contacts 1656. Bonding contacts 1656 can include conductive materials, such as Cu. The remaining area of bonding layer 1648 can be formed with dielectric materials, such as silicon oxide. Bonding contacts 1654 and surrounding dielectrics in bonding layer 1652 can be used for hybrid bonding. Bonding contacts 1656 are coupled with bonding contacts of first semiconductor structure 102 at bonding interface 106, according to some implementations.

In some implementations, interconnect layer 1646 can include a plurality of interconnects, such as MEOL interconnects and BEOL interconnects. In some implementations, the interconnects in interconnect layer 1646 also include local interconnects, such as bit lines 1638, bit line contacts 1644 (which may be omitted in some examples), and word line contacts 1642. Interconnect layer 1646 can further include one or more ILD layers in which the interconnect lines and via contacts can form. The interconnects in interconnect layer 1646 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof. In some implementations, interconnect layer 1646 including bit lines 1638 can be disposed between bonding layer 1648 and array of vertical transistors 1640.

First semiconductor structure 102 can include peripheral circuits 1658 on substrate 1660. In some implementations, peripheral circuits 1658 includes a plurality of transistors 1668 (e.g., planar transistors and/or semiconductor transistors). Trench isolations (e.g., shallow trench isolations (STIs)) and doped regions (e.g., wells, sources, and drains of transistors 1668) can be formed on or in substrate 1660 as well. In some implementations, first semiconductor structure 102 further includes an interconnect layer 1646 under peripheral circuits 1658 to transfer electrical signals to and from peripheral circuits 1658. Interconnect layer 1650 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 1650 can further include one or more interlayer dielectric (ILD) layers (also known as “intermetal dielectric (IMD) layers”) in which the interconnect lines and via contacts can form. That is, interconnect layer 1650 can include interconnect lines and via contacts in multiple ILD layers. In some implementations, peripheral circuits 1658 are coupled to one another through the interconnects in interconnect layer 1650. The interconnects in interconnect layer 1650 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

First semiconductor structure 102 can further include a bonding layer 1652 at bonding interface 106 and above interconnect layer 1650. Bonding layer 1652 can include a plurality of bonding contacts 1654 and dielectrics electrically isolating bonding contacts 1654. Bonding contacts 1654 can include conductive materials, such as Cu. The remaining area of bonding layer 1652 can be formed with dielectric materials, such as silicon oxide. Bonding contacts 1654 and surrounding dielectrics in bonding layer 1652 can be used for hybrid bonding. In some implementations, peripheral circuits 1658 includes a word line driver/row decoder coupled to word line contacts 1642 in interconnect layer 1646 through bonding contacts 1654 and 1656 in bonding layers 1652 and 1648 and interconnect layer 1650. In some implementations, peripheral circuits 1658 includes a bit line driver/column decoder coupled to bit lines 1638 and bit line contacts 1644 in interconnect layer 1646 through bonding contacts 1654 and 1656 in bonding layers 1652 and 1648 and interconnect layer 1650.

In some implementations, a pad-out interconnect layer 1662 is formed on the backside of the first semiconductor structure 102, as shown in FIG. 16K. In some implementations, pad-out interconnect layer 1662 is formed on the backside of the second semiconductor structure 104 (not shown).

Referring to FIG. 16K, pad-out interconnect layer 1662 is formed on the backside of substrate 1660 of first semiconductor structure 102. Pad-out interconnect layer 1662 can include interconnects, e.g., contact pads 1664, in one or more ILD layers. Pad-out interconnect layer 1662 and first semiconductor structure 102 can be formed on a same side as second semiconductor structure 104. In some implementations, the interconnects in pad-out interconnect layer 1662 can transfer electrical signals between the semiconductor device and outside circuits, e.g., for pad-out purposes. In some implementations, second semiconductor structure 104 further includes one or more contacts 1666 extending through substrate 1660 and part of pad-out interconnect layer 1662 to couple pad-out interconnect layer 1662 to DRAM cells and interconnect layer 1646. As a result, peripheral circuits 1658 can be coupled to DRAM cells through interconnect layers 1646 and 1650 as well as bonding layers 1652 and 1648, and peripheral circuits 1658 and DRAM cells can be coupled to outside circuits through contacts 1666 and pad-out interconnect layer 1662.

In some implementations, a pad-out interconnect layer 1662 is formed on the backside of second semiconductor structure 104, i.e., pad-out interconnect layer 1662 and first semiconductor structure 102 can be formed on opposite sides of second semiconductor structure 104, not shown. In some implementations, at operation 1414 in FIG. 14, substrate 1602 is removed or thinned to couple with pad-out interconnect layer 1662. In some implementations, planarization processes (e.g., CMP) and/or etching processes are performed to remove substrate 1602 until being stopped by metal layer 1604. Pad-out interconnect layer 1662 is removed to expose metal layer 1604, so that the thickness of the semiconductor device can be reduced.

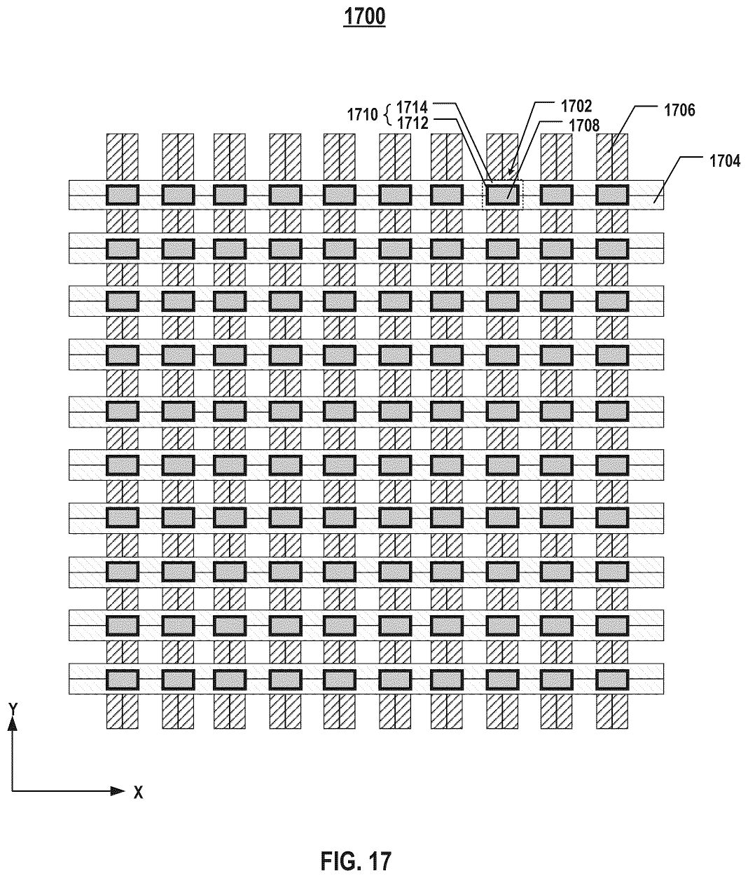

It is understood that the vertical transistors 626 in DRAM cells 624 are not limited to single-gate transistors as shown in FIG. 6A and FIG. 6B or double-gate transistors as shown in FIG. 13. According to some aspects of the present disclosure, the vertical transistors of memory cells in a semiconductor device are multi-gate transistors, and the gate dielectrics of vertical transistors in the word line direction are separate. For example, FIG. 17 illustrates a plan view of an array of memory cells 1702 each including a vertical transistor in a semiconductor device 1700, according to some aspects of the present disclosure. As shown in FIG. 17, semiconductor device 1700 can include a plurality of word lines 1704 each extending in a first lateral direction (the x-direction, referred to as the word line direction). Semiconductor device 1700 can also include a plurality of bit lines 1706 each extending in a second lateral direction perpendicular to the first lateral direction (the y-direction, referred to as the bit line direction). It is understood that FIG. 17 does not illustrate a cross-section of semiconductor device 1700 in the same lateral plane, and word lines 1704 and bit lines 1706 may be formed in different lateral planes for ease of routing as described below in detail.

Memory cells 1702 can be formed at the intersections of word lines 1704 and bit lines 1706. In some implementations, each memory cell 1702 includes a vertical transistor (e.g., vertical transistor 210 in FIG. 2) having a semiconductor layer 1708 and a gate structure 1710. Semiconductor layer 1708 can extend in the vertical direction (the z-direction, not shown) perpendicular to the first and second lateral directions. The vertical transistor can be a multi-gate transistor in which gate structure 1710 is coupled with a plurality of sides (e.g., all 4 sides in FIG. 17) of semiconductor layer 1708 (the active region in which channels are formed). As shown in FIG. 17, the vertical transistor is a GAA transistor in which gate structure 1710 fully circumscribes semiconductor layer 1708 in the plan view. That is, gate structure 1710 circumscribes (e.g., surrounding and contacting) all four sides of semiconductor layer 1708 (having a rectangle or square-shaped cross-section) in the plan view, according to some implementations. Gate structure 1710 can include a gate dielectric 1712 fully circumscribes semiconductor layer 1708 in the plan view, and a gate electrode 1714 fully circumscribes gate dielectric 1712. In some implementations, gate dielectric 1712 is laterally between gate electrode 1714 and semiconductor layer 1708 in the bit line direction and in the word line direction. As described above, gate electrode 1714 may be part of word line 1704, and word line 1704 may be an extension of gate electrode 1714.

As shown in FIG. 17, gate electrodes 1714 of adjacent vertical transistors in the word line direction (the x-direction) are continuous, e.g., parts of a continuous conductive layer having gate electrodes 1714 and 1704. In contrast, gate dielectrics 1712 of adjacent vertical transistors in the word line direction are separate, e.g., not parts of a continuous dielectric layer having gate dielectrics 1712.

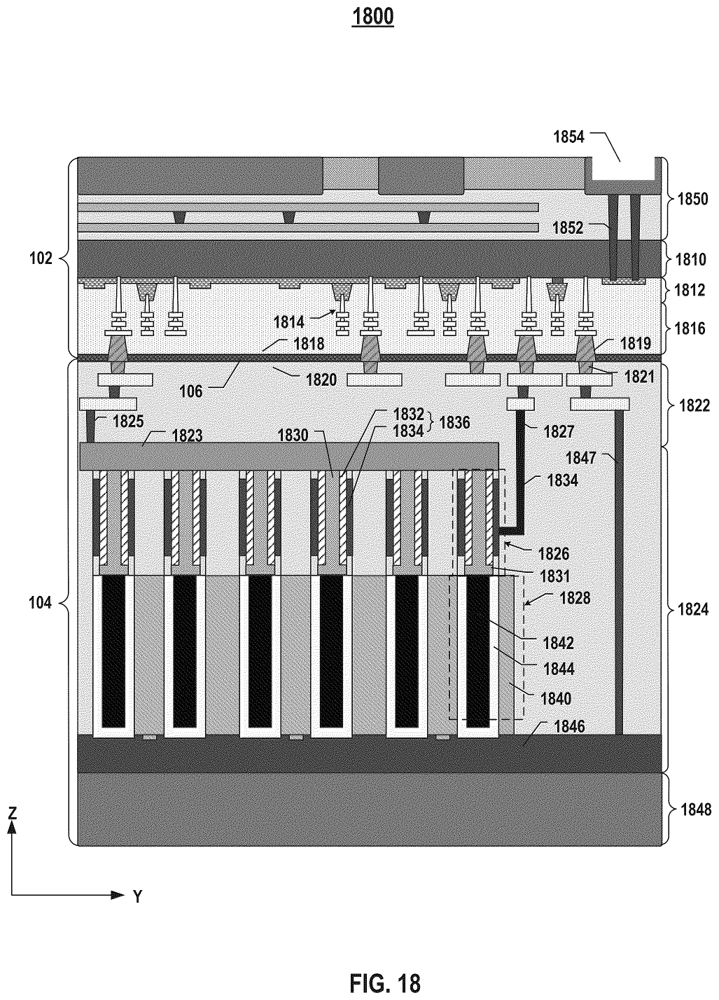

FIG. 18 illustrates a side view of a cross-section of a semiconductor device 1800 including vertical transistors, according to some aspects of the present disclosure. Semiconductor device 1800 may be one example of semiconductor device 1700 including multi-gate vertical transistors in which gate structures fully circumscribe semiconductor layers in the plan view, e.g., GAA vertical transistors. It is understood that FIG. 18 is for illustrative purposes only and may not necessarily reflect the actual device structure (e.g., interconnections) in practice. As one example of semiconductor device 100 described above with respect to FIG. 1A, semiconductor device 1800 is a bonded chip including first semiconductor structure 102 and second semiconductor structure 104 stacked under first semiconductor structure 102. First and second semiconductor structures 102 and 104 are jointed at bonding interface 106 therebetween, according to some implementations. As shown in FIG. 18, first semiconductor structure 102 can include a substrate 1810, which can include silicon (e.g., single crystalline silicon, c-Si), silicon germanium (SiGe), gallium arsenide (GaAs), germanium (Ge), silicon-on-insulator (SOI), or any other suitable materials.

First semiconductor structure 102 can include peripheral circuits 1812 on substrate 1810. In some implementations, peripheral circuits 1812 include a plurality of transistors 1814 (e.g., planar transistors and/or semiconductor transistors). Trench isolations (e.g., shallow trench isolations (STIs)) and doped regions (e.g., wells, sources, and drains of transistors 1814) can be formed on or in substrate 1810 as well.

In some implementations, first semiconductor structure 102 further includes an interconnect layer 1816 above peripheral circuits 1812 to transfer electrical signals to and from peripheral circuits 1812. Interconnect layer 1816 can include a plurality of interconnects (also referred to herein as “contacts”), including lateral interconnect lines and VIA contacts. Interconnect layer 1816 can further include one or more ILD layers in which the interconnect lines and via contacts can form. That is, interconnect layer 1816 can include interconnect lines and via contacts in multiple ILD layers. In some implementations, peripheral circuits 1812 are coupled to one another through the interconnects in interconnect layer 1816. The interconnects in interconnect layer 1816 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

As shown in FIG. 18, first semiconductor structure 102 can further include a bonding layer 1818 at bonding interface 106 and under interconnect layer 1816 and peripheral circuits 1812. Bonding layer 1818 can include a plurality of bonding contacts 1819 and dielectrics electrically isolating bonding contacts 1819. Bonding contacts 1819 can include conductive materials, such as Cu. The remaining area of bonding layer 1818 can be formed with dielectric materials, such as silicon oxide. Bonding contacts 1819 and surrounding dielectrics in bonding layer 1818 can be used for hybrid bonding. Similarly, as shown in FIG. 18, second semiconductor structure 104 can also include a bonding layer 1820 at bonding interface 106 and under bonding layer 1818 of first semiconductor structure 102. Bonding layer 1820 can include a plurality of bonding contacts 1821 and dielectrics electrically isolating bonding contacts 1821. Bonding contacts 1821 can include conductive materials, such as Cu. The remaining area of bonding layer 1820 can be formed with dielectric materials, such as silicon oxide. Bonding contacts 1821 and surrounding dielectrics in bonding layer 1820 can be used for hybrid bonding. Bonding contacts 1821 are coupled with bonding contacts 1819 at bonding interface 106, according to some implementations.

First semiconductor structure 102 can be bonded on top of second semiconductor structure 104 in a face-to-face manner at bonding interface 106. In some implementations, bonding interface 106 is disposed between bonding layers 1820 and 1818 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, bonding interface 106 is the place at which bonding layers 1820 and 1818 are met and bonded. In practice, bonding interface 106 can be a layer with a certain thickness that includes the bottom surface of bonding layer 1818 of first semiconductor structure 102 and the top surface of bonding layer 1820 of second semiconductor structure 104.

In some implementations, second semiconductor structure 104 further includes an interconnect layer 1822 including bit lines 1823 above bonding layer 1820 to transfer electrical signals. Interconnect layer 1822 can include a plurality of interconnects, such as MEOL interconnects and BEOL interconnects. In some implementations, the interconnects in interconnect layer 1822 also include local interconnects, such as bit lines 1823 and word line contacts 1827. Interconnect layer 1822 can further include one or more ILD layers in which the interconnect lines and via contacts can form. The interconnects in interconnect layer 1822 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof. In some implementations, peripheral circuits 1812 include a word line driver/row decoder coupled to the word line contacts in interconnect layer 1822 through bonding contacts 1821 and 1819 in bonding layers 1820 and 1818 and interconnect layer 116. In some implementations, peripheral circuits 1812 include a bit line driver/column decoder coupled to bit lines 1823 and bit line contacts 1825 in interconnect layer 1822 through bonding contacts 1821 and 1819 in bonding layers 1820 and 1818 and interconnect layer 1816.

In some implementations, second semiconductor structure 104 includes a DRAM device in which memory cells are provided in the form of an array of DRAM cells 1824 (e.g., an example of memory cells 1702 in FIG. 17) under interconnect layer 1822 and bonding layer 1820. That is, interconnect layer 1822 including bit lines 1823 can be disposed between bonding layer 1820 and array of DRAM cells 1824. It is understood that the cross-section of semiconductor device 1800 in FIG. 18 may be made along the bit line direction (the y-direction), and one bit line 1823 in interconnect layer 1822 extending laterally in the y-direction may be coupled to a column of DRAM cells 1824.

Vertical transistor 1826 can be a MOSFET used to switch a respective memory cell 1824. In some implementations, vertical transistor 1826 includes a semiconductor layer 1830 (i.e., the active region in which channels can form) extending vertically (in the z-direction), and a gate structure 1836 coupled with a plurality of sides of semiconductor layer 1830 in the bit line direction (the y-direction). In some implementations, a leakage value of semiconductor layer 1830 is lower than a pico-ampere. For example, semiconductor layer 1830 can include a metal oxide semiconductor material. In the present implementation, the metal oxide semiconductor material can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

As described above, as in a GAA vertical transistor, semiconductor layer 1830 can have a cuboid shape or a cylinder shape, and gate structure 1836 can fully circumscribe semiconductor layer 1830 in the plan view, for example, as shown in FIG. 15. Gate structure 1836 includes a gate electrode 1834 and a gate dielectric 1832 laterally between gate electrode 1834 and semiconductor layer 1830, according to some implementations. For example, for semiconductor layer 1830 having a cylinder shape, semiconductor layer 1830, gate dielectric 1832, and gate electrode 1834 may be disposed radially from the center of vertical transistor 1826 in this order. In some implementations, gate dielectric 1832 surrounds and is coupled with semiconductor layer 1830, and gate electrode 1834 surrounds and is coupled with gate dielectric 1832.

As shown in FIG. 18, in some implementations, an extending portion 1831 extends along the second lateral direction (the y-direction) from an end of semiconductor layer 1830 and extending portion 1831 is coupled with the capacitor 1828. That is, a contact area between capacitor 1828 and vertical transistor 1826 equals an area of extending portion 1831 on the x-y plane, which is tens of times than an area of an end of semiconductor layer 1830 on the x-y plane. The contact resistance can be reduced significantly due to the increasement of contact area.

Vertical transistor 1826 can further include a source and a drain disposed at the two ends (the upper end and lower end) of semiconductor layer 1830, respectively, in the vertical direction (the z-direction). In some implementations, one of source and drain (e.g., at the lower end in FIG. 18) is coupled to capacitor 1828, and the other one of source and drain (e.g., at the upper end in FIG. 18) is coupled to bit line 1823. Source and drain can be doped with N-type dopants (e.g., P or As) or P-type dopants (e.g., B or Ga) at a desired doping level. In some implementations, a silicide layer, such as a metal silicide layer, is formed between source and drain and bit line 1823 or first electrode 1842 to reduce the contact resistance. In some implementations, gate dielectric 1832 includes dielectric materials, such as silicon oxide, silicon nitride, or high-k dielectrics including, but not limited to, Al₂O₃, HfO₂, Ta₂O₅, ZrO₂, TiO₂, or any combination thereof. In some implementations, gate electrode 1834 includes conductive materials including, but not limited to W, Co, Cu, Al, TiN, TaN, polysilicon, silicides, or any combination thereof. In some implementations, gate electrode 1834 includes multiple conductive layers, such as a W layer over a TiN layer. In one example, gate structure 1836 may be a “gate oxide/gate poly” gate in which gate dielectric 1832 includes silicon oxide and gate electrode 1834 includes doped polysilicon. In another example, gate structure 1836 may be an HKMG in which gate dielectric 1832 includes a high-k dielectric and gate electrode 1834 includes a metal.

As described above, since gate electrode 1834 may be part of a word line or extend in the word line direction as a word line, second semiconductor structure 104 of semiconductor device 1800 can also include a plurality of word lines 1834 (referred to as 1834 as well) each extending in the word line direction. Each word line 1834 can be coupled to a row of DRAM cells 1824. That is, bit line 1823 and word line 1834 can extend in two perpendicular lateral directions, and semiconductor layer 1830 of vertical transistor 1826 can extend in the vertical direction perpendicular to the two lateral directions in which bit line 1823 and word line 1834 extend. Word lines 1834 are coupled with word line contacts (not shown), according to some implementations. In some implementations, word lines 1834 include conductive materials including, but not limited to W, Co, Cu, Al, TiN, TaN, polysilicon, silicides, or any combination thereof. In some implementations, word line 1834 includes multiple conductive layers, such as a W layer over a TiN layer.

As shown in FIG. 18, vertical transistor 1826 extends vertically through and is coupled with a corresponding word line 1834, and source or drain of vertical transistor 1826 at the upper end thereof is coupled with bit line 1823 (or bit line contact 1825), according to some implementations. Accordingly, word lines 1834 and bit lines 1823 can be disposed in different planes in the vertical direction due to the vertical arrangement of vertical transistor 1826, which simplifies the routing of word lines 1834 and bit lines 1823. In some implementations, bit lines 1823 are disposed vertically between bonding layer 1820 and word lines 1834, and word lines 1834 are disposed vertically between bit lines 1823 and capacitors 1828. Word lines 1834 can be coupled to peripheral circuits 1812 in first semiconductor structure 102 through word line contacts in interconnect layer 1822, bonding contacts 1821 and 1819 in bonding layers 1820 and 1818, and the interconnects in interconnect layer 1816. Similarly, bit lines 1823 in interconnect layer 1822 can be coupled to peripheral circuits 1812 in first semiconductor structure 102 through bonding contacts 1821 and 1819 in bonding layers 1820 and 1818 and the interconnects in interconnect layer 1816.

As shown in FIG. 18, in some implementations, capacitor 1828 includes a first electrode 1842 above and coupled with source or drain 1831 of vertical transistor 1826, e.g., the lower end of semiconductor layer 1830. Capacitor 1828 can also include a capacitor dielectric 1844 above and coupled with first electrode 1842, and a second electrode 1840 above and coupled with capacitor dielectric 1844. That is, capacitor 1828 can be a vertical capacitor in which first and second electrodes 1842 and 1840 and capacitor dielectric 1844 are stacked vertically (in the z-direction), and capacitor dielectric 1844 can be sandwiched between first and second electrodes 1842 and 1840. In some implementations, each first electrode 1842 is coupled to source or drain of a respective vertical transistor 1826 in the same DRAM cell, while all second electrodes 1840 are parts of a common plate 1846 coupled to the ground, e.g., a common ground. As shown in FIG. 18, second semiconductor structure 104 can further include a capacitor contact 1847 couple with common plate 1846 for coupling second electrodes 1840 of capacitor 1828 to peripheral circuits 1812 or to the ground directly. In some implementations, the ILD layer in which capacitors 1828 are formed has the same dielectric material as the two ILD layers into which semiconductor layer 1830 extends, such as silicon oxide.

It is understood that the structure and configuration of capacitor 1828 are not limited to the example in FIG. 18 and may include any suitable structure and configuration, such as a planar capacitor, a stack capacitor, a multi-fins capacitor, a cylinder capacitor, a trench capacitor, or a substrate-plate capacitor. In some implementations, capacitor dielectric 1844 includes dielectric materials, such as silicon oxide, silicon nitride, or high-k dielectrics including, but not limited to, Al₂O₃, HfO₂, Ta₂O₅, ZrO₂, TiO₂, or any combination thereof. It is understood that in some examples, capacitor 1828 may be a ferroelectric capacitor used in a FRAM cell, and capacitor dielectric 1844 may be replaced by a ferroelectric layer having ferroelectric materials, such as lead zirconate titanate (PZT) or Strontium Bismuth Tantalate (SBT). In some implementations, first and second electrodes 1842 and 1840 include conductive materials including, but not limited to W, Co, Cu, Al, TiN, TaN, polysilicon, silicides, or any combination thereof.

As shown in FIG. 18, in some implementations, vertical transistors 1826 are disposed vertically between capacitors 1828 and bonding interface 106. That is, vertical transistors 1826 can be arranged closer to peripheral circuits 1812 of first semiconductor structure 102 and bonding interface 106 than capacitors 1828. Since bit lines 1823 and capacitors 1828 are coupled to opposite ends of vertical transistors 1826, as described above, bit lines 1823 (as part of interconnect layer 1822) are disposed vertically between vertical transistors 1826 and bonding interface 106, according to some implementations. As a result, interconnect layer 1822 including bit lines 1823 can be arranged close to bonding interface 106 to reduce the interconnect routing distance and complexity.

In some implementations, first semiconductor structure 102 further includes a substrate 1848 disposed under DRAM cells 1824. As described below with respect to the fabrication process, substrate 1848 can be part of a carrier wafer. It is understood that in some examples, substrate 1848 may not be included in second semiconductor structure 104.

As shown in FIG. 18, second semiconductor structure 104 can further include a pad-out interconnect layer 1850 above peripheral circuit 1812 and substrate 1848. Pad-out interconnect layer 1850 can include interconnects, e.g., contact pads 1854, in one or more ILD layers. Pad-out interconnect layer 1850 and interconnect layer 1816 can be formed on opposite sides of peripheral circuit 1812. In some implementations, the interconnects in pad-out interconnect layer 1850 can transfer electrical signals between semiconductor device 1800 and outside circuits, e.g., for pad-out purposes. In some implementations, first semiconductor structure 102 further includes one or more contacts 1852 extending through substrate 1810 and part of pad-out interconnect layer 1850 to couple pad-out interconnect layer 1850 to peripheral circuit 1812 and interconnect layer 1816. As a result, DRAM cells 1824 can be coupled to peripheral circuit 1812 through interconnect layers 1816 and 1822 as well as bonding layers 1820 and 1818, and peripheral circuits 1812 and DRAM cells 1824 can be coupled to outside circuits through contacts 1852 and pad-out interconnect layer 1850. Contact pads 1854 and contacts 1852 can include conductive materials including, but not limited to, W, Co, Cu, Al, silicide, or any combination thereof. In one example, contact pad 1854 may include Al, and contact 1852 may include W. In some implementations, contact 1852 includes a via surrounded by a dielectric spacer (e.g., having silicon oxide) to electrically separate the via from substrate 1810. Depending on the thickness of substrate 1810, contact 1852 can be an ILV having a depth in the submicron-level (e.g., between 10 nm and 1 μm), or a TSV having a depth in the micron- or tens micron-level (e.g., between 1 μm and 100 μm).

Although not shown, it is understood that the pad-out of semiconductor devices is not limited to from first semiconductor structure 102 having peripheral circuit 1812 as shown in FIG. 18 and may be from second semiconductor structure 104 having DRAM cells 1824 in the similar manner as described above with respect to FIG. 6A. Although not shown, it is further understood that more than one array of DRAM cells 1824 may be stacked over one another to vertically scale up the number of DRAM cells 1824 in the similar manner as described above with respect to FIGS. 9A and 9B.

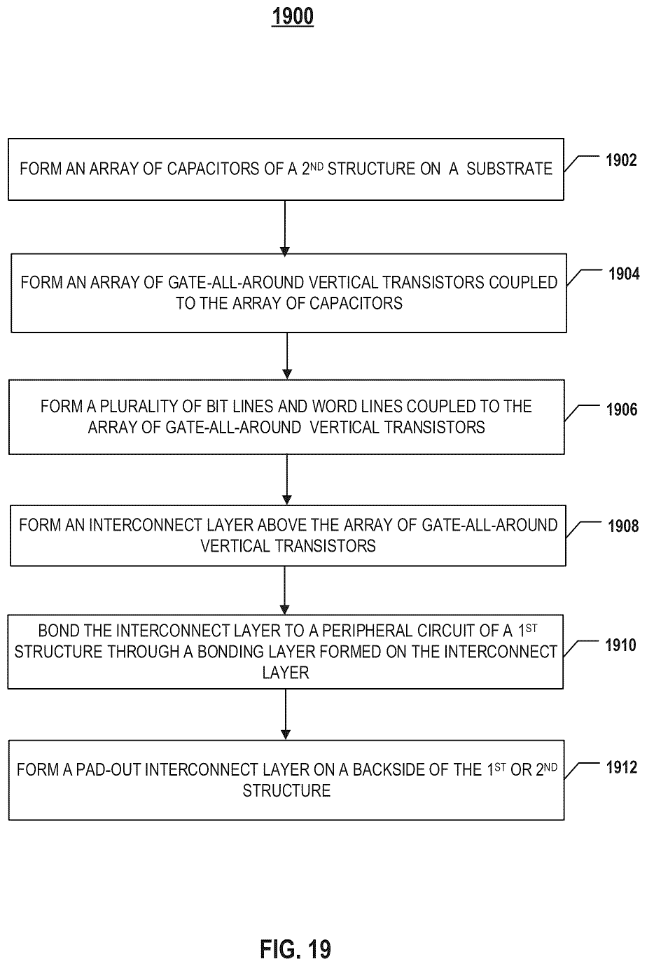

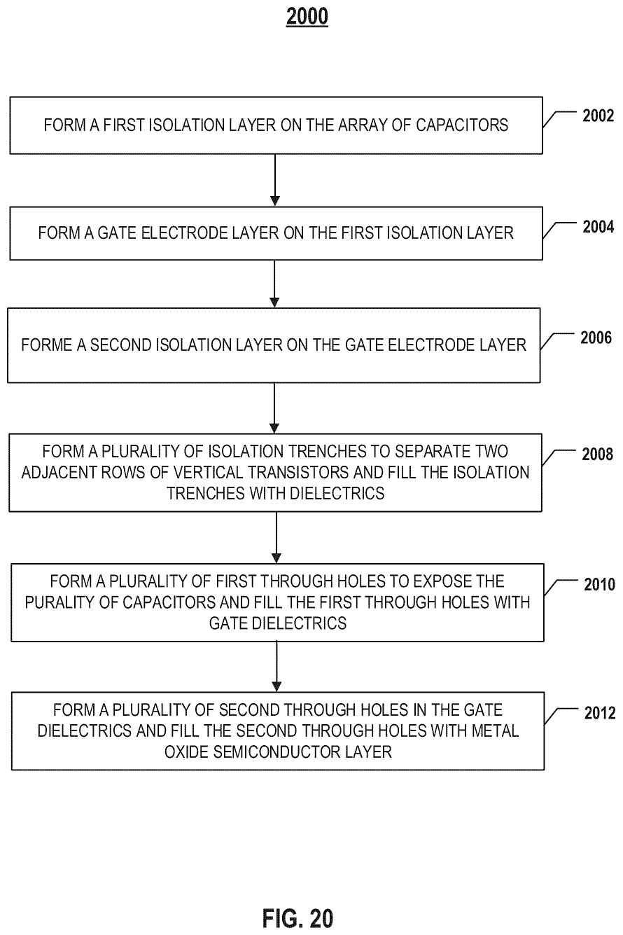

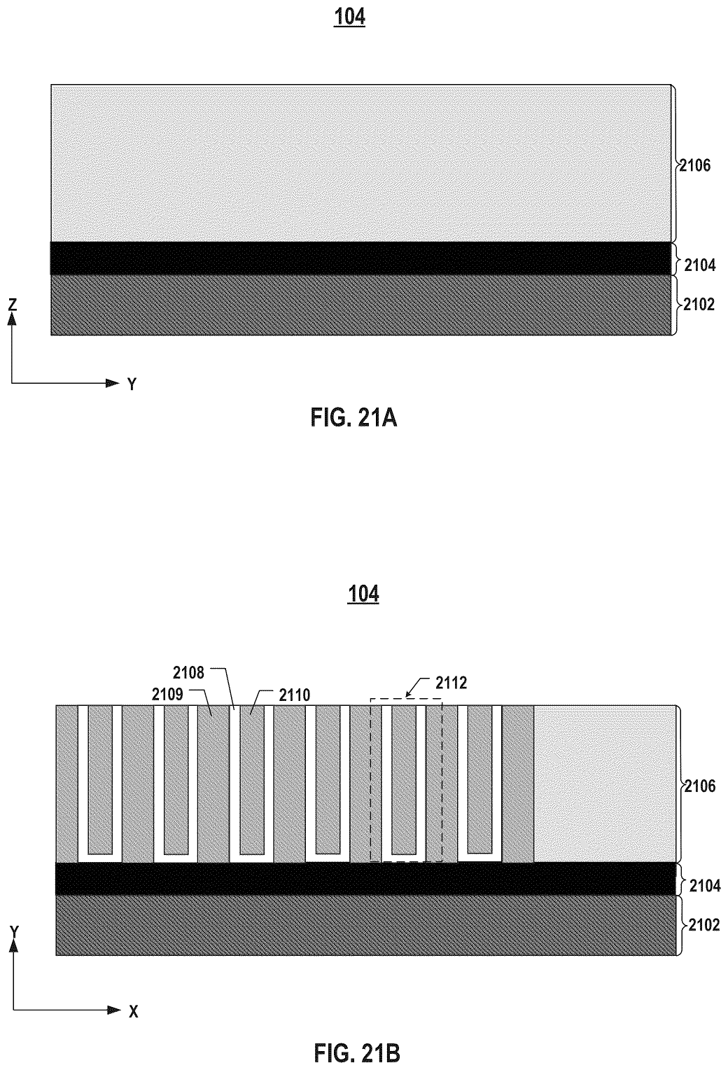

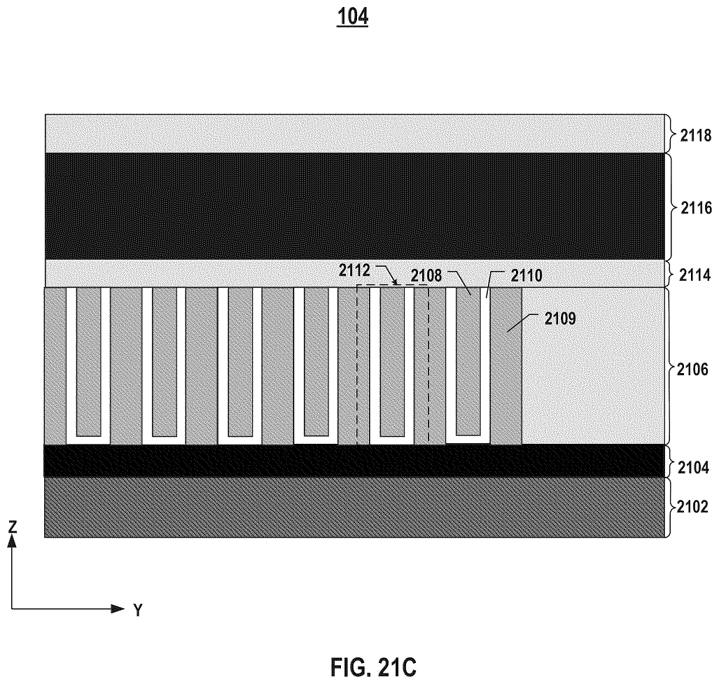

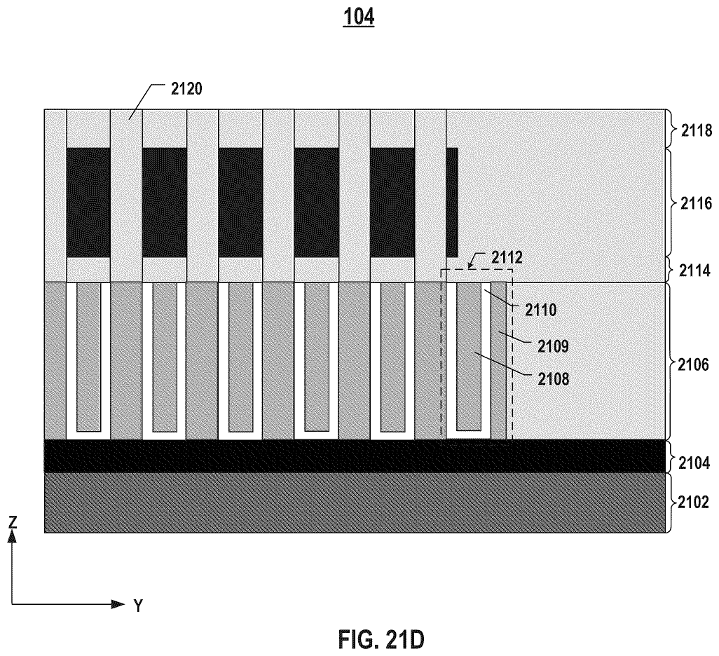

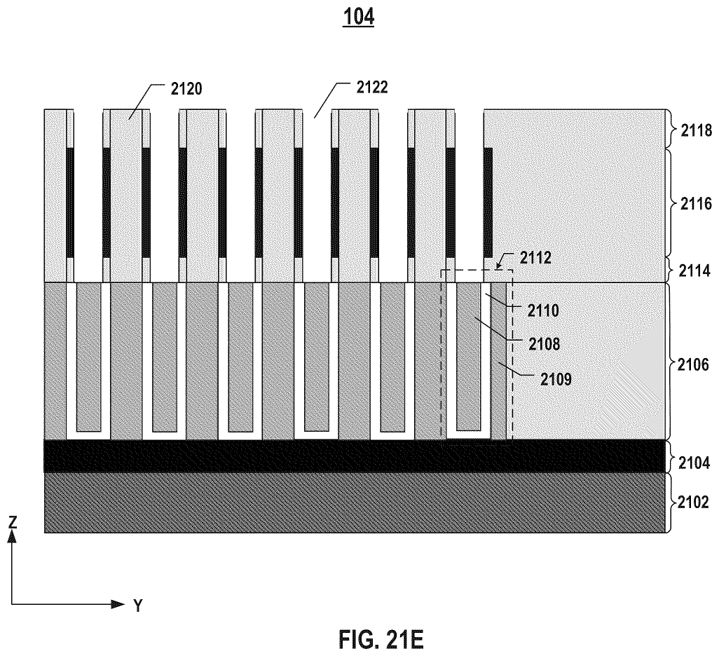

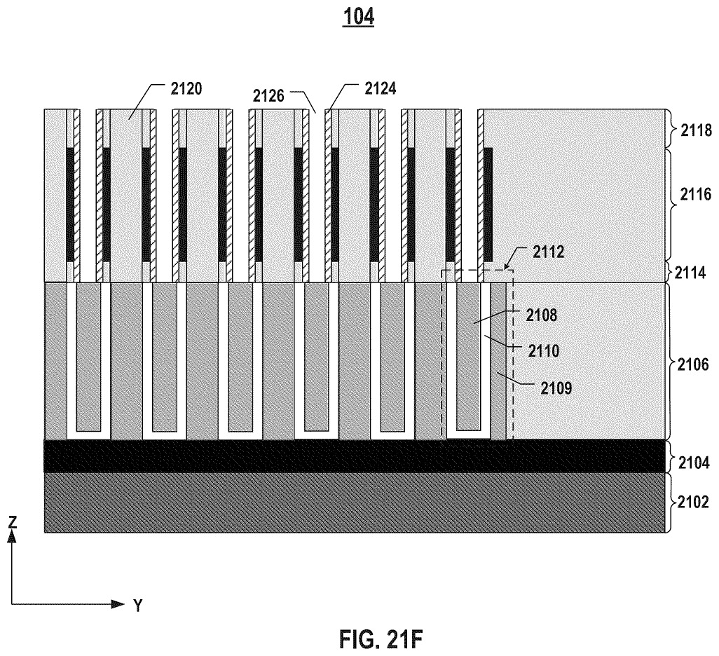

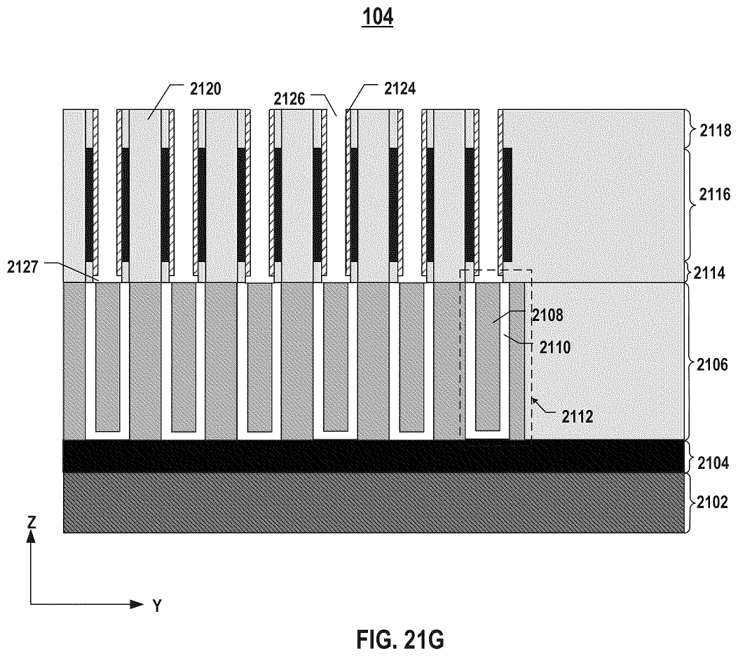

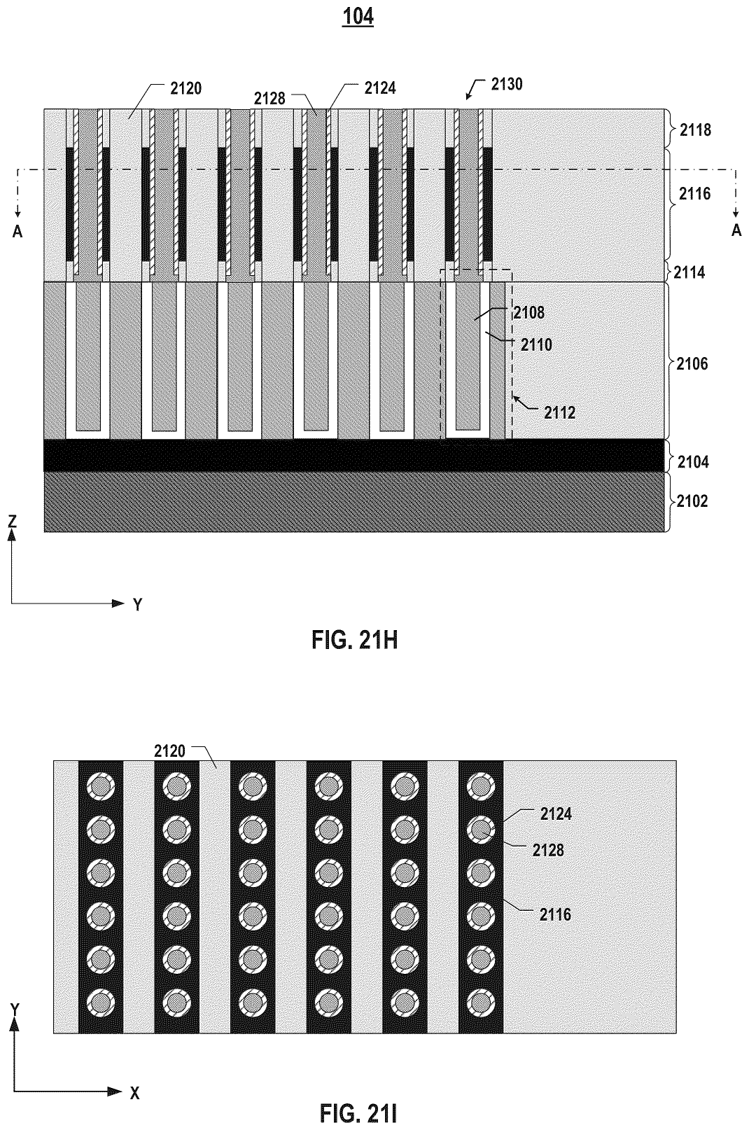

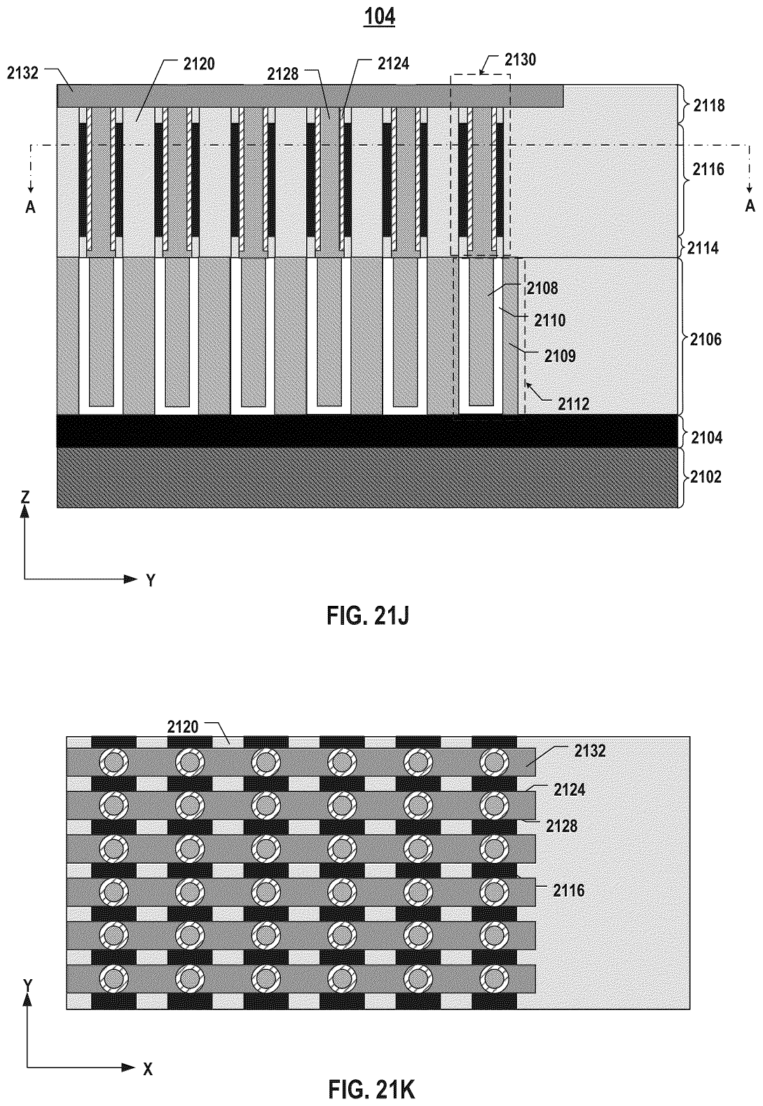

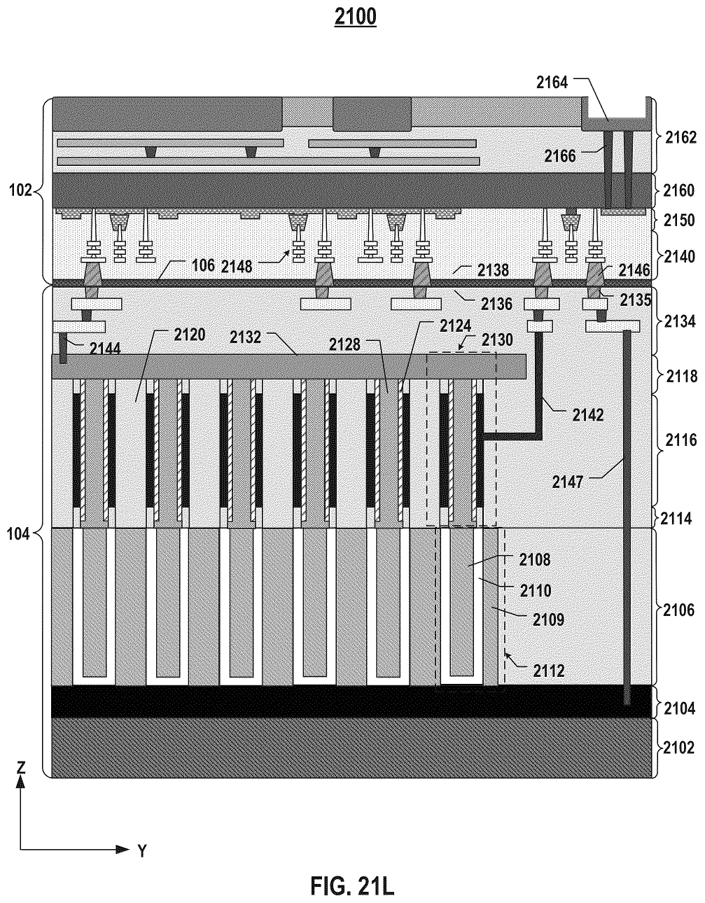

FIG. 19 illustrates a flowchart of a method 1900 for forming a semiconductor device including double-gate vertical transistors, such as semiconductor device 1800 described above in connection with FIG. 18, according to some implementations of the present disclosure. FIG. 20 illustrates a flowchart of a method 2000 for forming GAA vertical transistors in semiconductor device 1800 according to some implementations of the present disclosure. FIGS. 21A-21K illustrate a fabrication process for forming a semiconductor device 2100 at certain fabricating stages of the method 1900 shown in FIG. 19, according to various implementations of the present disclosure. It is understood that the operations shown in method 1900 are not exhaustive and that other operations can be performed as well before, after, or between any of the illustrated operations. Further, some of the operations may be performed simultaneously, or in a different order than shown in FIG. 19.

As shown in FIG. 19, method 1900 can start at operation 1902, in which an array of capacitors 2112 can be formed on a substrate 2102. Referring to FIG. 21B, the array of capacitors 2112 is a part of second semiconductor structure 104 as discussed above. First semiconductor structure 102 and second semiconductor structure 104 can be formed separately through independent fabrication processes and will be bonded together after corresponding fabrication processes are completed. First semiconductor structure 102 may be formed before, after, or at the same time as second semiconductor structure 104. The sequence of the fabrication of first and second semiconductor structures 102 and 104 are not limited in the implementations of the present disclosure and can be arranged and adjusted according to practical needs.

In some implementations, a first step of operation 1902 of method 1900 is proceeded, as shown in FIG. 21A, in which a metal layer 2104 is formed on first substrate 2102 and a dielectric layer 2106 is formed on metal layer 2104, FIG. 21A illustrates a schematic side cross-sectional view of the semiconductor device in y-z plane after dielectric layer 2106 is formed. Then a second step of operation 1902 of method 1900 is proceeded, in which an array of through holes are formed on dielectric layer 2106, then a capacitor dielectric 2108 and a first electrode 2110 of a capacitor 2112 is formed in each of the through holes. FIG. 21B illustrates a schematic side cross-sectional view of the semiconductor device in y-z plane after first electrode 2110 is formed.

In some implementations, the substrate 2102 can be a semiconductor substrate, which can include silicon (e.g., single crystalline silicon, c-Si), silicon germanium (SiGe), gallium arsenide (GaAs), germanium (Ge), silicon-on-insulator (SOI), or any other suitable materials. In such implementations, the array of capacitors 2112 can be formed directly on the semiconductor substrate 2102, and the transistor can be formed on a front side of the array of capacitors 2112 in subsequent processes. In some other implementations, the substrate 2102 can be a carrier substrate, which can include any suitable semiconductor materials, or an electrically non-conductive material, such as a glass, a plastic, or a sapphire wafer. In such implementations, the array of capacitors 2112 can be formed directly on another semiconductor substrate, and the carrier substrate 2102 can be formed on a front side of the array of capacitors 2112. After flipping over the structure and removing the semiconductor substrate, the transistor can be formed on a back side of the array of capacitors 2112 in subsequent processes.

The array of capacitors 2112 can include a second electrode 2109 coupled with a common plate, i.e., metal layer 2104, a plurality of first electrode 2110, and a capacitor dielectric 2108 between first electrodes 2110 and second electrode 2109. As shown, the array of capacitors 2112 can be an array. In some implementations, first electrodes 2110 and/or the second electrode 2109 can include conductive materials including, but not limited to, W, Co, Cu, Al, TiN, TaN, polysilicon, silicide, or any combination thereof. In some implementations, capacitor dielectric 808 includes dielectric materials, such as silicon oxide, silicon nitride, or high-k dielectrics including, but not limited to, Al₂O₃, HfO₂, Ta₂O₅, ZrO₂, TiO₂, or any combination thereof.

In some implementations, at least one mesh layer and a plurality of storage node contact may be formed during the fabrication of the array of capacitors 2112. It is understood that the details of the fabrication methods of mesh layer and storage node contact are not repeated here to ease description.

In some implementations, the array of capacitors 2112 can be formed by a series of fabricating processes including thin film deposition processes (e.g., chemical vapor deposition (CVD), physical vapor deposition (PVD), atomic layer deposition (ALD), etc.) and patterning processes (e.g., photoetching, dry etching, wet etching, cleaning, chemical mechanical polishing (CMP), etc. It is noted that, the fabricating processes and/or orders of forming the first electrodes 2110, the metal layer 2104, and the capacitor dielectric 2108 can be varied depending on a front side process or a back side process.

As shown in FIG. 19, method 1900 can proceed to operation 1904, in which an array of GAA vertical transistors 2130 are formed to couple to the array of capacitors 2112. FIG. 18 illustrates a flowchart of a method 2000 for forming GAA vertical transistors 2130 in semiconductor device 1600 according to some implementations of the present disclosure, as shown in FIGS. 21C-21I.

As shown in FIG. 20, method 2000 can proceed to operation 2002, in which a first isolation layer 2114 is formed on the array of capacitors 2112. First isolation layer 2114 is configured as an ILD layer to isolate the array of capacitors 2112 from the array of GAA transistors 2130, as shown in FIG. 21C. First isolation layer 2114 can be formed with dielectric materials including, but not limited to, silicon oxide, silicon nitride, silicon oxynitride, low-k dielectrics, or any combination thereof.

As shown in FIG. 20, method 2000 can then proceed to operation 2004, in which a gate electrode layer 2116 is formed on first isolation layer 2114. Gate electrode layer 2116 is configured to form a plurality of gate electrodes 2116 (referred to as 2116 as well) of the array of GAA vertical transistors 2130 corresponding to the array of capacitors 2112, as shown in FIG. 21C. In some implementations, gate electrode layer 2116 includes conductive materials including, but not limited to W, Co, Cu, Al, TiN, TaN, polysilicon, silicides, or any combination thereof. In some implementations, gate electrode layer 2116 includes multiple conductive layers, such as a W layer over a TiN layer.

As shown in FIG. 20 and FIG. 21C, method 2000 can then proceed to operation 2006, in which a second isolation layer 2118 is formed on gate electrode layer 2116. Second isolation layer 2118 is configured as an ILD layer to isolate the array of GAA transistors 2130 from the bonding layer and peripheral circuit. Second isolation layer 2114 can be formed with dielectric materials including, but not limited to, silicon oxide, silicon nitride, silicon oxynitride, low-k dielectrics, or any combination thereof.

As shown in FIG. 20, method 2000 can then proceed to operation 2008, in which a plurality of isolation trenches are formed to separate two adjacent rows of vertical transistors. The plurality of isolation trenches are then filled with dielectrics 2120, as shown in FIG. 21D. The plurality of isolation trenches are configured to isolate vertical transistors 2130 connected to a same word line from other vertical transistors. Thus, the isolation trenches penetrate at least the stack of second isolation layer 2118 and gate electrode layer 2116 so that the gate electrodes 2116 of vertical transistors connected to different word lines are electrically isolated. Fabrication processes to form the isolation trenches can include photolithography, wet/dry etch, or any other suitable processes. Dielectrics 2120 can include dielectric materials deposited by one or more thin film deposition processes including, but not limited to, CVD, PVD, ALD, or any combination thereof.

As shown in FIG. 20, method 2000 can then proceed to operation 2010, in which a plurality of first through holes 2122 are formed outside dielectrics 2120. First through holes 2122 penetrates first isolation layer 2114, gate electrode layer 2116, and second isolation layer 2118, the top ends of the plurality of capacitors 2112 are exposed from first through holes 2122, as shown in FIG. 21E. First through holes 2122 are surrounded by gate electrode layer 2116, a diameter of the plurality of first through holes is carefully designed so that a minimal distance between a side wall of each first through hole 2122 and an adjacent dielectric 2120 is larger than a preset value. In some implementations, a lithography process is performed to pattern the plurality of first through holes 2122 using an etch mask (e.g., a photoresist mask), for example, one or more dry etching and/or wet etching processes, such as reactive ion etch (RIE), are performed to etch first through holes 2122 through s first isolation layer 2114, gate electrode layer 2116, and second isolation layer 2118 until being stopped by first electrodes 2110 of capacitors 2112.

In some implementations, first through holes 2122 are then partly filled with gate dielectrics 2124, and a plurality of second through hole 2126 corresponding with the plurality of first through holes 2122 are then formed within and surrounded by gate dielectrics 2124, as shown in FIG. 21F. In some implementations, gate dielectric 2124 includes dielectric materials, such as silicon oxide, silicon nitride, or high-k dielectrics including, but not limited to, aluminum oxide (Al₂O₃), hafnium oxide (HfO₂), tantalum oxide (Ta₂O₅), zirconium oxide (ZrO₂), titanium oxide (TiO₂), or any combination thereof. Gate dielectrics 2124 can be deposited on the side walls of first through holes 2122. In some implementations, gate dielectric 2124 is formed by depositing a layer of dielectric, such as silicon oxide, over the exposed side walls of first through holes 2122 using one or more thin film deposition processes including, but not limited to, CVD, PVD, ALD, or any combination thereof. In some implementations, first through holes 2122 are fully filled with gate dielectrics 2124, second through holes 2126 are then formed within gate dielectrics using an etch mask.

In some implementations, a bottom end of each gate dielectric 2124 is selectively etched along y-direction to expand an area of the bottom end of corresponding second through hole 2126, as shown in FIG. 21G. A plurality of cavities 2127 are formed at an end of second through holes 2126 close to capacitors 2112. By forming cavity 2127, a part of gate dielectrics 2124 on first electrode 2110 would be replaced by semiconductor materials in subsequent processes. Thus, a contact area between the array of capacitors and the array of GAA vertical transistors can be expended to reduce the contact resistance. In some implementations, part of first isolation layer 2114 near the bottom end of second through hole 2126 is also etched to increase contact area between corresponding capacitor 2112 and vertical transistor 2130 until being stopped by dielectrics 2120.

As shown in FIG. 20, method 2000 can proceed to operation 2012, in which the plurality of second through holes 2126 are filled with semiconductor layer 2128, as shown in FIG. 21H and FIG. 21I. FIG. 21H illustrates a schematic side cross-sectional view of the semiconductor device 2100 in y-z plane after operation 2012 of method 2000. FIG. 21I illustrates a schematic side cross-sectional view of the semiconductor device in x-y plane alone A-A′ direction after operation 2012 of method 2000.

As shown in FIG. 21H, each GAA vertical transistor 2130 includes a semiconductor layer 2128 extending vertically from a bottom end of second through hole 2126 to an upper end opposite to capacitor 2112. Semiconductor layer 2128 is surrounded by gate dielectric 2124 of each vertical transistor 2130 and gate dielectric 2124 is surrounded by gate electrode 2116 of each vertical transistor 2130. With a gate structure (e.g., gate electrode 2116 and gate dielectric 2124) surrounding a semiconductor layer, GAA vertical transistor 2130 can achieve an increased gate control area and lower leakage current. In some implementations, semiconductor layer 2128 can be formed from a deposition process. In some implementations, the semiconductor can be one or more of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O, etc.

Vertical transistor 2130 can further include a source and a drain disposed at the two ends of semiconductor layer 2128, respectively, in the vertical direction. In some implementations, one of source and drain is coupled to capacitor 2112, and the other one of source and drain is coupled to bit line. In some implementations, gate electrode 2116 is etched to expose an end of semiconductor layer 2128 so that at least one end of semiconductor layer 2128 extends beyond gate electrode 2116 along vertical direction (e.g., z direction), as shown in FIG. 21H.

As shown in FIG. 21J, method 1900 can proceed to operation 1906, in which a plurality of bit lines 2132 and word lines 2116 (referred to 2116 as well) can be formed on the array of vertical transistors 2130. FIG. 21J illustrates a schematic side cross-sectional view of the semiconductor device in y-z plane after operation 1906 of method 1900. FIG. 21K illustrates a schematic side cross-sectional view of the semiconductor device in x-y plane after operation 1906 of method 1900.

As shown in FIGS. 21J and 21K, vertical transistor 2130 extends vertically through and is coupled with a corresponding word line 2116, and source or drain of vertical transistor 2130 at the upper end thereof is coupled with bit line 2132 (or bit line contact if any), according to some implementations. Accordingly, word lines 2116 and bit lines 2132 can be disposed in different planes in the vertical direction due to the vertical arrangement of vertical transistor 2130, which simplifies the routing of word lines 2116 and bit lines 2132. Referring to FIGS. 21J and 21K, bit lines 2132 extend along y direction and coupled with a plurality of sides of semiconductor layer 2128, word lines 2116 are disposed vertically between bit lines 2132 and capacitors 2112. In some implementations, a top end of each gate dielectric 2124 is replaced by bit line 2132, and a top end of semiconductor layer 2128 is surrounded by each bit line 2132, as shown in FIGS. 21J and 21K.

As shown in FIG. 19, method 1900 can proceed to operation 1908, in which an interconnect layer 2134 is formed above the array of vertical transistors 2130. Method 1900 can then proceed to operation 1910, in which interconnect layer 2134 is bonded to a peripheral circuit 2150 of first semiconductor structure 102 through a bonding layer 2138 formed above interconnect layer 2134. Method 1900 can then proceed to operation 1912, in which a pad-out interconnect layer 2162 is formed. FIG. 21L illustrates a schematic side cross-sectional view of the semiconductor device 2100 in y-z plane after operation 1912 of method 1900.

As shown in FIG. 21L, second semiconductor structure 104 can also include a bonding layer 2138 at bonding interface 106 to be coupled to a bonding layer of first semiconductor structure 102. Bonding layer 2138 can include a plurality of bonding contacts 2146 and dielectrics electrically isolating bonding contacts 2146. Bonding contacts 2146 can include conductive materials, such as Cu. The remaining area of bonding layer 2138 can be formed with dielectric materials, such as silicon oxide. Bonding contacts 2146 and surrounding dielectrics in bonding layer 2138 can be used for hybrid bonding. Bonding contacts 2146 are coupled with bonding contacts of first semiconductor structure 102 at bonding interface 106, according to some implementations.

In some implementations, interconnect layer 2134 can include a plurality of interconnects, such as MEOL interconnects and BEOL interconnects. In some implementations, the interconnects in interconnect layer 2134 also include local interconnects, such as bit lines 2132, bit line contacts 2144 (which may be omitted in some examples), word line contacts 2142, and capacitor contacts 2147. Interconnect layer 2134 can further include one or more ILD layers in which the interconnect lines and via contacts can form. The interconnects in interconnect layer 2134 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof. In some implementations, interconnect layer 2134 including bit lines 2132 can be disposed between bonding layer 2136 and array of vertical transistors 2130.

First semiconductor structure 102 can include peripheral circuits 2150 on substrate 2160. In some implementations, peripheral circuits 2150 includes a plurality of transistors 2148 (e.g., planar transistors and/or semiconductor transistors). Trench isolations (e.g., shallow trench isolations (STIs)) and doped regions (e.g., wells, sources, and drains of transistors 2148) can be formed on or in substrate 2160 as well. In some implementations, first semiconductor structure 102 further includes an interconnect layer 2140 under peripheral circuits 2150 to transfer electrical signals to and from peripheral circuits 2150. Interconnect layer 2140 can include a plurality of interconnects (also referred to herein as “contacts”), including lateral interconnect lines and vertical interconnect access (VIA) contacts. As used herein, the term “interconnects” can broadly include any suitable types of interconnects, such as middle-end-of-line (MEOL) interconnects and back-end-of-line (BEOL) interconnects. Interconnect layer 2140 can further include one or more interlayer dielectric (ILD) layers (also known as “intermetal dielectric (IMD) layers”) in which the interconnect lines and via contacts can form. That is, interconnect layer 2140 can include interconnect lines and via contacts in multiple ILD layers. In some implementations, peripheral circuits 2150 are coupled to one another through the interconnects in interconnect layer 2140. The interconnects in interconnect layer 2140 can include conductive materials including, but not limited to, W, Co, Cu, Al, doped silicon, silicide, or any combination thereof. The ILD layers can be formed with dielectric materials including, but not limited to, silicon oxide, silicon nitride, silicon oxynitride, low-k dielectrics, or any combination thereof.

First semiconductor structure 102 can further include a bonding layer 2138 at bonding interface 106 and above interconnect layer 2134. Bonding layer 2138 can include a plurality of bonding contacts 2146 and dielectrics electrically isolating bonding contacts 2146. Bonding contacts 2146 can include conductive materials, such as Cu. The remaining area of bonding layer 2138 can be formed with dielectric materials, such as silicon oxide. Bonding contacts 2146 and surrounding dielectrics in bonding layer 2138 can be used for hybrid bonding. In some implementations, peripheral circuits 2150 includes a word line driver/row decoder coupled to word line contacts 2142 in interconnect layer 2134 through bonding contacts 2135 and 2146 in bonding layers 2136 and 2138. In some implementations, peripheral circuits 2150 includes a bit line driver/column decoder coupled to bit lines 2132 and bit line contacts 2144 in interconnect layer 2134 through bonding contacts 2135 and 2146 in bonding layers 2136 and 2138 and interconnect layer 2140.

In some implementations, a pad-out interconnect layer 2162 is formed on the backside of the first semiconductor structure 102, as shown in FIG. 21L. In some implementations, pad-out interconnect layer 2162 is formed on the backside of the second semiconductor structure 104 (not shown).

Referring to FIG. 21L, pad-out interconnect layer 2162 is formed on the backside of substrate 2160 of first semiconductor structure 102. Pad-out interconnect layer 2162 can include interconnects, e.g., contact pads 2164, in one or more ILD layers. Pad-out interconnect layer 2162 and first semiconductor structure 102 can be formed on a same side as second semiconductor structure 104. In some implementations, the interconnects in pad-out interconnect layer 2162 can transfer electrical signals between the semiconductor device and outside circuits, e.g., for pad-out purposes. In some implementations, second semiconductor structure 104 further includes one or more contacts 2166 extending through substrate 2160 and part of pad-out interconnect layer 2162 to couple pad-out interconnect layer 2162 to DRAM cells and interconnect layer 2140. As a result, peripheral circuits 2150 can be coupled to DRAM cells through interconnect layers 2140 and 2134 as well as bonding layers 2136 and 2138, and peripheral circuits 2150 and DRAM cells can be coupled to outside circuits through contacts 2166 and pad-out interconnect layer 2162.

In some implementations, a pad-out interconnect layer 2162 is formed on the backside of second semiconductor structure 104, i.e., pad-out interconnect layer 2162 and first semiconductor structure 102 can be formed on opposite sides of second semiconductor structure 104, not shown. In some implementations, at operation 1912 in FIG. 19, substrate 2102 is removed or thinned to couple with pad-out interconnect layer 2162. In some implementations, planarization processes (e.g., CMP) and/or etching processes are performed to remove substrate 2102 until being stopped by metal layer 2104. Pad-out interconnect layer 2162 is removed to expose metal layer 2104, so that the thickness of the semiconductor device can be reduced.

The foregoing description of the specific implementations can be readily modified and/or adapted for various applications. Therefore, such adaptations and modifications are intended to be within the meaning and range of equivalents of the disclosed implementations, based on the teaching and guidance presented herein.

The breadth and scope of the present disclosure should not be limited by any of the above-described exemplary implementations but should be defined only in accordance with the following claims and their equivalents.

What is claimed is:

1. A semiconductor device, comprising:
a first semiconductor structure comprising a peripheral circuit; and
a second semiconductor structure comprising memory cells each having a vertical transistor and a storage unit coupled to the vertical transistor, and the vertical transistor comprising a semiconductor layer extending along a vertical direction and a gate structure coupled to the semiconductor layer; wherein
a leakage value of the semiconductor layer is lower than a pico-ampere; and
the first semiconductor structure is coupled with the second semiconductor structure, and the vertical transistor is between the peripheral circuit and the storage unit.

2. The semiconductor device of claim 1, wherein the second semiconductor structure further comprises:
bit lines each extending along a first lateral direction and coupled with the semiconductor layer; and
gate lines each extending along a second lateral direction and coupled with the gate structure,
wherein the vertical direction, the first lateral direction, and the second lateral direction are perpendicular to each other.

3. The semiconductor device of claim 2, wherein the bit lines are between the vertical transistors and the peripheral circuit.

4. The semiconductor device of claim 2, wherein each bit line is coupled with at least two opposite sides of an end of the semiconductor layer of each vertical transistor away from the storage unit.

5. The semiconductor device of claim 1, wherein the gate structure comprises a gate electrode and a gate dielectric between the gate electrode and the semiconductor layer in the first and second lateral directions.

6. The semiconductor device of claim 1, wherein the vertical transistor is a single-gate transistor in which a gate structure of the vertical transistor is located at one side of the semiconductor layer in a plan view.

7. The semiconductor device of claim 6, wherein the semiconductor layer comprises:
a vertical portion extending along the vertical direction; and
an extending portion extending from an end of the vertical portion towards an adjacent vertical transistor along a second lateral direction; wherein
the extending portion is coupled with the storage unit; and
the vertical direction and the second lateral direction are perpendicular to each other.

8. The semiconductor device of claim 1, wherein the vertical transistor comprises a double-gate transistor in which a gate structure of the vertical transistor is located at two opposite sides of the semiconductor layer.

9. The semiconductor device of claim 8, wherein the semiconductor layer comprises:
a vertical portion extending along the vertical direction; and
an extending portion extending from an end of the vertical portion towards two adjacent vertical transistors along a second lateral direction; wherein
the extending portion is coupled with the storage unit; and
the vertical direction and the second lateral direction are perpendicular to each other.

10. The semiconductor device of claim 1, wherein the vertical transistor comprises a gate-all-around (GAA) transistor in which the gate structure fully surrounds the semiconductor layer in a plan view.

11. The semiconductor device of claim 10, wherein the semiconductor layer comprises:
a vertical portion extending along the vertical direction; and
an extending portion extending from an end of the vertical portion towards two adjacent vertical transistors along a second lateral direction; wherein
the extending portion is coupled with the storage unit; and
the vertical direction and the second lateral direction are perpendicular to each other.

12. The semiconductor device of claim 1, wherein the vertical transistor comprises a tri-gate transistor in which the gate structure partially surrounds the semiconductor layer in a plan view.

13. The semiconductor device of claim 1, wherein the second semiconductor structure further comprises a pad-out interconnect layer, and the storage units are disposed between the vertical transistors and the pad-out interconnect layer.

14. The semiconductor device of claim 1, wherein the first semiconductor structure further comprises a pad-out interconnect layer, and the peripheral circuit is disposed between the second semiconductor structure and the pad-out interconnect layer.

15. The semiconductor device of claim 1, wherein the semiconductor layer comprises one or a combination of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O, and InₓGa_{y}O.

16. A method for forming a semiconductor memory device, comprising:
forming a first set of memory cells on a substrate;
forming a dielectric layer covering the first set of memory cells; and
forming a second set of memory cells on the dielectric layer; wherein
each of the memory cells of the first set and the second set comprises a vertical transistor and a storage unit coupled to the vertical transistor, the vertical transistor comprises a semiconductor layer extending along a vertical direction and a gate structure coupled to the semiconductor layer; and
a leakage value of the semiconductor layer is lower than a pico-ampere.

17. The method of claim 16, further comprising:
coupling a peripheral circuit with the second set of memory cells, wherein the vertical transistors of the second set of memory cells are between the peripheral circuit and the storage units of the second set of memory cells.

18. The method of claim 17, wherein forming the first set of memory cells comprises:
forming the storage units on the substrate, wherein the storage units are surrounded by a first isolation layer;
forming a second isolation layer covering the storage units;
forming through holes on the second isolation layer to expose the storage units; and
forming the vertical transistors in the through holes.

19. The method of claim 18, wherein forming the vertical transistors in the through holes comprises:
forming two semiconductor layers of two adjacent vertical transistors on two opposite sidewalls of each of the through holes, wherein comprises:
epitaxially growing an initial semiconductor layer covering a bottom and the two opposite sidewalls of each of the through hole; and
forming a trench on the initial semiconductor layer on the bottom of the through hole to punch through the initial semiconductor layer into two separate semiconductor layers of two adjacent vertical transistors;
forming two gate structures coupled to the two semiconductor layers respectively; and
filling the through holes with dielectric materials to isolate the two gate structures from each other.

20. A semiconductor device, comprising:
a first semiconductor structure comprising a peripheral circuit; and
a second semiconductor structure comprising a first set of memory cells and a second set of memory cells stacked on the first set of memory cells; wherein
each of the memory cells of the first set and the second set comprises a vertical transistor and a storage unit coupled to the vertical transistor, the vertical transistor comprises a semiconductor layer extending along a vertical direction and a gate structure coupled to the semiconductor layer, and a leakage value of the semiconductor layer is lower than a pico-ampere; and
the first semiconductor structure is bonded with the second semiconductor structure, and the first set of memory cells is between the peripheral circuit and the second set of memory cells.
